(19) United States
(12) Patent Application Publication
(10) Pub. No.: US 2026/0282576 A1
(43) Pub. Date: Sep. 17, 2026

(54) IMAGING DEVICE AND METHOD OF MANUFACTURING IMAGING DEVICE

(71) Applicant: SONY SEMICONDUCTOR SOLUTIONS CORPORATION, Kanagawa (JP)

(72) Inventors: Shinichiro NOUDO, Kumamoto (JP); Rikiya HIROSE, Kumamoto (JP); Katsuji KIMURA, Kanagawa (JP)

(73) Assignee: SONY SEMICONDUCTOR SOLUTIONS CORPORATION, Kanagawa (JP)

(21) Appl. No.: 19/167,515

(22) PCT Filed: Mar. 29, 2024
(86) PCT No.: PCT/JP2024/013362

§ 371 Date: Sep. 22, 2025

Related U.S. Application Data
(60) Provisional application No. 63/456,135, filed on Mar. 31, 2023.

(51) Int. Cl. H10F 39/00

(52) U.S. Cl. CPC H10F 39/8053; H10F 39/024; H10F 39/804; H10F 39/811

(57) ABSTRACT

An imaging device includes: an infrared-absorbing filter that absorbs infrared light; and a solid-state imaging element including a base in which a plurality of pixels is arranged in a two-dimensional array, the pixels each including a photoelectric conversion region that converts incident light having passed through the infrared-absorbing filter into an electric signal, in which the infrared-absorbing filter and the base are recessed in an incident direction of the incident light, and are curved as a whole.

### TECHNICAL FIELD

The present disclosure relates to an imaging device and to a method of manufacturing an imaging device.

### BACKGROUND ART

When an image sensor detects a large amount of near-infrared light (infrared rays) that is invisible to human eyes, a thus-obtained image has a deviation in color reproduction, as compared with a case where a subject is directly viewed by the human eyes. For this reason, a filter such as an infrared cut filter is provided in the image sensor to reduce the amount of near-infrared light that is to be detected by the image sensor.

For example, PTL 1 discloses an imaging device and a camera module. In the imaging device, a plurality of multilayer films having different refractive indices is provided on a surface of a sealing glass on a side of an optical sensor.

### CITATION LIST

### Patent Literature

PTL 1: Japanese Unexamined Patent Application Publication No. 2013-41941

### SUMMARY OF THE INVENTION

In an imaging device, a principal ray is obliquely incident on a multilayer film filter at a position where an image height is high in an image plane. It is desirable to provide an imaging device and a method of manufacturing the imaging device that each make it possible to effectively suppress or prevent deterioration in color reproducibility even when the principal ray is obliquely incident on the multilayer film filter.

An imaging device according to a first aspect of the present disclosure includes: an infrared-absorbing filter that absorbs infrared light; and a solid-state imaging element including a base in which a plurality of pixels is arranged in a two-dimensional array, the pixels each including a photoelectric conversion region that converts incident light having passed through the infrared-absorbing filter into an electric signal, in which the infrared-absorbing filter and the base are recessed in an incident direction of the incident light, and are curved as a whole.

In an imaging device according to a second aspect of the present disclosure, the infrared-absorbing filter includes an infrared-absorbing film formed by an on-chip in the pixel of the solid-state imaging element, in the imaging device according to the first aspect. In addition, the imaging device according to the second aspect further includes a multilayer film filter formed by an on-chip, in addition to the infrared-absorbing film. The multilayer film filter includes a high refractive index layer and a low refractive index layer that are alternately stacked, and has a specific transmission spectrum. The low refractive index layer has a refractive index lower than a refractive index of the high refractive index layer.

An imaging device according to a third aspect of the present disclosure further includes a seating including a curved housing section at a middle part of a front surface on a side of the solid-state imaging element, in the imaging device according to the first aspect. The curved housing section corresponds to a curved shape of the solid-state imaging element, and is recessed in the incident direction of the incident light to house the solid-state imaging element.

A method of manufacturing an imaging device according to a fourth aspect of the present disclosure includes: forming a solid-state imaging element including a base in which a plurality of pixels is arranged in a two-dimensional array, the pixels each including a photoelectric conversion region that converts incident light into an electric signal; forming a seating including a curved housing section at a middle part of a front surface of the seating, and a ventilation section, the curved housing section being recessed in an incident direction of the incident light to house the solid-state imaging element, the ventilation section being formed in the curved housing section from the middle part of the front surface to a side of a back surface opposed to the middle part of the front surface; placing the solid-state imaging element in the curved housing section and forming an infrared-absorbing filter that covers the curved housing section with the solid-state imaging element interposed between the infrared-absorbing filter and the curved housing section and absorbs infrared light; and generating a pressure difference in which a pressure on an inner side of the curved housing section is smaller than a pressure on a side of the infrared-absorbing filter to curve the solid-state imaging element and the infrared-absorbing filter along the curved housing section and bring the infrared-absorbing filter into close contact with a light-receiving surface, on which the plurality of pixels is arranged, of the solid-state imaging element.

A method of manufacturing an imaging device according to a fifth aspect of the present disclosure includes: forming a solid-state imaging element including a base in which a plurality of pixels is arranged in a two-dimensional array, the pixels each including a photoelectric conversion region that converts incident light into an electric signal; forming a seating including a curved housing section at a middle part of a front surface of the seating, the curved housing section being recessed in an incident direction of the incident light to house the solid-state imaging element; placing the solid-state imaging element in the curved housing section and bringing an infrared-absorbing filter into close contact with a light-receiving surface, on which the plurality of pixels is arranged, of the solid-state imaging element, the infrared-absorbing filter that absorbs infrared light; and curving the solid-state imaging element and the infrared-absorbing filter along the curved housing section after bringing the infrared-absorbing filter into close contact with the light-receiving surface of the solid-state imaging element.

### BRIEF DESCRIPTION OF THE DRAWINGS

FIG. 1 is a schematic cross-sectional configuration diagram of a main part of a first configuration of an imaging device according to a first embodiment of the present disclosure.

FIG. 2 is a diagram illustrating a transmittance characteristic of an infrared-absorbing filter used for the imaging device illustrated in FIG. 1.

FIG. 3 is a cross-sectional view in a first step describing a method of mounting the imaging device illustrated in FIG. 1.

FIG. 4 is a cross-sectional view in a second step describing the method of mounting the imaging device.

FIG. 5 is a schematic cross-sectional configuration diagram of a main part of a second configuration of the imaging device according to the first embodiment of the present disclosure.

FIG. 6 is a diagram illustrating a relationship between a plurality of inorganic materials that allows for formation of a multilayer film filter used for the imaging device illustrated in FIG. 5, and a refractive index of each of the inorganic materials.

FIG. 7 illustrates an example of transmittance characteristics of the infrared-absorbing filter and the multilayer film filter that are used for the imaging device illustrated in FIG. 5.

FIG. 8 is a step diagram illustrating a first curved mounting method in a case where a portion of a solid-state imaging element protrudes from a curved housing section of a seating. (A) of FIG. 8 is a planar configuration diagram of the seating before mounting. (B) of FIG. 8 is a cross-sectional configuration diagram of the seating before the mounting. (C) of FIG. 8 is a planar configuration diagram of the solid-state imaging element before the mounting. (D) of FIG. 8 is a planar configuration diagram of the imaging device in which the solid-state imaging element is mounted on the curved housing section of the seating. (E) of FIG. 8 is a cross-sectional configuration diagram of the imaging device taken along a line E-E illustrated in (D) of FIG. 8. (F) of FIG. 8 is a cross-sectional configuration diagram of the imaging device taken along a line F-F illustrated in (D) of FIG. 8.

FIG. 9 is a step diagram illustrating a second curved mounting method in a case where the solid-state imaging element is completely contained in the curved housing section of the seating. (A) of FIG. 9 is a planar configuration diagram of the seating before mounting. (B) of FIG. 9 is a cross-sectional configuration diagram of the seating before the mounting. (C) of FIG. 9 is a planar configuration diagram of the solid-state imaging element before the mounting. (D) of FIG. 9 is a planar configuration diagram of the imaging device in which the solid-state imaging element is mounted on the curved housing section of the seating. (E) of FIG. 9 is a cross-sectional configuration diagram of the imaging device taken along a line E-E illustrated in (D) of FIG. 9. (F) of FIG. 9 is a cross-sectional configuration diagram of the imaging device taken along a line F-F illustrated in (D) of FIG. 9.

FIG. 10 is a step diagram illustrating a third curved mounting method in which the solid-state imaging element is mounted on a curved housing section according to a first configuration. (A) of FIG. 10 is a planar configuration diagram of the seating before mounting. (B) of FIG. 10 is a cross-sectional configuration diagram of the seating before the mounting. (C) of FIG. 10 is a cross-sectional configuration diagram of the imaging device in which the solid-state imaging element is mounted on the curved housing section of the seating by using a pressure difference due to depressurization. (D) of FIG. 10 is a cross-sectional configuration diagram of an imaging device in which the solid-state imaging element is mounted on the curved housing section of the seating by using a pressure difference due to pressurization.

FIG. 11 is a step diagram illustrating the third curved mounting method in which the solid-state imaging element is mounted on a curved housing section according to a second configuration. (A) of FIG. 11 is a planar configuration diagram of the seating before mounting. (B) of FIG. 11 is a cross-sectional configuration diagram of the seating before the mounting.

FIG. 12 is a diagram describing a fourth curved mounting method in which the solid-state imaging element is mounted on a curved housing section according to a third configuration. (A) of FIG. 12 is a planar configuration diagram of the seating before mounting. (B) of FIG. 12 is a cross-sectional configuration diagram of the seating before the mounting. (C) of FIG. 12 is a cross-sectional configuration diagram at the time when the solid-state imaging element is placed on the curved housing section of the seating. (D) of FIG. 12 is a cross-sectional configuration diagram of the imaging device in which the solid-state imaging element is mounted on the curved housing section of the seating.

FIG. 13 is a step diagram describing a curved mounting method in which the solid-state imaging element is mounted on a curved housing section according to a fourth configuration. (A) of FIG. 13 is a cross-sectional configuration diagram of the seating and the solid-state imaging element before mounting. (B) of FIG. 13 is a cross-sectional configuration diagram illustrating, in an enlarged manner, main parts of the seating and the solid-state imaging element.

FIG. 14 is a planar configuration diagram of a seating according to a fifth configuration.

FIG. 15 is a cross-sectional view in a first step describing an overview of a method of manufacturing a solid-state imaging element according to a first configuration of the imaging device.

FIG. 16 is a cross-sectional view in a second step.

FIG. 17 is a cross-sectional view in a third step.

FIG. 18 is a cross-sectional configuration diagram of the imaging device in which the solid-state imaging element is mounted on the seating

FIG. 19 is a system configuration diagram of the imaging device.

FIG. 20 is a circuit configuration diagram of a pixel of the solid-state imaging element.

FIG. 21 is a specific cross-sectional configuration diagram of the solid-state imaging element and the infrared-absorbing filter.

FIG. 22 is a diagram illustrating a chemical formula of an organic material included in the infrared-absorbing filter.

FIG. 23A is a cross-sectional view in a first step describing a method of manufacturing the solid-state imaging element.

FIG. 23B is a cross-sectional view in a second step.

FIG. 23C is a cross-sectional view in a third step.

FIG. 23D is a cross-sectional view in a fourth step.

FIG. 23E is a cross-sectional view in a fifth step.

FIG. 23F is a cross-sectional view in a sixth step.

FIG. 23G is a cross-sectional view in a seventh step.

FIG. 23H is a cross-sectional view in an eighth step.

FIG. 23I is a cross-sectional view in a ninth step.

FIG. 23J is a cross-sectional view in a tenth step.

FIG. 23K is a cross-sectional view in an eleventh step.

FIG. 23L is a cross-sectional view in a twelfth step.

FIG. 23M is a cross-sectional view in a thirteenth step.

FIG. 23N is a cross-sectional view in a fourteenth step.

FIG. 23O is a cross-sectional view in a fifteenth step.

FIG. 24 is a cross-sectional configuration diagram of the solid-state imaging element and the infrared-absorbing filter that are used in a press type curved mounting method.

FIG. 25A is a cross-sectional view in a first step describing the press type curved mounting method.

FIG. 25B is a cross-sectional view in a second step.

FIG. 25C is a cross-sectional view in the second step at the time when a configuration of the housing curved section is changed.

FIG. 26A is a schematic cross-sectional view in a step of the press type curved mounting method with a pressing jig.

FIG. 26B is a perspective view of the seating, the solid-state imaging element, and the infrared-absorbing filter.

FIG. 27A is a planar configuration diagram of the curved housing section of the seating on which the solid-state imaging element is mounted.

FIG. 27B is a planar configuration diagram of the solid-state imaging element.

FIG. 28A is a planar configuration diagram of the seating for describing a depressurization type curved mounting method of a pressure difference type curved mounting method.

FIG. 28B is a planar configuration diagram of the seating.

FIG. 29A is a planar configuration diagram of the seating on which the solid-state imaging element is placed.

FIG. 29B is a cross-sectional configuration diagram of the seating on which the solid-state imaging element is placed.

FIG. 29C is a cross-sectional configuration diagram illustrating, in an enlarged manner, a main part of the seating on which the solid-state imaging element is placed.

FIG. 30A is a planar configuration diagram of the seating on which a gas leakproof film is mounted.

FIG. 30B is a cross-sectional configuration diagram of the seating on which the gas leakproof film is mounted.

FIG. 31 is a cross-sectional configuration diagram of the seating on which a collet is mounted.

FIG. 32A is a planar configuration diagram of the seating in a depressurization state.

FIG. 32B is a cross-sectional configuration diagram of the seating in the depressurization state.

FIG. 33 is a cross-sectional configuration diagram of the seating after finishing of curved mounting.

FIG. 34 is a cross-sectional configuration diagram of the imaging device after the finishing of the curved mounting.

FIG. 35A is a planar configuration diagram of the seating for describing a pressurization type curved mounting method of the pressure difference type curved mounting method.

FIG. 35B is a planar configuration diagram of the seating.

FIG. 36A is a planar configuration diagram of the seating on which the solid-state imaging element is placed.

FIG. 36B is a cross-sectional configuration diagram of the seating on which the solid-state imaging element is placed.

FIG. 36C is a cross-sectional configuration diagram illustrating, in an enlarged manner, a main part of the seating on which the solid-state imaging element is placed.

FIG. 37A is a planar configuration diagram of the seating on which the gas leakproof film is mounted.

FIG. 37B is a cross-sectional configuration diagram of the seating on which the gas leakproof film is mounted.

FIG. 38 is a cross-sectional configuration diagram of the seating on which a nozzle is mounted.

FIG. 39A is a planar configuration diagram of the seating in a pressurization state.

FIG. 39B is a cross-sectional configuration diagram of the seating in the pressurization state.

FIG. 40 is a cross-sectional configuration diagram of the seating after finishing of curved mounting.

FIG. 41 is a cross-sectional configuration diagram of the imaging device after the finishing of the curved mounting.

FIG. 42 is a specific cross-sectional configuration diagram of a solid-state imaging element according to the first configuration and the infrared-absorbing filter.

FIG. 43 is a specific cross-sectional configuration diagram of a solid-state imaging element according to a second configuration and the infrared-absorbing filter.

FIG. 44 is a specific cross-sectional configuration diagram of a solid-state imaging element according to a third configuration and the infrared-absorbing filter.

FIG. 45 is a specific cross-sectional configuration diagram of a solid-state imaging element according to a fourth configuration and the infrared-absorbing filter.

FIG. 46 is a specific cross-sectional configuration diagram of a solid-state imaging element according to a fifth configuration and the infrared-absorbing filter.

FIG. 47 is a specific cross-sectional configuration diagram of a solid-state imaging element according to a sixth configuration, the infrared-absorbing filter, and the multilayer film filter.

FIG. 48 is a specific cross-sectional configuration diagram illustrating the multilayer film filter in an enlarged manner.

FIG. 49A is a wavelength-transmittance characteristic diagram of the infrared-absorbing filter.

FIG. 49B is a wavelength-transmittance characteristic diagram of the multilayer film filter.

FIG. 50 is a specific cross-sectional configuration diagram of a solid-state imaging element according to a seventh configuration, the infrared-absorbing filter, and the multilayer film filter.

FIG. 51 is a specific cross-sectional configuration diagram of a solid-state imaging element according to an eighth configuration, the infrared-absorbing filter, and the multilayer film filter.

FIG. 52 is a specific cross-sectional configuration diagram of a solid-state imaging element according to a ninth configuration, the infrared-absorbing filter, and the multilayer film filter.

FIG. 53 is a diagram illustrating an infrared-absorbing material of an infrared-absorbing filter 3, and each of (A) to (M) is a molecular structure diagram of the infrared-absorbing material.

FIG. 54 illustrates an example of a cross-sectional configuration of an imaging device 1 according to a second embodiment of the present disclosure.

FIG. 55A is a planar configuration diagram of a seating before mounting.

FIG. 55B is a cross-sectional configuration diagram of the seating before the mounting.

FIG. 56A is a planar configuration diagram of the seating on which a solid-state imaging element is placed.

FIG. 56B is a cross-sectional configuration diagram of the seating on which the solid-state imaging element is placed.

FIG. 57A is a planar configuration diagram of the seating on which the infrared-absorbing filter is mounted.

FIG. 57B is a cross-sectional configuration diagram of the seating on which the infrared-absorbing filter is mounted.

FIG. 58A is a planar configuration diagram of the seating, the solid-state imaging element, and the infrared-absorbing filter after finishing of curved mounting.

FIG. 58B is a cross-sectional configuration diagram of the seating, the solid-state imaging element, and the infrared-absorbing filter after the finishing of the curved mounting.

FIG. 59A is a planar configuration diagram of the seating for describing a depressurization type curved mounting method of the pressure difference type curved mounting method.

FIG. 59B is a cross-sectional configuration diagram of the seating.

FIG. 60A is a planar configuration diagram of the seating on which the solid-state imaging element is placed.

FIG. 60B is a cross-sectional configuration diagram of the seating on which the solid-state imaging element is placed.

FIG. 60C is a cross-sectional configuration diagram illustrating a main part of the seating in an enlarged manner.

FIG. 61 is a planar configuration diagram of the infrared-absorbing filter.

FIG. 62A is a planar configuration diagram of the seating on which the infrared-absorbing filter is mounted.

FIG. 62B is a cross-sectional configuration diagram of the seating on which the infrared-absorbing filter is mounted.

FIG. 63A is a planar configuration diagram of the seating in a depressurization state.

FIG. 63B is a cross-sectional configuration diagram of the seating in the depressurization state.

FIG. 64 is a cross-sectional configuration diagram of the seating in a state in which a ventilation section is filled with an embedded member.

FIG. 65 is a cross-sectional configuration diagram of a package on which the seating is mounted.

FIG. 66 is a cross-sectional configuration diagram of the package in a state in which a wire is bonded. FIG. 67 is a cross-sectional configuration diagram of a seating in a pressurization state according to a modification example.

FIG. 68A is a planar configuration diagram of the solid-state imaging element and the infrared-absorbing filter for describing the press type curved mounting method.

FIG. 68B is a cross-sectional configuration diagram of the solid-state imaging element and the infrared-absorbing filter for describing the press type curved mounting method.

FIG. 69 is a cross-sectional configuration diagram of the seating, the solid-state imaging element, the infrared-absorbing filter, and the pressing jig before press type curved mounting.

FIG. 70 is a cross-sectional configuration diagram of the seating, the solid-state imaging element, the infrared-absorbing filter, and the pressing jig during the press type curved mounting.

FIG. 71 is a cross-sectional configuration diagram of the seating, the solid-state imaging element, the infrared-absorbing filter, and the pressing jig after the press type curved mounting.

FIG. 72 is a planar configuration diagram of the infrared-absorbing filter for describing the press type curved mounting method.

FIG. 73 is a cross-sectional configuration diagram of the seating on which the solid-state imaging element and the infrared-absorbing filter are placed.

FIG. 74 is a cross-sectional configuration diagram of the seating, the solid-state imaging element, the infrared-absorbing filter, and the pressing jig before press type curved mounting.

FIG. 75 is a cross-sectional configuration diagram of the seating, the solid-state imaging element, the infrared-absorbing filter, and the pressing jig during the press type curved mounting.

FIG. 76 is a cross-sectional configuration diagram of the seating, the solid-state imaging element, the infrared-absorbing filter, and the pressing jig after the press type curved mounting.

### MODES FOR CARRYING OUT THE INVENTION

Hereinafter, description is given in detail of embodiments of the present disclosure with reference to the drawings. It is to be noted that the description is given in the following order.

### 1. First Embodiment

A first embodiment describes an example in which the present technology is applied to an imaging device and a method of manufacturing of the imaging device. In the first embodiment, a filter is disposed on a light-receiving surface of a solid-state imaging element that constructs the imaging device, and the solid-state imaging element and the filter are each mounted in a curved shape. An infrared-absorbing filter is used for the filter. In addition, the infrared-absorbing filter and a multilayer film filter are used for the filter. The first embodiment describes, in detail, the imaging device configured as described above and the method of manufacturing the imaging device.

### 2. Second Embodiment

A second embodiment describes a method of bringing a film into close contact with the light-receiving surface of the solid-state imaging element, in the imaging device and the method of manufacturing of the imaging device according to the first embodiment.

### 3. Other Embodiments

### 1. First Embodiment

Description is given, with reference to FIGS. 1 to 53, of an imaging device 1 and a method of manufacturing the imaging device 1 according to the first embodiment of the present disclosure.

Here, an arrow −X direction indicated as appropriate in the drawings indicates one planar direction of the imaging device 1 placed on a plane for convenience. An arrow −Y direction indicates another planar direction orthogonal to the arrow −X direction. In addition, an arrow −Z direction indicates an upward direction orthogonal to the arrow −X direction and the arrow −Y direction. That is, the arrow −X direction, the arrow −Y direction, and the arrow −Z direction exactly coincide with an X-axis direction, a Y-axis direction, and a Z-axis direction, respectively, of a three-dimensional coordinate system.

It is to be noted that these directions are each indicated to aid understanding of descriptions, and are not intended to limit directions used in the present technology.

In addition, in the first embodiment and the second embodiment described later, components the same or substantially the same as one another are denoted by the same reference numerals, and redundant descriptions are omitted.

### [Schematic Configuration of Imaging Device 1]

### (1) Overview of First Configuration of Imaging Device 1

FIG. 1 illustrates an example of a schematic cross-sectional configuration of a main part of a first configuration of the imaging device 1 according to the first embodiment.

As illustrated in FIG. 1, the imaging device 1 includes a solid-state imaging element 2 and an infrared-absorbing filter 3.

The solid-state imaging element 2 includes a base 20. The base 20 includes a semiconductor substrate 21 and a wiring layer 22. The semiconductor substrate 21 has a first surface 21A in the arrow-Z direction, and a second surface 21B opposed to the first surface 21A. The wiring layer 22 is disposed on the semiconductor substrate on a side of the second surface 21B.

The semiconductor substrate 21 is, for example, a single-crystal Si substrate. A photoelectric conversion region 200 that converts incident light L into an electric signal is disposed in the semiconductor substrate 21. The incident light L is incident on the photoelectric conversion region 200 in a direction, as an incident direction, opposite to the arrow-Z direction from an outside of the imaging device 1 through the infrared-absorbing filter 3.

The photoelectric conversion region 200 is formed by, for example, a semiconductor photodiode. Here, one photoelectric conversion region 200 constructs one pixel 200P.

Here, the wiring layer 22 includes a plurality of wirings 221 in an insulating film 222. In actuality, the insulating film 222 is formed by stacking a plurality of insulating films.

Another base that is not illustrated is disposed on the wiring layer 22 on a side opposite to the semiconductor substrate 21. For example, a readout circuit or the like is disposed in the other base. The readout circuit reads out electric charge converted into the electric signal by the photoelectric conversion region 200. That is, the wiring layer 22 is used for electrical coupling between the photoelectric conversion region 200 and the readout circuit or the like. It is to be noted that in some cases, the readout circuit may be described as a “pixel circuit”.

An optical filter 23, an optical lens 24, and a planarization film 25 are sequentially stacked on the first surface 21A of the semiconductor substrate 21 in the arrow −Z direction.

The optical filter 23 is a color filter disposed for each pixel 200P. For example, the optical filter 23 of green (G) that allows a wavelength band of green light to pass therethrough is disposed for one pixel 200P. In addition, the optical filter 23 of red (R) that allows a wavelength band of red light to pass therethrough is disposed for one pixel 200P. Furthermore, although not illustrated, the optical filter 23 of blue (B) that allows a wavelength band of blue light to pass therethrough is disposed for one pixel 200P.

The optical lens 24 is formed in a curved shape that protrudes in a direction opposite to the incident direction of the incident light L as viewed in the arrow −Y direction (hereinafter, simply referred to as “in a side view”). The optical lens 24 is formed in a curved shape for each pixel 200P. That is, the optical lens 24 condenses the incident light L in the incident direction. The optical lens 24 is mounted on the semiconductor substrate 21, and is formed as what is called an on-chip lens.

It is to be noted that the optical lens 24 may be formed in a curved shape for every two or more pixels 200P.

The planarization film 25 has a surface, on a side opposite to the optical lens 24, that reduces a step height shape caused by the optical lens 24 and is planarized more than a surface on a side of the optical lens 24. In other words, the planarization film 25 improves, for example, adhesiveness to the infrared-absorbing filter 3 that is stacked on the surface of the planarization film 25.

The infrared-absorbing filter 3 is disposed on the surface of the planarization film 25 on the side opposite to the optical lens 24. The infrared-absorbing filter 3 is an absorption type infrared-absorbing film that absorbs infrared light. In other words, the infrared-absorbing filter 3 is an infrared-absorbing film.

The infrared-absorbing filter 3 is formed by an on-chip on a surface of the solid-state imaging element 2 on a side of the arrow −Z direction (on the surface of the planarization film 25), and is finally formed in close contact with the surface of the solid-state imaging element 2. Here, the infrared-absorbing filter 3 is formed by, for example, a spin coating method.

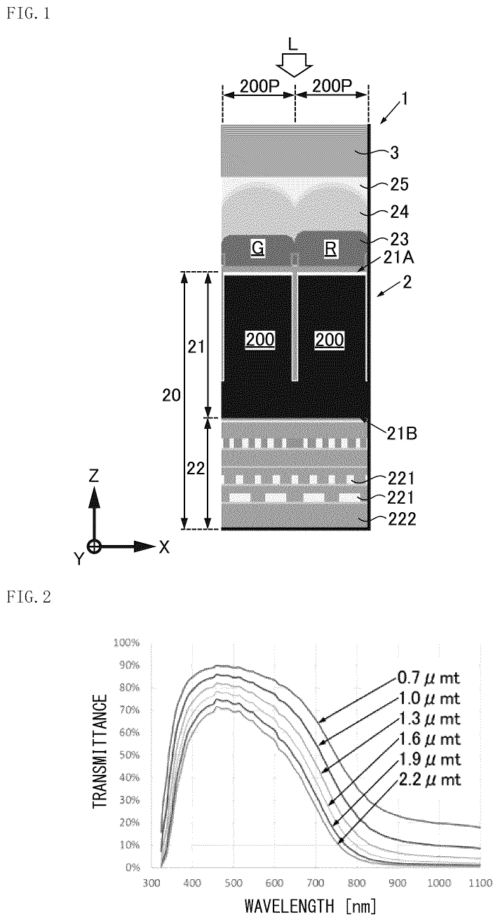

FIG. 2 illustrates an example of a transmittance characteristic of the infrared-absorbing filter 3. In FIG. 2, a horizontal axis indicates a wavelength [nm], and a vertical axis indicates a transmittance [%].

FIG. 2 illustrates transmittances of respective infrared-absorbing filters 3 having thicknesses of 0.7 μm, 1.0 μm, 1.3 μm, 1.6 μm, 1.9 μm, and 2.2 μm. As can be seen from FIG. 2, the thinner the thickness of the infrared-absorbing filter 3 is, the higher the transmittance becomes.

### (2) Mounting Structure and Mounting Method of Imaging Device 1

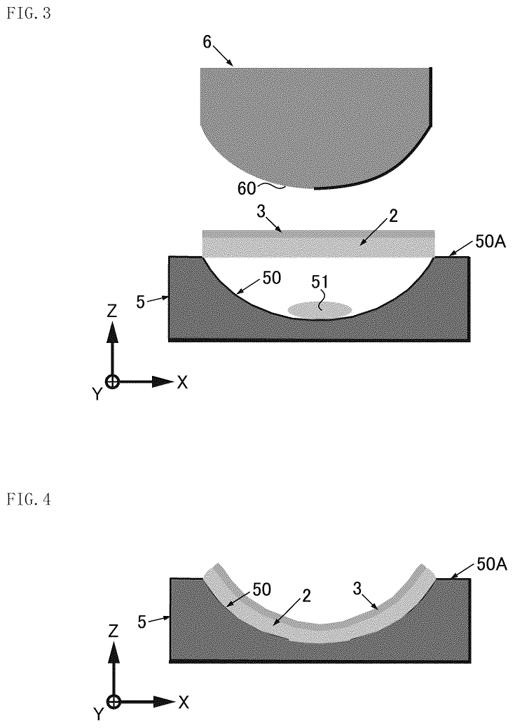

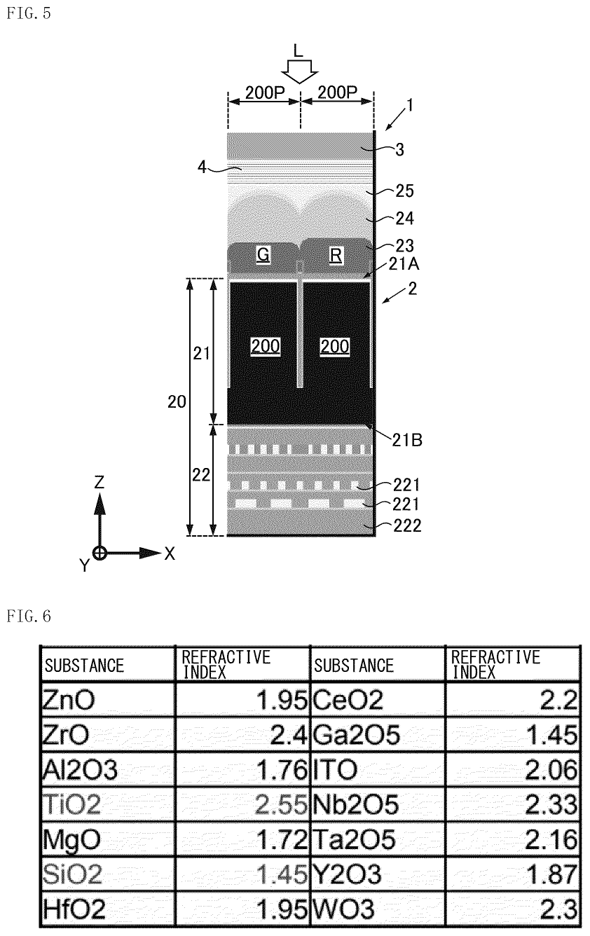

FIG. 3 illustrates an example of a first step for describing a method of mounting the imaging device 1. FIG. 4 illustrates an example of a second step for describing the method of mounting the imaging device 1.

The method of mounting the imaging device 1 is as follows.

First, a seating 5 is prepared (see FIG. 3). The seating 5 includes a curved housing section 50 at a middle part of a front surface 50A. The curved housing section 50 is recessed from the front surface 50A in the incident direction of the incident light L, and is formed in a curved shape in a side view. The solid-state imaging element 2 on which the infrared-absorbing filter 3 is disposed is placed on the curved housing section 50 (see FIG. 3). An adhesive 51 is formed in the curved housing section 50 in advance. As the adhesive 51, for example, a resin adhesive is used.

As illustrated in FIG. 3, a pressing jig 6 is placed above the solid-state imaging element 2 and the infrared-absorbing filter 3. The pressing jig 6 has an end part 60 that is formed in a curved shape that protrudes in the incident direction of the incident light L in a side view.

The end part 60 of the pressing jig 6 is pressed against the infrared-absorbing filter 3 and the solid-state imaging element 2. Thus, the solid-state imaging element 2 and the infrared-absorbing filter 3 are each formed in a curved shape along the curved shape of the curved housing section 50 (see FIG. 4). The solid-state imaging element 2 is adhered in the curved housing section 50 by the adhesive 51, and thereafter, the pressing jig 6 is released from pressing as illustrated in FIG. 4.

According to the above mounting method, in the imaging device 1, the solid-state imaging element 2 and the infrared-absorbing filter 3 are mounted on the curved housing section 50 of the seating 5. The solid-state imaging element 2 and the infrared-absorbing filter 3 that have been mounted correspond to the curved shape of the curved housing section 50 of the seating 5, and are recessed in the incident direction of the incident light L and curved as a whole.

### (3) Workings and Effects

The imaging device 1 according to the first configuration includes the infrared-absorbing filter 3 on a side of a light-receiving surface of the solid-state imaging element 2, as illustrated in FIG. 1. The infrared-absorbing filter 3 is formed by the on-chip. Furthermore, the solid-state imaging element 2 and the infrared-absorbing filter 3 are recessed in the incident direction of the incident light L and curved as a whole.

According to the imaging device 1 configured as described above, it is possible to reduce the number of components of an infrared cut filter (IRCF) on a set side and reduce reflection surfaces of the infrared cut filter on the set side, which makes it possible to effectively suppress or prevent flare or ghost.

In other words, reduction in the number of components makes it possible to reduce fabrication cost of the imaging device 1. In addition, effective suppression or prevention of the flare or ghost makes it possible to effectively suppress or prevent a ripple.

In addition, according to the imaging device 1 according to the first configuration, the infrared-absorbing filter 3 and the solid-state imaging element 2 are curved, which reduces dependence on an image height of an optical length in the infrared-absorbing filter 3. This makes it possible to effectively suppress or prevent color shading at a field angle end.

In addition, according to the imaging device 1 according to the first configuration, even if dust is adhered onto the light-receiving surface of the solid-state imaging element 2, it is possible to decrease image formability of the dust.

### (4) Overview of Second Configuration of Imaging Device 1

FIG. 5 illustrates an example of a schematic cross-sectional configuration of a main part of a second configuration of the imaging device 1 according to the first embodiment.

As illustrated in FIG. 5, the imaging device 1 includes the solid-state imaging element 2 and the infrared-absorbing filter 3, as with the imaging device 1 according to the first configuration, and further includes a multilayer film filter 4 that reflects infrared light. The multilayer film filter 4 is disposed between the planarization film 25 and the infrared-absorbing filter 3.

The multilayer film filter 4 includes a plurality of high refractive index layers and a plurality of low refractive index layers that are alternately stacked, and has a specific transmission spectrum. The low refractive index layers each have a refractive index lower than that of each of the high-refractive index layers. The multilayer film filter 4 is formed by an on-chip on the surface of the solid-state imaging element 2 on the side of the arrow-Z direction (on the surface of the planarization film 25), and is finally formed in close contact with the surface of the solid-state imaging element 2.

FIG. 6 illustrates an example of a relationship between a plurality of inorganic materials that allows for formation of the multilayer film filter 4, and a refractive index of each of the inorganic materials.

As illustrated in FIG. 6, the inorganic materials that allow for formation of the multilayer film filter 4 are transparent thin film materials. For example, it is possible to use two or more inorganic materials selected from ZnO, ZrO₂, Al₂O₃, TiO₂, MgO, SiO₂, HfO₂, CeO₂, Ga₂O₅, ITO, Nb₂O₅, Ta₂O₅, Y₂O₃, and WO₃. The refractive index of each of the inorganic materials is as illustrated in FIG. 6. Films of the inorganic materials are each formed by, for example, one or more methods selected from a vapor deposition method, a CVD (Chemical Vapor Deposition) method, and an ALD (Atomic Layer Deposition) method.

In the first embodiment, for example, TiO₂ having a refractive index of 2.28 is used for the high refractive index layers. In addition, for example, SiO₂ having a refractive index of 1.45 is used for the low refractive index layers.

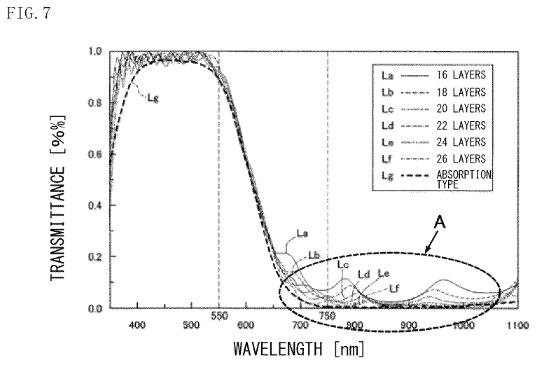

FIG. 7 illustrates an example of transmittance characteristics of the infrared-absorbing filter 3 and the multilayer film filter 4. In FIG. 7, a horizontal axis indicates a wavelength [nm], and a vertical axis indicates a transmittance [%].

A curve La indicates a transmittance characteristic of the reflection type multilayer film filter 4 including 16 layers. Likewise, a curve Lb, a curve Lc, a curve Ld, a curve Le, and a curve Lf respectively indicate transmittance characteristics of the reflection type multilayer film filter 4 including 18 layers, the reflection type multilayer film filter 4 including 20 layers, the reflection type multilayer film filter 4 including 22 layers, the reflection type multilayer film filter 4 including 24 layers, and the reflection type multilayer film filter 4 including 26 layers.

In contrast, a curve Lg indicates a transmittance characteristic of the absorption type multilayer film filter 4. The absorption type multilayer film filter 4 exhibits an ideal transmittance characteristic when natural colors close to a human vision sensitivity characteristic are reproduced. It is to be noted that, as indicated by the curve La to the curve Lf, increasing the number of layers stacked in the multilayer film filter 4 makes it possible to suppress a ripple in the transmittance characteristic. For detailed description, refer to Japanese Unexamined Patent Application Publication No. 2004-309934.

### (5) Mounting Structure and Mounting Method of Imaging Device 1

As with the imaging device 1 according to the first configuration, the imaging device 1 according to the second configuration is mounted on the seating 5 by the mounting method illustrated in FIGS. 3 and 4 described above. That is, in the imaging device 1, the solid-state imaging element 2, the multilayer film filter 4, and the infrared-absorbing filter 3 are housed in the curved housing section 50 of the seating 5, and are curved as a whole in the incident direction of the incident light L.

### (6) Workings and Effects

The imaging device 1 according to the second configuration includes the multilayer film filter 4 and the infrared-absorbing filter 3 on the side of the light-receiving surface of the solid-state imaging element 2, as illustrated in FIG. 5. The multilayer film filter 4 and the infrared-absorbing filter 3 are each formed by the on-chip. Furthermore, the solid-state imaging element 2, the multilayer film filter 4, and the infrared-absorbing filter 3 are recessed in the incident direction of the incident light L and curved as a whole.

According to the imaging device 1 configured as described above, it is possible to obtain workings and effects similar to the workings and effects obtained by the imaging device 1 according to the first configuration.

In addition, according to the imaging device 1, as illustrated in FIG. 7, the absorption type multilayer film filter 4 enhances a transmittance of visible light with a thin film. As a result, it is possible to reduce the number of layers stacked in the absorption type multilayer film filter 4.

In addition, according to the imaging device 1, it is possible to suppress a ripple of the reflection type multilayer film filter 5 by the absorption type multilayer film filter 4, as indicated by in a portion with a symbol A encircled by a broken line in FIG. 7. In contrast, it is possible to suppress floating of the absorption type multilayer film filter 4 by the reflection type multilayer film filter 4.

### [Configuration of Seating 5]

As illustrated in FIGS. 3 and 4 described above, the seating 5 includes the curved housing section 50. The curved shape of the curved housing section 50 is formed along an image-forming surface of an unillustrated module lens. Here, the module lens corresponds to a lens unit mounted on the imaging device 1 in the arrow −Z direction with respect to the optical lens 24 illustrated in FIGS. 1 and 5. The lens unit includes, for example, an optical lens, an optical part including, for example, a filter, and a mechanical part including, for example, a driving part that moves a focal position of the optical lens.

Adopting the seating 5 having such a shape makes it possible to reduce a corresponding load of image plane distortion in design of the module lens. Accordingly, it is possible to reduce the number of lenses of the module lens, thus making it possible to achieve a reduction in height of the module lens and higher resolution of the module lens.

In addition, the curved housing section 50 of the seating 5 may be formed in a curved shape in which a normal line of a curved surface coincides with respect to a principal light beam axis angle (CRA: Chief Ray Angle) of the module lens.

According to the seating 5 having such a shape, even in a case of a high image height, a principal light beam is vertically incident on the solid-state imaging element 2, thus making it possible to effectively suppress sensitivity loss due to vignetting (celare: vignetting) in the pixel 200P and degradation in image quality such as oblique light color mixture.

In addition, in the imaging device 1, the curved solid-state imaging element 2 may be fixed to the curved housing section 50 of the seating 5, and the infrared-absorbing filter 3 curved in a similar manner may be formed on the side of the light-receiving surface of the solid-state imaging element 2.

According to the imaging device 1 formed as described above, it is possible to eliminate dependence on an image height for an optical path difference in the infrared-absorbing filter 3, thus making it possible to effectively suppress color shading.

The solid-state imaging element 2 is fixed to the curved housing section 50 of the seating 5 without causing a crack. In accordance with the physical principle, a thinner semiconductor substrate (Si substrate) 21 of the base 20 allows the solid-state imaging element 2 to be formed in a curved shape more easily. In contrast, when handling the solid-state imaging element 2 as a sample, a possibility that the solid-state imaging element 2 is cracked is high.

For this reason, in reality, a thickness of the semiconductor substrate 21 is set to a range of 10 μm or more and 50 μm or less. Furthermore, the thickness of the semiconductor substrate 21 is preferably set to a range of 15 μm or more and 35 μm or less.

In a curved mounting method using the seating 5, the degree of difficulty varies widely depending on whether or not the solid-state imaging element 2 protrudes from an opening of the curved housing section 50 (whether the solid-state imaging element 2 is inside the curved housing section 50 or outside the curved housing section 50).

### (1) First Curved Mounting Method

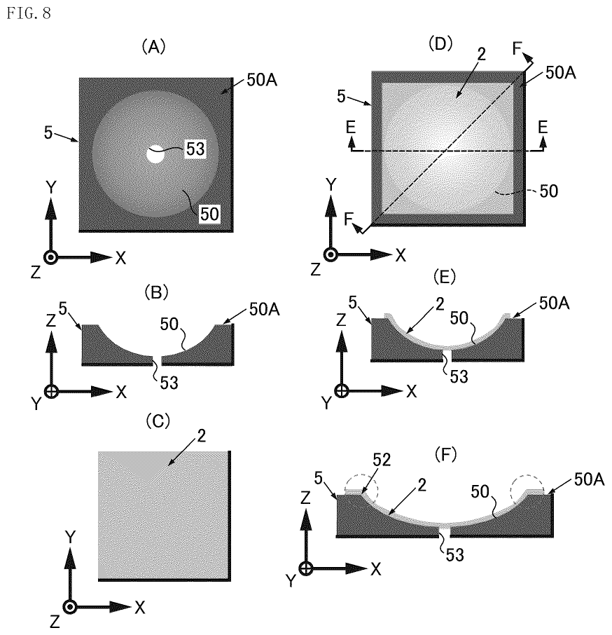

FIG. 8 is a step diagram illustrating a first curved mounting method in a case where a portion of the solid-state imaging element 2 protrudes from the curved housing section 50. (A) of FIG. 8 illustrates an example of a planar configuration of the seating 5 before mounting. (B) of FIG. 8 illustrates an example of a cross-sectional configuration of the seating 5 before the mounting. (C) of FIG. 8 illustrates an example of a planar configuration of the solid-state imaging element 2 before the mounting. (D) of FIG. 8 illustrates an example of a planar configuration of the imaging device 1 in which the solid-state imaging element 2 is mounted on the curved housing section 50 of the seating 5. (E) of FIG. 8 illustrates an example of a cross-sectional configuration of the imaging device 1 taken along a line E-E illustrated in (D) of FIG. 8. (F) of FIG. 8 illustrates an example of a cross-sectional configuration of the imaging device 1 taken along a line F-F illustrated in (D) of FIG. 8.

First, as illustrated in (A) of FIG. 8 and (B) of FIG. 8, the seating 5 is formed. The seating 5 includes the curved housing section 50.

Meanwhile, as illustrated in (C) of FIG. 8, the solid-state imaging element 2 is formed. The infrared-absorbing filter 3 is formed on the solid-state imaging element 2, or the infrared-absorbing filter 3 and the multilayer film filter 4 are formed on the solid-state imaging element 2, although detailed illustration is omitted.

Next, as illustrated in (D) of FIG. 8 to (F) of FIG. 8, the solid-state imaging element 2 is mounted in a curved shape on the curved housing section 50 of the seating 5.

At this time, as viewed in the arrow-Z direction (hereinafter, simply referred to as “in a plan view”) and in a side view, a portion of a peripheral edge of the solid-state imaging element 2 extending to the outside from the curved housing section 50 is bent along the front surface 50A of the seating 5. At a boundary edge 52 between the curved housing section 50 and the front surface 50A, stress concentration occurs on the solid-state imaging element 2.

The semiconductor substrate 21 of the solid-state imaging element 2 is thinned to have a thickness of 30 μm or less, and the mounting state is verified. As a result, a crack occurs in the semiconductor substrate 21 in a region of a curvature radius of 100 mm or less in the curved housing section 50, thus causing the imaging device 1 to be defective.

### (2) Second Curved Mounting Method

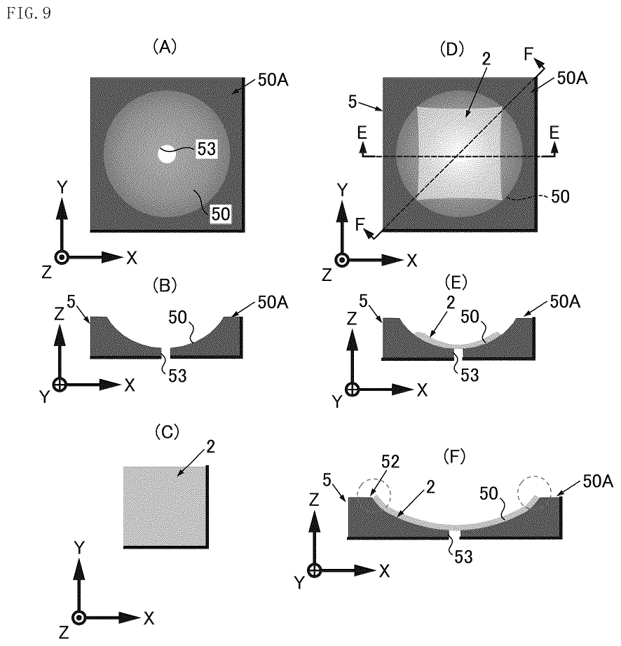

FIG. 9 is a step diagram illustrating a second curved mounting method in a case where the solid-state imaging element 2 is completely contained in the curved housing section 50. (A) of FIG. 9 illustrates an example of a planar configuration of the seating 5 before mounting. (B) of FIG. 9 illustrates an example of a cross-sectional configuration of the seating 5 before the mounting. (C) of FIG. 9 illustrates an example of a planar configuration of the solid-state imaging element 2 before the mounting. (D) of FIG. 9 illustrates an example of a planar configuration of the imaging device 1 in which the solid-state imaging element 2 is mounted on the curved housing section 50 of the seating 5. (E) of FIG. 9 illustrates an example of a cross-sectional configuration of the imaging device 1 taken along a line E-E illustrated in (D) of FIG. 9. (F) of FIG. 9 illustrates an example of a cross-sectional configuration of the imaging device 1 taken along a line F-F illustrated in (D) of FIG. 9.

First, as illustrated in (A) of FIG. 9 and (B) of FIG. 9, the seating 5 is formed. The seating 5 includes the curved housing section 50.

Meanwhile, as illustrated in (C) of FIG. 9, the solid-state imaging element 2 is formed. The solid-state imaging element 2 is formed relatively into a size that allows the solid-state imaging element 2 to be housed in the curved housing section 50. As with the first curved mounting method, the infrared-absorbing filter 3 is formed on the solid-state imaging element 2, or the infrared-absorbing filter 3 and the multilayer film filter 4 are formed on the solid-state imaging element 2, although detailed illustration is omitted.

Next, as illustrated in (D) of FIG. 9 to (F) of FIG. 9, the solid-state imaging element 2 is mounted in a curved shape on the curved housing section 50 of the seating 5.

At this time, in a plan view and in a side view, the solid-state imaging element 2 is contained in the curved housing section 50, and the solid-state imaging element 2 is formed entirely in a curved shape along the curved shape of the curved housing section 50. In other words, the peripheral edge of the solid-state imaging element 2 does not reach the boundary edge 52 and is not bent.

According to the imaging device 1 formed as described above, a crack does not occur in the semiconductor substrate 21 of the solid-state imaging element 2 even when the semiconductor substrate 21 is thinned to have a thickness of 30 μm or less and the curvature radius of the curved housing section 50 reaches a region of 15 mm or less. This allows for obtainment of non-defective imaging device 1.

### (3) Material of Seating 5

The seating 5 used for curved mounting is formed by a material for which a thermal load in a mounting process and a thermal variation in a market environment are taken into consideration. In other words, in order not to cause a stress due to a temperature change on the solid-state imaging element 2, the seating 5 is formed by a material that allows thermal expansion coefficients of the seating 5 and the solid-state imaging element 2 to be uniformized as much as possible.

For example, when the Si substrate is used for the semiconductor substrate 21 of the solid-state imaging element 2, the seating 5 is formed by Si. Si is optimum in that Si minimizes a thermal stress. In a case where Si is not used, it may be possible to form the seating 5 using a material having a thermal expansion coefficient close to the thermal expansion coefficient of Si of 4.15×10⁻⁶/° C.

In addition, in selecting the material of the seating 5, easiness in processing, material cost, processing cost, a seating weight, rigidity, seating thinning, and the like are taken into consideration. Specific examples of a practically available material of the seating 5 include an inorganic insulator, a semiconductor material, a metal material, a resin material, and a ceramic material.

The semiconductor material includes carbon (C), silicon carbide (SiC), or the like.

It may be possible to use, as the metal material, one or more metals selected from aluminum (Al), copper (Cu), brass, and titanium (Ti), or an alloy including one or more of the metals. The metal material is excellent in heat dissipation.

The resin material includes acrylic, polystyrene, polycarbonate, polypropylene, or the like. The resin material is excellent in cost reduction and weight reduction.

The ceramic material includes aluminum oxide (Al₂O₃), or the like. The ceramic material is high in cost, but is excellent in durability, heat dissipation, and the like.

### (4) Schematic Configuration of Curved Housing Section 50

In the seating 5, a surface structure of the curved housing section 50 is important. For example, when a protrusion is present on the curved surface of the curved housing section 50, stress concentration on the solid-state imaging element 2 occurs starting from the protrusion, thus causing the solid-state imaging element 2 to be easily damaged.

Even if the solid-state imaging element 2 is not damaged, the curved shape of the solid-state imaging element 2 is deformed due to the protrusion, which causes a deviation from the image-forming surface of the module lens by an amount of such deformation, thus resulting in degraded resolution.

Accordingly, a front surface of the curved shape of the curved housing section 50 is formed in a smooth front surface with no protrusion.

The smooth front surface may be formed using polishing processing, grinding processing, polishing buff processing, wheel processing, electrochemical polishing processing, or the like. The front surface of a region of the curved housing section 50 in contact with the solid-state imaging element 2 at least has a maximum roughness/height of 1 μm or less. Preferably, the maximum roughness/height is 0.5 μm or less. More preferably, the maximum roughness/height is 0.1 μm or Less.

Here, the maximum height/roughness is based on the definitions specified in the Japanese Industrial standards JIS B0601:2013.

### (5) First Configuration of Curved Housing Section 50 and Third Curved Mounting Method

FIG. 10 is a step diagram illustrating a third curved mounting method in which the solid-state imaging element 2 is mounted on the curved housing section 50 according to a first configuration. (A) of FIG. 10 illustrates an example of a planar configuration of the seating 5 before mounting. (B) of FIG. 10 illustrates an example of a cross-sectional configuration of the seating 5 before the mounting. (C) of FIG. 10 illustrates an example of a cross-sectional configuration of the imaging device 1 in which the solid-state imaging element 2 is mounted on the curved housing section 50 of the seating 5 by using a pressure difference due to depressurization. (D) of FIG. 10 illustrates an example of a cross-sectional configuration of the imaging device 1 in which the solid-state imaging element 2 is mounted on the curved housing section 50 of the seating 5 by using a pressure difference due to pressurization.

First, as illustrated in (A) of FIG. 10 and (B) of FIG. 10, the seating 5 is formed. The seating 5 includes the curved housing section 50. A ventilation section 53 is formed at a middle part close to a center position of the front surface 50A of the seating 5, in other words, at a middle part of the curved housing section 50. The ventilation section 53 is formed as a through-opening penetrating from the front surface 50A to a back surface 50B opposed to the front surface 50A.

Meanwhile, as illustrated in (C) of FIG. 9 for the second curved mounting method described above, the solid-state imaging element 2 is formed.

The solid-state imaging element 2 is placed on the curved housing section 50 of the seating 5 (see (C) of FIG. 10). Here, a vacuum device 600 is connected to the ventilation section 53 formed in the curved housing section 50 of the seating 5.

A gas leakproof film 601 is disposed on the surface of the solid-state imaging element 2. A gas is released by the vacuum device 600 through the ventilation section 53 from the inside of a cavity closed by the gas leakproof film 601, the solid-state imaging element 2, and the curved housing section 50. This causes the inside of the cavity to be depressurized, and, as illustrated in (C) of FIG. 10, the solid-state imaging element 2 is curved by a pressure difference along the curved shape of the curved housing section 50, and thus the solid-state imaging element 2 is mounted in the curved housing section 50.

In addition, the solid-state imaging element 2 is placed on the curved housing section 50 of the seating 5 (see (D) of FIG. 10). Here, a nozzle 610 is disposed at a position opposed in the arrow-Z direction to the curved housing section 50 of the seating 5.

The gas leakproof film 601 and the solid-state imaging element 2 are pressurized by a gas blown from the nozzle 610. As the gas, for example, air, an inert gas, or the like may be practically used. The nozzle 610 is connected to an unillustrated gas generation device. In a case where air is used as the gas, a compressor is used as the gas generation device.

As illustrated in (D) of FIG. 10, the solid-state imaging element 2 is curved by a pressure difference along the curved shape of the curved housing section 50, and thus the solid-state imaging element 2 is mounted in the curved housing section 50. At this time, the gas in the cavity is released through the ventilation section 53.

### (6) Second Configuration of Curved Housing Section 50

FIG. 11 is a step diagram illustrating the third curved mounting method in which the solid-state imaging element 2 is mounted on the curved housing section 50 according to a second configuration. (A) of FIG. 11 illustrates an example of a planar configuration of the seating 5 before mounting. (B) of FIG. 11 illustrates an example of a cross-sectional configuration of the seating 5 before the mounting.

First, as illustrated in (A) of FIG. 11 and (B) of FIG. 11, the seating 5 is formed. The seating 5 includes the curved housing section 50. The ventilation section 53 is formed at the middle part close to the center position of the front surface 50A of the seating 5, in other words, at the middle part of the curved housing section 50. The ventilation section 53 is formed as a through-opening penetrating from the front surface 50A to the back surface 50B, as with the curved housing section 50 according to the first configuration.

Furthermore, a porous (porous) material 54 is formed in an embedded state in the ventilation section 53. The porous material 54 is a material in which many fine holes are formed. More specifically, for example, the porous material 54 includes fine powder of Al₂O₃, stainless steel (SUS), or the like sintered in a breathable state.

Meanwhile, as illustrated in (C) of FIG. 9 for the second curved mounting method described above, the solid-state imaging element 2 is formed.

As with the third curved mounting method illustrated in (C) of FIG. 10 described above, the pressure difference due to the depressurization causes the solid-state imaging element 2 to be curved along the curved shape of the curved housing section 50 with use of such a seating 5, thus allowing the solid-state imaging element 2 to be mounted in the curved housing section 50.

In addition, as with the third curved mounting method illustrated in (D) of FIG. 10 described above, the pressure difference due to the pressurization causes the solid-state imaging element 2 to be curved along the curved shape of the curved housing section 50, thus allowing the solid-state imaging element 2 to be mounted in the curved housing section 50.

### (7) Third Configuration of Curved Housing Section 50 and Fourth Curved Mounting Method

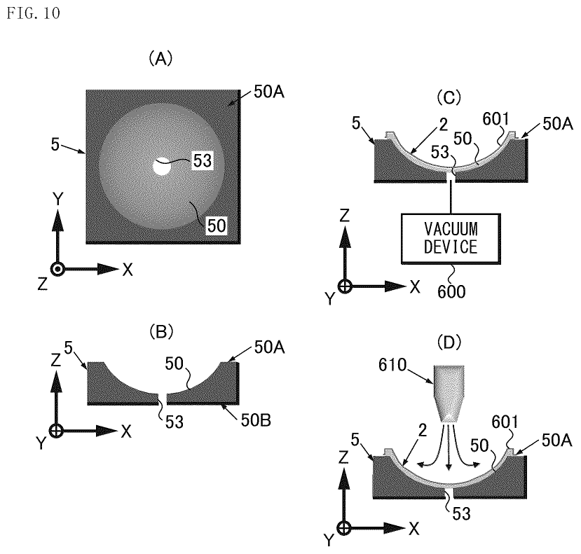

FIG. 12 is a step diagram describing a fourth curved mounting method in which the solid-state imaging element 2 is mounted on the curved housing section 50 according to a third configuration. (A) of FIG. 12 illustrates an example of a planar configuration of the seating 5 before mounting. (B) of FIG. 12 illustrates an example of a cross-sectional configuration of the seating 5 before the mounting. (C) of FIG. 12 illustrates an example of a cross-sectional configuration at the time when the solid-state imaging element 2 is placed on the curved housing section 50 of the seating 5. (D) of FIG. 12 illustrates an example of a cross-sectional configuration of the imaging device 1 in which the solid-state imaging element 2 is mounted on the curved housing section 50 of the seating 5.

First, as illustrated in (A) of FIG. 12 and (B) of FIG. 12, the seating 5 is formed. The seating 5 includes the curved housing section 50. A pocket 55 is formed around the middle part close to the center position of the front surface 50A of the seating 5. In a side view, the pocket 55 is formed in a groove shape that is further recessed from the surface of the curved housing section 50 in the incident direction of the incident light L. In addition, here, the pocket 55 is formed in a circular ring shape in a plan view, although the shape of the packet 55 is not particularly limited thereto. The pocket 55 takes in an excess of the adhesive 51 formed in the curved housing section 50 to effectively suppress or prevent spillover of the adhesive 51 from between the curved housing section 50 and the solid-state imaging element 2.

Meanwhile, as illustrated in (C) of FIG. 9 for the second curved mounting method described above, the solid-state imaging element 2 is formed.

As illustrated in (C) of FIG. 12, the adhesive 51 is formed in the curved housing section 50 of the seating 5, and, further, the solid-state imaging element 2 is placed on the curved housing section 50.

The pressing jig 6 illustrated in FIG. 3 described above is used to form the solid-state imaging element 2 in a curved shape along the curved shape of the curved housing section 50 by pressing the end part 60 of the pressing jig 6 against the solid-state imaging element 2 (see (D) of FIG. 12). After the solid-state imaging element 2 is adhered in the curved housing section 50 by the adhesive 51, pressing by the pressing jig 6 is released. Thus, the imaging device 1 in which the solid-state imaging element 2 is mounted on the seating 5 is formed.

### (8) Fourth Configuration of Curved Housing Section 50

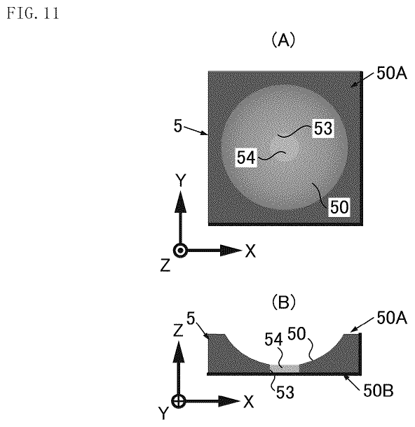

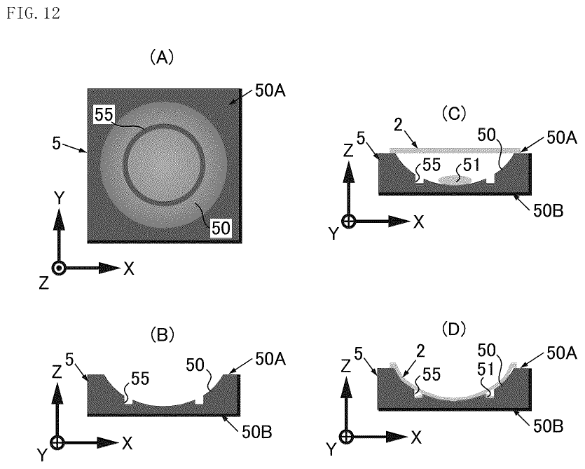

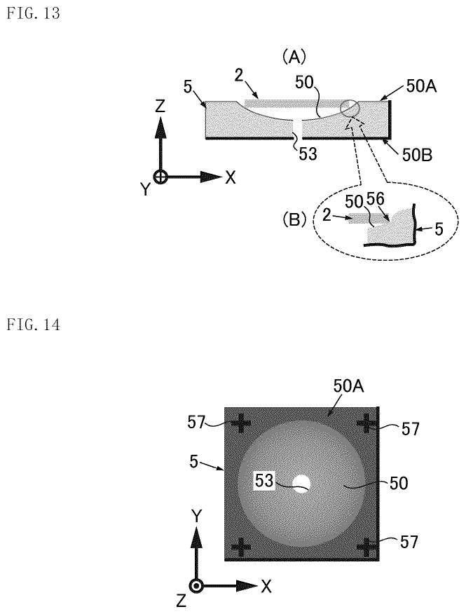

FIG. 13 is a step diagram describing a curved mounting method in which the solid-state imaging element 2 is mounted on the curved housing section 50 according to a fourth configuration. (A) of FIG. 13 illustrates an example of a cross-sectional configuration of the seating 5 and the solid-state imaging element 2 before mounting. (B) of FIG. 13 illustrates, in an enlarged manner, an example of a cross-sectional configuration of main parts of the seating 5 and the solid-state imaging element 2.

As illustrated in (A) of FIG. 13 and (B) of FIG. 13, a stepped part 56 is formed in the curved housing section 50 of the seating 5. The stepped part 56 is formed as a positioning guide that abuts a peripheral end of the solid-state imaging element 2 placed in the curved housing section 50 to perform positioning of the solid-state imaging element 2 with respect to the curved housing section 50.

According to the seating 5 configured as described above, it is possible to perform positioning of the solid-state imaging element 2 with respect to the curved housing section 50 easily and accurately by using the stepped part 56.

### (9) Fifth Configuration of Curved Housing Section 50

FIG. 14 illustrates an example of a planar configuration of a seating according to a fifth configuration.

As illustrated in FIG. 14, a mark 57 is formed in a peripheral part of the front surface 50A of the seating 5. The mark 57 is formed as an alignment mark to perform positioning of the curved housing section 50 of the seating 5 and the solid-state imaging element 2. Positioning of the mark 57 is performed with respect to an outline shape of the solid-state imaging element 2, for example.

According to the seating 5 configured as described above, the use of the mark 57 makes it possible to perform positioning of the solid-state imaging element 2 with respect to the curved housing section 50 easily and accurately.

It is to be noted that, in the seating 5, the ventilation section 53, the pocket 55, or the stepped part 56 described above in contact with the solid-state imaging element 2 has a rounding shape in which corner portions have roundness. It is possible, in a region having the rounding shape, to effectively suppress or prevent stress concentration that occurs on the solid-state imaging element 2 that is formed in a curved shape and subjected to the stress.

### [Overview of Method of Manufacturing Solid-state Imaging Element 2 and Method of Mounting Imaging Device 1]

Description is given next of an overview of a method of manufacturing the solid-state imaging element 2 according to the first configuration of the imaging device 1 and a method of mounting the imaging device 1.

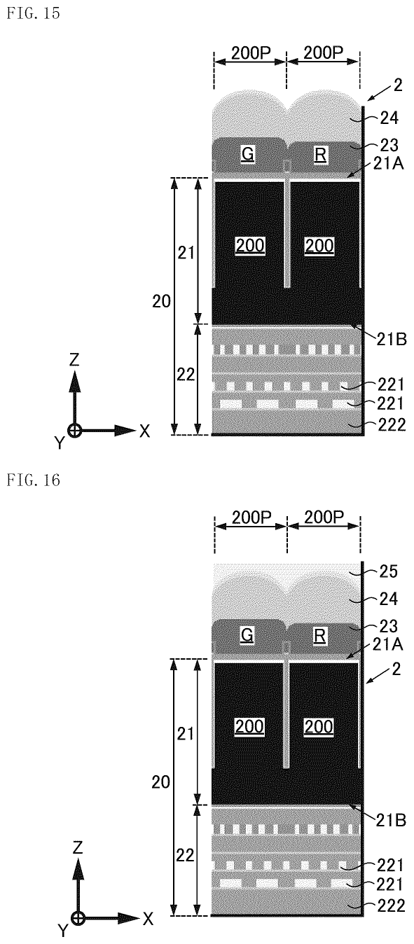

FIGS. 15 to 17 each illustrate an example of a cross-section in a step describing the method of manufacturing the solid-state imaging element 2. FIG. 18 illustrates an example of a cross-sectional configuration of the imaging device 1 in which the solid-state imaging element 2 is mounted on the seating 5.

The overview of the method of manufacturing the solid-state imaging element 2 according to the first configuration of the imaging device 1 is as follows. First, the wiring layer 22 is formed on the semiconductor substrate 21 including the photoelectric conversion region 200. Thus, the base 20 is formed (see FIG. 15).

Subsequently, the optical filter 23 is formed on a side of a light-receiving surface of the base 20, and the optical lens 24 is formed as illustrated in FIG. 15. When the optical lens 24 is formed, the solid-state imaging element 2 is substantially completed.

As illustrated in FIG. 16, the planarization film 25 is formed on the optical lens 24.

Thereafter, as illustrated in FIG. 17, the infrared-absorbing filter 3 is formed on the solid-state imaging element 2 with the planarization film 25 interposed therebetween.

The method of mounting the imaging device 1 is as follows.

As described above, the seating 5 including the curved housing section 50 is formed (see FIG. 18).

Subsequently, as illustrated in FIG. 18, the solid-state imaging element 2 including the infrared-absorbing filter 3 is mounted in a curved state in the curved housing section 50 of the seating 5. Thus, the imaging device 1 is completed that has, as a cavityless CSP (Chip Size Package), a light-condensing structure including an on-chip lens including a high refractive index material and a planarization film including a low refractive index material on the on-chip lens.

### [System Configuration of Imaging Device 1]

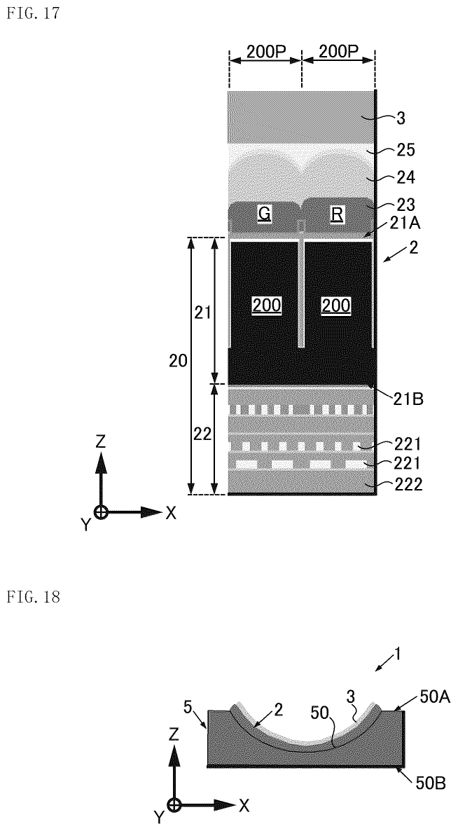

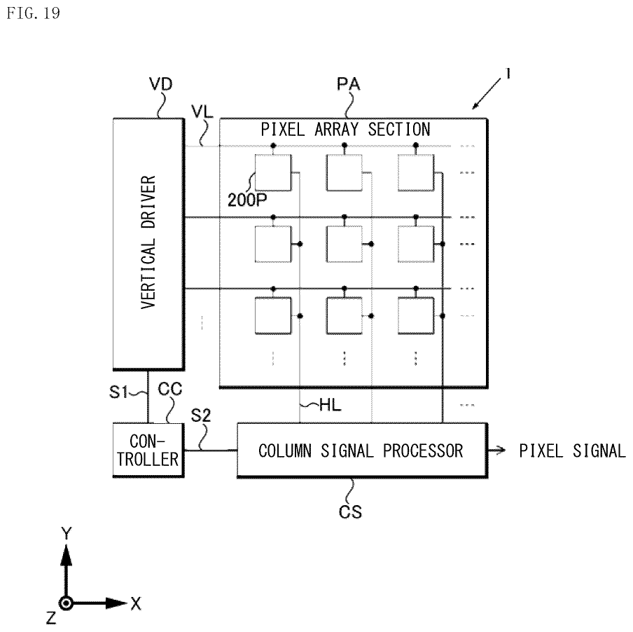

FIG. 19 illustrates an example of a system configuration of the imaging device 1. As illustrated in FIG. 19, the imaging device 1 includes a pixel array section PA, a vertical driver VD, a column signal processor CS, and a controller CC.

The pixel array section PA includes a plurality of pixels 200P arranged in a two-dimensional lattice form. As described above, the pixels 200P each include the photoelectric conversion region 200 (see FIG. 1, for example), and the photoelectric conversion region 200 converts the incident light L into an electric signal (electric charge).

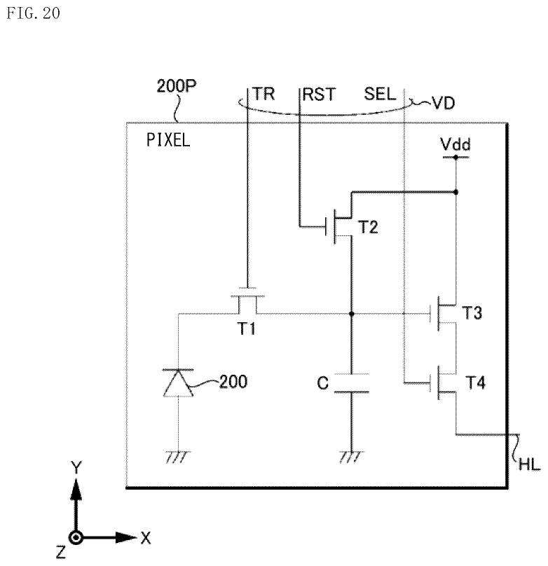

Here, an unillustrated pixel circuit (see FIG. 20) is included in the pixel 200P. The pixel circuit generates an image signal on the basis of the electric signal generated by the photoelectric conversion region 200. Generation of the image signal is controlled by a control signal generated by the vertical driver VD to be described later.

A plurality of signal lines VL and a plurality of signal lines HL are arranged in an XY matrix in the pixel array section PA.

The signal lines VL are each a signal line that transmits a control signal of the pixel circuit in the pixel 200P. Each of the signal lines VL is disposed for a corresponding one of rows of the pixel array section PA, and is wired in common with the pixels 200P arranged in the corresponding row.

The signal lines HL are each a signal line that transmits the image signal generated by the pixel circuit of the pixel 200P. Each of the signal lines HL is disposed for a corresponding one of columns of the pixel array section PA, and is wired in common with the pixels 200P arranged in the corresponding column.

The vertical driver VD generates the control signal of the pixel circuit of the pixel 200P. The vertical driver VD transmits the generated control signal to the pixel 200P through the signal line VL.

The column signal processor CS processes the image signal generated by the pixel 200P. The column signal processor CS processes the image signal transmitted from the pixel 200P through the signal line HL. Examples of processing in the column signal processor CS include analog-to-digital conversion processing in which the image signal as an analog signal generated by the pixel 200P is converted into an image signal as a digital signal. The image signal processed by the column signal processor CS is outputted as the image signal generated in the imaging device 1.

The controller CC controls the entirety of the imaging device 1. The controller CC generates and outputs a control signal for controlling the vertical driver VD and the column signal processor CS, and controls the imaging device 1. The control signal generated by the controller CC is transmitted to the vertical driver VD through a signal line S1, and is transmitted to the column signal processor CS through a signal line S2.

### [Circuit Configuration of Pixel 200P]

FIG. 20 illustrates an example of a circuit configuration of the pixel 200P of the solid-state imaging element 2.

As illustrated in FIG. 20, the pixel 200P of the solid-state imaging element 2 includes the photoelectric conversion region 200, a charge holding section C, and transistors T1 to T4. Here, the charge holding section C and the transistors T1 to T4 construct the pixel circuit.

The photoelectric conversion region 200 is configured by a photodiode including an anode region and a cathode region. The anode region is grounded. The cathode region is electrically coupled to one main electrode of the transistor T1.

The charge holding section C is configured by a capacitor that holds electric charge generated by photoelectric conversion in the photoelectric conversion region 200. One electrode of the charge holding section C is electrically coupled to the cathode region. Another electrode of the charge holding section C is grounded.

The transistors T1 to T4 are each formed by an insulated gate field effect transistor (IGFET: Insulated Gate Field Effect Transistor) including a pair of main electrodes and a gate electrode.

The transistor T1 is a transfer transistor that transfers, to the charge holding section C, the electric charge generated by photoelectric conversion in the photoelectric conversion region 200. The transistor T2 is a reset transistor that resets the electric charge held by the charge holding section C. The transistor T3 is an amplification transistor that generates an image signal on the basis of the electric charge held by the charge holding section C. The transistor T4 is a selection transistor that outputs the image signal to the signal line HL (see FIG. 19).

Another main electrode of the transistor T1 is electrically coupled to the one electrode of the charge holding section C, and is also electrically coupled to each of one main electrode of the transistor T2 and the gate electrode of the transistor T3. The gate electrode of the transistor T1 is electrically coupled to a transfer signal line TR.

Another main electrode of the transistor T2 is electrically coupled to a power supply line Vdd. The gate electrode of the transistor T2 is electrically coupled to a reset signal line RST.

One main electrode of the transistor T3 is electrically coupled to the power supply line Vdd. Another main electrode of the transistor T3 is electrically coupled to one main electrode of the transistor T4.

Another main electrode of the transistor T4 is electrically coupled to the signal line HL (see FIG. 19). The gate electrode of the transistor T4 is electrically coupled to a selection signal line SEL. The transfer signal line TR, the reset signal line RST, and the selection signal line SEL configure the signal line VL (see FIG. 19).

### [Specific Configuration of Pixel 200P of Solid-State Imaging Element 2]

FIG. 21 illustrates an example of a specific cross-sectional configuration of the solid-state imaging element 2 and the infrared-absorbing filter 3.

Here, the solid-state imaging element 2 illustrated in FIG. 21 is a back-illuminated solid-state imaging element. Accordingly, the first surface 21A of the semiconductor substrate 21 of the base 20 is disposed on the side of the arrow −Z direction. The second surface 21B of the semiconductor substrate 21 is disposed on a side opposite to the arrow −Z direction.

As described above, the infrared-absorbing filter 3 is disposed on the solid-state imaging element 2, and the pixel 200P includes the infrared-absorbing filter 3. That is, the pixel 200P includes the infrared-absorbing filter 3, the planarization film 25, an antireflection film 241, the optical lens 24, the optical filter 23, a protective film 232, a light-blocking film 231, an insulating film 206, a fixed charge film 205, the photoelectric conversion region 200, an element separation region 201, the semiconductor substrate 21, and the wiring layer 22.

The semiconductor substrate 21 is formed by, for example, a Si semiconductor substrate, as described above. The photoelectric conversion region 200 is disposed for each pixel 200P in the semiconductor substrate 21. In addition, at least the transistor (transfer transistor) T1 of the pixel circuit described above is disposed in the semiconductor substrate 21 (see FIG. 20). Here, the other transistors T2 to T4 of the pixel circuit are formed in an unillustrated base disposed separately from the base 20.

### (1) Configuration of Photoelectric Conversion Region 200

The photoelectric conversion region 200 is formed over an entire region in a thickness direction of the semiconductor substrate 21. More specifically, the photoelectric conversion region 200 includes an n-type semiconductor region as a first electrically-conductive type, and a p-type semiconductor region as a second electrically-conductive type that is disposed facing both of the first surface 21A and the second surface 21B of the semiconductor substrate 21. That is, the photoelectric conversion region 200 is configured by a pn-junction photodiode. The p-type semiconductor region also serves as a hole charge accumulation region, and is able to effectively suppress a dark current.

### (2) Configuration of Transistor T1

The p-type semiconductor region of the second surface 21B of the semiconductor substrate 21 is also used as a p-type well region. The transistor T1 is disposed in the p-type well region, although not illustrated here.

The pair of main electrodes of the transistor T1 are a source region and a drain region that are each formed by the n-type semiconductor region, and are formed in the p-type well region. A gate insulating film is formed on a surface (the second surface 21B) of the p-type well region between the pair of main electrodes. Furthermore, the gate electrode is formed in the gate insulating film.

### (3) Configuration of Optical Lens 24

The optical lens 24 condenses the incident light L on the photoelectric conversion region 200. This makes it possible to effectively suppress vignetting of the incident light L by the light-blocking film 231 disposed between the pixels 200P.

Here, the optical lens 24 is disposed for each pixel 200P.

The optical lens 24 is formed by, for example, one or more organic materials selected from a styrene-based resin, an acrylic-based resin, a styrene-acrylic-based resin, and a siloxane-based resin. In addition, it is possible to form the optical lens 24 by dispersing titanium oxide particles in the above-described organic materials or a polyimide-based resin.

Furthermore, the optical lens 24 may be formed by an inorganic material such as silicon nitride (SiN) or silicon oxynitride (SiON).

In addition, the antireflection film 241 having a refractive index different from a refractive index of the optical lens 24 is formed on a surface of the optical lens 24. The antireflection film 241 is able to effectively suppress or prevent reflection of the incident light L on the surface of the optical lens 24.

### (4) Configuration of Light-Blocking Film 231

The light-blocking film 231 is disposed in a region at a boundary between the pixels 200P on a side closer to the semiconductor substrate 21 than the optical lens 24. In other words, the light-blocking film 231 is disposed between the optical filters 23. The light-blocking film 231 blocks stray light of the incident light L leaking from an adjacent pixel 200P in the region at the boundary between the pixels 200P.

It is sufficient to adopt a material that blocks light for the light-blocking film 231. However, the light-blocking film 231 is formed by a material that has a strong light-blocking property and is finely processible. Here, examples of fine processing include accurate processing by etching.

The light-blocking film 231 is formed by, for example, one or more metal materials selected from Al, tungsten (W) and Cu. The light-blocking film 231 may be formed by one or more metal materials selected from silver (Ag), gold (Au), platinum (Pt), molybdenum (Mo), chromium (Cr), titanium (Ti), nickel (Ni), iron (Fe), and tellurium (Te), or an alloy material including any of these metal materials.

In addition, the light-blocking film 231 may be formed by staking a plurality of layers of the above-described materials.

In addition, in order to enhance adhesiveness with the underlying insulating film 206, an unillustrated barrier metal may be formed between the light-blocking film 231 and the insulating film 206.

For the barrier metal, for example, it is possible to use a metal material selected from Ti, tantalum (Ta), W, and cobalt (Co), or an alloy material including the metal material, a nitride material including the metal material, an oxide material including the metal material, or a carbide material including the metal material.

In addition, it is possible to use the light-blocking film 231 as a light-blocking film for an unillustrated pixel that determines an optical black level. In addition, it is possible to use the light-blocking film 231 as a light-blocking film for prevention of noise to a peripheral circuit region.

The light-blocking film 231 is preferably grounded. Such a grounding structure allows all of the light-blocking films 231 to be electrically coupled to each other, and allows the light-blocking films 231 to be grounded in a region outside an effective region. According to such a configuration, even if plasma damage is caused by accumulated electric charge during processing in a manufacturing step, it is possible to effectively suppress damage to the light-blocking film 231 and destruction of the light-blocking film 231.

### (5) Configuration of Optical Filter 23

The optical filter 23 is disposed for each pixel 200P or every two or more pixels 200P, and is a color filter that allows the incident light L in a specific wavelength region to pass therethrough. For example, the optical filter 23 is one color filter of color light selected from red light, green light, blue light, cyan light, magenta light, and yellow light.

The optical filter 23 is formed by adding a pigment or a dye to a resin material.

In addition, the optical filter 23 may be formed to have a film thickness that differs for each color, in consideration of color reproducibility by an optical spectrum or sensor sensitivity specifications.

### (6) Configuration of Insulating Film 206

The insulating film 206 is disposed between the optical filter 23 and the fixed charge film 205 that is formed on the first surface 21A of the semiconductor substrate 21. The insulating film 206 is able to effectively suppress deterioration in dark characteristics. In addition, a refractive index of the insulating film 206 is set to be lower than a refractive index of the fixed charge film 205, thus making it possible to effectively suppress reflection.

For the insulating film 206, it is possible to use, for example, silicon oxide (SiO₂) and a composite material containing SiO₂ as a main component. Specific examples of the composite material include SiON and silicon carbonate (SiOC).

### (7) Configuration of Protective Film 232

The protective film 232 is disposed between the optical filter 23 and the light-blocking film 231. The protective film 232 avoids generation of a mixing layer by contact between the resin material of the optical filter 23 and the metal material of the light-blocking film 231, or avoids a change in the mixing layer caused by a reliability test.

As with the insulating film 206, for the protective film 232, it is possible to use, for example, SiO₂ and a composite material containing SiO₂ as a main component.

### (8) Configuration of Fixed Charge Film 205

The fixed charge film 205 is disposed on the first surface 21A of the semiconductor substrate 21. The fixed charge film 205 has negative fixed electric charge due to an oxygen (O₂) dipole, and enhances pinning.

The fixed charge film 205 is formed by, for example, an oxide material or nitride material including one or more selected from hafnium (Hf), Al. zirconium (Zr). Tantalum (Ta), and Ti. The fixed charge film 205 is formed by a CVD method, a sputtering method, or an ALD method. The ALD method is preferably employed. In this case, it is possible to form SiO₂, which reduces an interface state, during film formation of the fixed charge film 205 in the same step.

In addition, it is possible to form the fixed charge film 205 by an oxide material or nitride material including one or more selected from lanthanum (La), cerium (Ce), neodymium (Nd), promethium (Pm), samarium (Sm), europium (Eu), gadolinium (Gd), terbium (Tb), dysprosium (Dy), holmium (Ho), thulium (Tm), ytterbium (Yb), lutetium (Lu), and yttrium (Y).

In addition, it is possible to use hafnium oxynitride (HfON) or aluminum oxynitride (AlON) for the fixed charge film 205.

In addition, it is possible to add Si or nitrogen (N) in an amount that does not impair an insulating property to the fixed charge film 205. In the fixed charge film 205 formed in such a manner, it is possible to improve heat resistance and the like.

The fixed charge film 205 is able to effectively prevent reflection for the semiconductor substrate 21 having a high refractive index by controlling a film thickness of the fixed charge film 205 or by stacking multiple layers.

### (9) Configuration of Element Separation Region 201

The element separation region 201 is disposed between the pixels 200P adjacent to each other in each of the arrow −X direction and the arrow −Y direction. The element separation region 201 electrically and optically separates the pixel 200P from another pixel adjacent to that pixel 200P.

The element separation region 201 is formed by, for example, a p-type semiconductor region, and is grounded here.

Alternatively, the element separation region 201 may be constructed by including a trench and an embedded member. The trench is formed in the semiconductor substrate 21, and the embedded member is embedded in the trench. One or more materials selected from the above-described fixed charge film 205 and the above-described insulating film 206 are used for the embedded member. According to the element separation region 201 using the insulating film 206 for the embedded member, a crosstalk caused by rolling of, for example, an electron as a carrier is blocked by the insulating film 206, which makes it possible to effectively suppress a light crosstalk by interfacial reflection resulting from a refractive index difference.

### (10) Configuration of Wiring Layer 22

The wiring layer 22 includes the plurality of wirings 221. The wirings 221 each transmit an image signal generated by the pixel 200P. In addition, the wirings 221 each transmit a signal to be supplied to the pixel circuit or a signal supplied from the pixel circuit. Specifically, the wirings 221 are each used for the signal line VL, the signal line HL, or the power supply line Vdd illustrated in FIG. 20 described above.

A via plug (a through wiring) allows for electrical coupling, for example, between the wirings 221 in different layers and between the wiring 221 and the pixel circuit, although detailed illustration is omitted in FIG. 21.

The wirings 221 are each formed by including, for example, one or more metal materials selected from Al and Cu. In addition, the via plug is formed by including, for example, one or more metal materials selected from W and Cu.

For example, an insulating material such as SiO₂ is used for the insulating film 222 of the wiring layer 22.

### (11) Configuration of Planarization Film 25

The planarization film 25 is formed to cover the optical lens 24, and reduces a step height shape caused by the optical lens 24. That is, a surface of the planarization film 25 is planarized. The planarization film 25 is formed by including, for example, one or more resin materials selected from a siloxane-based resin, a styrene-based resin, an acrylic-based resin and a styrene-acrylic copolymer-based resin. In addition, the planarization film 25 may be formed by, for example, an organic material such as an F-containing material of the selected resin material or a resin material in which the selected resin material is internally filled with beads having a refractive index lower than that of the resin material.

Furthermore, the planarization film 25 may be formed by one or more inorganic materials selected from SiO₂, niobium oxide (Nb₂O₅), tantalum oxide (Ta₂O₅), aluminum oxide (Al₂O₃), hafnium oxide (HfO₂), SiN, SiON, SiC, SiOC, SiNC, and zirconium oxide (ZrO2). In addition, the planarization film 25 may be formed by a stacked structure in which a plurality of layers of the selected inorganic material is stacked. A film of the inorganic material is formed by, for example, a CVD method or a sputtering method.

In a case where such an inorganic material is used, for example, a chemical mechanical polishing (CMP: Chemical Mechanical Polishing) method is used for planarization of the planarization film 25.

### (12) Configuration of Infrared-Absorbing Filter 3

FIG. 22 is a diagram illustrating a chemical formula of an organic material included in the infrared-absorbing filter 3.

An organic material including a cyanine pigment illustrated in FIG. 22 is used for the infrared-absorbing filter 3.

Here, R1 and R2 are each a chain or cyclic alkyl group; a group having one or two or more hydrogen atoms in the alkyl group substituted with at least one functional group of a halogen atom, an alkoxy group, an alkanoyloxy group, an amino group, a thiol group, and a mercapto group; a group having at least one reactive group of a vinyl group, an acrylic group, a carbonyl group, a carboxyl group, an alkenyl group, an alkenyloxy group, an alkoxycarbonyl group, a nitrile group, a carboxyl group, a carbonyl group, a sulfonyl group, a sulfamoyl group, a carbamoyl group, a benzoyloxy group, and a cyano group introduced to a terminal of an alkyl group or a position where two or more carbon atoms are away from an indoline ring; or a phenyl group or a benzyl group, and may be the same as or different from each other. In addition, X-represents an anion. It is to be noted that as for the organic material of this kind, refer to Japanese Unexamined Patent Application Publication No. 2015-203863.

### (13) Configuration of Other Base 250

Referring back to FIG. 21, as schematically illustrated, another base 250 is disposed on the wiring layer 22 of the base 20. For example, the pixel circuit illustrated in FIG. 20 described above, and logic circuits including, for example, the vertical driver VD, the column signal processor CS, and the controller CC illustrated in FIG. 19 described above are disposed in the other base 250. The other base 250 includes a semiconductor substrate and a wiring layer, as with the base 20. The base 20 and the other base 250 are electrically and mechanically coupled to each other by, for example, Cu-Cu junction.

In the imaging device 1 configured as described above, it is possible to vertically stack the base 20 and the other base 250 in the arrow −Z direction, thus making it possible to reduce a size of the imaging device 1.

In addition, the other base 250 may be formed as a support substrate that reinforces the base 20. In this case, the base 20 and the other base 250 are bonded to each other, for example, by a plasma bonding method or with an adhesive material.

### [Method of Manufacturing Solid-State Imaging Element 2]

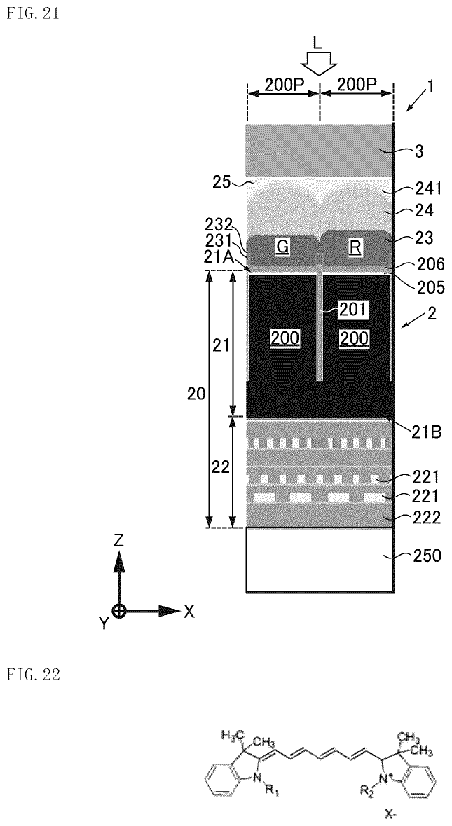

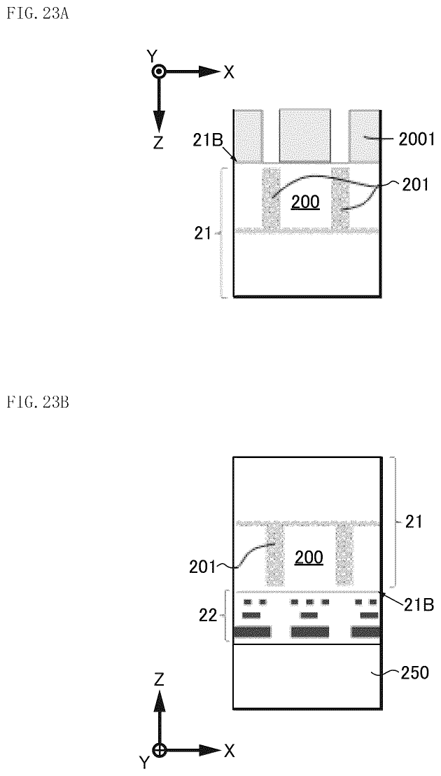

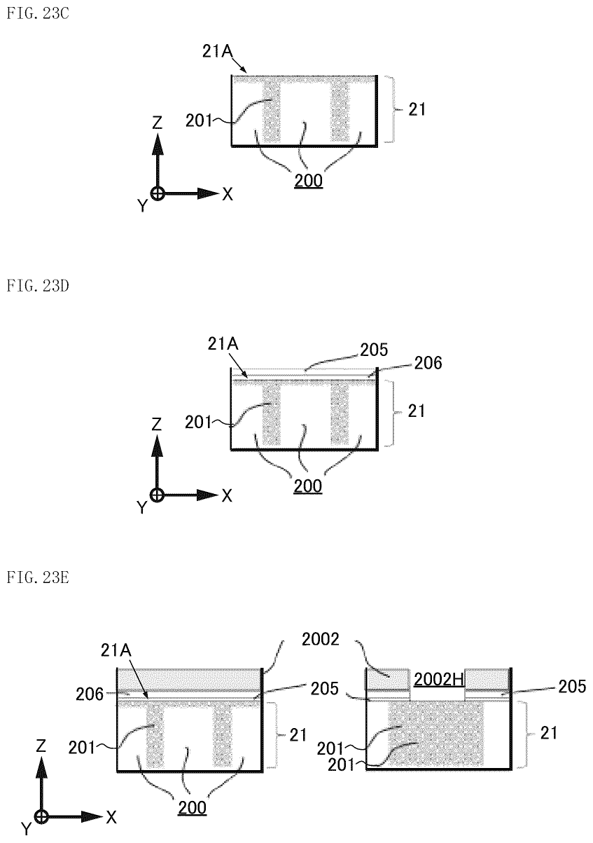

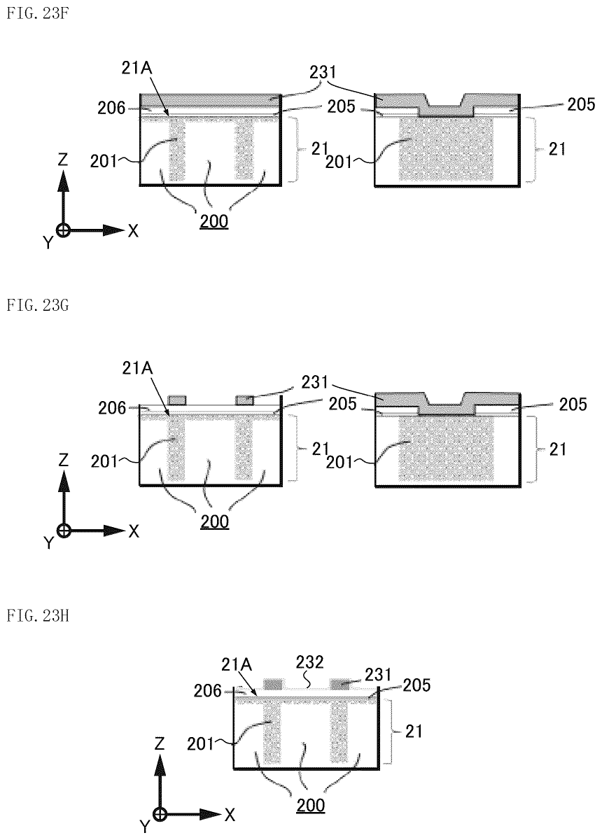

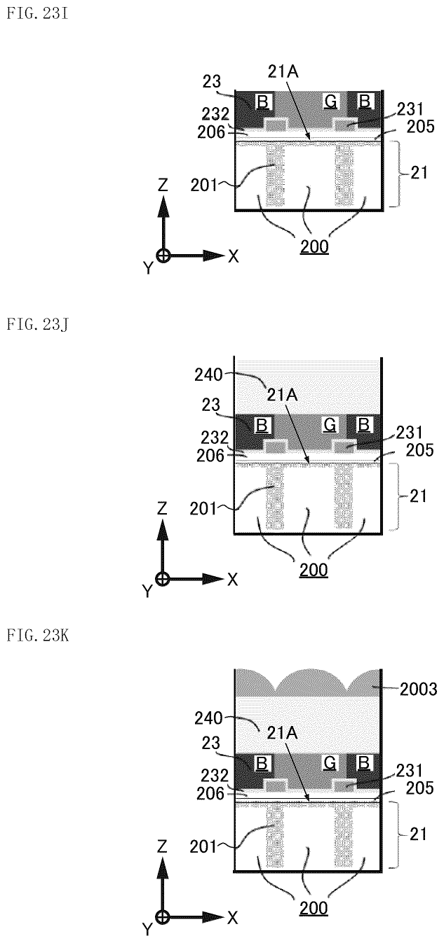

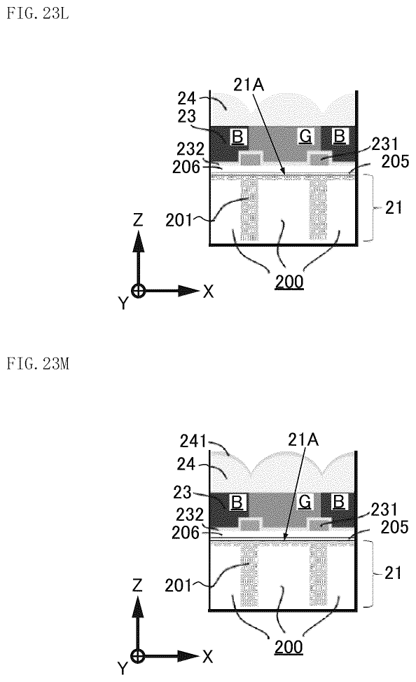

FIGS. 23A to 23O each illustrate an example of a cross-section in a step describing the method of manufacturing the solid-state imaging element 2 according to the first embodiment. The method of manufacturing the solid-state imaging element 2 is as follows.

In the solid-state imaging element 2, the photoelectric conversion region 200 is formed in a region where the pixel 200P of the semiconductor substrate 21 is to be formed, and the element separation region 201 is formed around a side surface of the photoelectric conversion region 200. The photoelectric conversion section 200 is formed by a pn junction including the n-type semiconductor region that is disposed throughout the entire region in the thickness direction of the semiconductor substrate 21 and the p-type semiconductor region that is in contact with the n-type semiconductor region and faces both of the first surface 21A and the second surface 21B of the semiconductor substrate 21.

First, the photoelectric conversion region 200 common to the plurality of pixels 200P is formed in the semiconductor substrate 21 (see FIG. 23A). Subsequently, a mask 2001 having an opening between the pixels 200P is formed on the side of the second surface 21B of the semiconductor substrate 21 (see FIG. 23A). For example, a resist is used for the mask 2001.

As illustrated in FIG. 23A, the element separation region 201 is formed by introducing a p-type impurity into the semiconductor substrate 21 with use of the mask 2001. For example, an ion implantation method is used to introduce the impurity. When the element separation region 201 is formed, the photoelectric conversion regions 200 individually separated from each other by the element separation region 201 are formed.

Here, although not illustrated, at least the transistor T1 of the pixel circuit is formed on the second surface 21B of the semiconductor substrate 21 (see FIG. 20). The transistor T1 includes the pair of main electrodes, the gate insulating film, and the gate electrode, as described above.

Next, the wiring layer 22 is formed on the side of the second surface 21B of the semiconductor substrate 21 (see FIG. 23B). The wiring layer 22 includes the plurality of wirings 221, the insulating film 222, and the unillustrated via plug, as described above. An frontmost surface of the wiring layer 22 is planarized by, for example, a CMP method.

As illustrated in FIG. 23B, the semiconductor substrate 21 is flipped vertically, and the semiconductor substrate 21 is bonded to the other base 250 with the wiring layer 22 interposed therebetween. Here, the other base 250 is used as a support substrate that reinforces the semiconductor substrate 21. The other base 250 is bonded to the wiring layer 22 by, for example, a plasma bonding method.

It is to be noted that in the following description, illustration of the wiring layer 22 and the other base 250 is omitted.

As illustrated in FIG. 23C, the semiconductor substrate 21 is thinned by polishing on a side of the first surface 21A of the semiconductor substrate 21. The thinning is performed by, for example, wet etching or dry etching, and then further performed by a CMP method until reaching a desired thickness. The semiconductor substrate 21 is formed to have, for example, a thickness of 2 μm or more and 6 μm or less when only a visible light region is included.

As illustrated in FIG. 23D, the fixed charge film 205 and the insulating film 206 are sequentially formed on the first surface 21A of the semiconductor substrate 21. The fixed charge film 205 and the insulating film 206 are each formed using, for example, a CVD method, a sputtering method, or an ALD method.

When the ALD method is employed to form the fixed charge film 205, in a portion of the fixed charge film 205 in contact with the first surface 21A of the semiconductor substrate 21, favorable step coverage is achieved at an atomic layer level.

For example, SiO₂ is used for the insulating film 206, and the ALD is similarly employed to form the insulating film 206. At this time, the insulating film 206 is formed to have at least a thickness of 20 nm or more and 50 nm or less, because the insulating film 206 having a thinner film thickness is likely to undergo film detachment caused by a blister phenomenon.

Next, the mask 2002 is formed on the insulating film 206 (see FIG. 23E). For example, a resist is used for the mask 2002. The mask 2002 is formed to cover the pixel array section PA (see a left side of FIG. 23E). In addition, the mask 2002 has an opening 2002H at a position overlapping the element separation region 2001 in a region outside the pixel array section PA (see a right side of FIG. 23E).

As illustrated in FIG. 23E, the insulating film 206 and the fixed charge film 205 exposed from the opening 2002H are removed with use of the mask 2002 to form an opening 205H. The opening 205H causes the element separation region 201 in the region outside the pixel array section PA to be exposed. Anisoropic etching or wet etching is used to form the opening 205H. Although not illustrated, the opening 205H is formed to have a width of several micrometers in a plan view.

Thereafter, the mask 2002 is removed.

It is to be noted that in FIGS. 23F and 23G to be described later, as in FIG. 23E, the pixel array section PA and the region outside the pixel array section PA are illustrated.

As illustrated in FIG. 23F, the light-blocking film 231 is formed on the insulating film 206. The light-blocking film 231 is formed by the above-described metal material or the above-described alloy material by a CVD method or a sputtering method. A portion of the light-blocking film 231 is coupled to the element separation region 201 in the region outside the pixel array section PA through the opening 205H.

When the element separation region 201 is, for example, grounded, it is possible to effectively suppress plasma damage that is caused when processing the light-blocking film 231.

As illustrated in FIG. 23G, the light-blocking film 231 is subjected to patterning processing in the pixel array section PA. That is, the light-blocking film 231 in a region overlapping the photoelectric conversion region 200 is removed. In addition, although not illustrated, the light-blocking film 231 formed in a pad section, a scribe line section, or the like is removed in the same step. For example, anisotropic etching is used for the patterning processing. In addition, a residue is removed by chemical washing, as needed.

As illustrated in FIG. 23H, the protective film 232 is formed on the light-blocking film 231. A transparent inorganic film, e.g., SiO₂ is used for the protective film 232.

Forming the protective film 232 makes it possible to effectively suppress or prevent transformation caused by contact between a film provided on the light-blocking film 231, e.g., the resin material of the optical filter 23 and the metal material of the underlying light-blocking film 231. In addition, in a case where a film on the protective film 232 needs to be detached due to a light exposure trouble or due to formation of a nonstandard color filter, the protective film 232 protects the metal of the light-blocking film 231 from a detaching chemical solution, or the like.

As illustrated in FIG. 23I, the optical filter 23 is formed on the protective film 232. For example, a film of a resist including a photosensitizing agent and a pigment or a dye is formed by a spin-coating method, and light exposure, development, and post-baking are performed on the film to form the optical filter 23.

In addition, in a case where a dye resist is used, ultraviolet (UV) cure or additional baking may be performed to form the optical filter 23.

As illustrated in FIG. 23J, a lens material 240 of the optical lens 24 is formed. The optical lens 24 condenses light with a refractive index difference from the planarization film 25; therefore, a material having a high refractive index is used for the lens material 240.

For example, an organic resin material such as a styrene-based resin (a refractive index n: about 1.6), an acrylic-based resin (n: about 1.5), or a styrene-acrylic copolymer-based resin (n: 1.5 to 1.6) is used for the lens material 240. A film of the organic resin material is formed by spin coating.

Alternatively, an organic-inorganic hybrid material in which TiO fine particles are dispersed in the above-described organic resin or a polyimide resin may be used for the lens material 240. Alternatively, an inorganic material such as SiN (n: about 1.9 to 2) or SiON (n: about 1.45 to 1.9) may be used for the lens material 240. A film of the inorganic material is formed by, for example, a CVD method.

As illustrated in FIG. 23K, a mask 2003 is formed on the lens material 240. A resist is used for the mask 2003. The mask 2003 is formed in a lens shape through respective steps of light exposure and reflow.

As illustrated in FIG. 23L, the shape of the mask 2003 is transferred to the lens material 240 with use of the mask 2003 to form the optical lens 24 from the lens material 240. For example, anisoropic etching is used to transfer the shape.

Subsequently, as illustrated in FIG. 23M, the antireflection film 241 is formed on the surface of the optical lens 24. The antireflection film 241 has a refractive index different from the refractive index of the optical lens 24. The antireflection film 241 makes it possible to improve light reception sensitivity, and further makes it possible to effectively suppress or prevent flare. More specifically, for example, SiON having a refractive index of about 1.45 to 1.9 is used for the antireflection film 241, and coating with the antireflection film 241 is performed in an antireflection design conforming to 4/λ rule. In addition, the antireflection film 241 is not limited to a single-layer film, and may be formed by a plurality of layers.

The formation of the antireflection film 241 makes it possible to reduce an area of a planar ineffective region of a diagonal part where no curved surface of the optical lens 24 is formed.

As illustrated in FIG. 23M, the planarization film 25 is formed on the optical lens 24. The planarization film 25 is formed by the organic material, the inorganic material, or the like, as described above.

In a case where the inorganic material is used for the planarization film 25, the surface of the planarization film 25 is formed in a step height shape following the shape of the optical lens 24. Accordingly, the surface of the planarization film 25 is planarized by, for example, a CMP method. At this time, the optical lens 24 is formed thick, which prevents an upper end of the optical lens 24 from being polished.

As illustrated in FIG. 23O, the infrared-absorbing filter 3 is formed on the planarization film 25. The infrared-absorbing filter 3 is formed by, for example, an organic material including a cyanine pigment, a binder resin, or the like. The infrared-absorbing filter 3 is formed by coating using one or more methods selected from a spin coating method, a die coating method, a slit coating method, and a dispensing method.

When such a series of steps is completed, the method of manufacturing the solid-state imaging element 2 and the infrared-absorbing filter 3 is completed.

### [Press Type Curved Mounting Method]

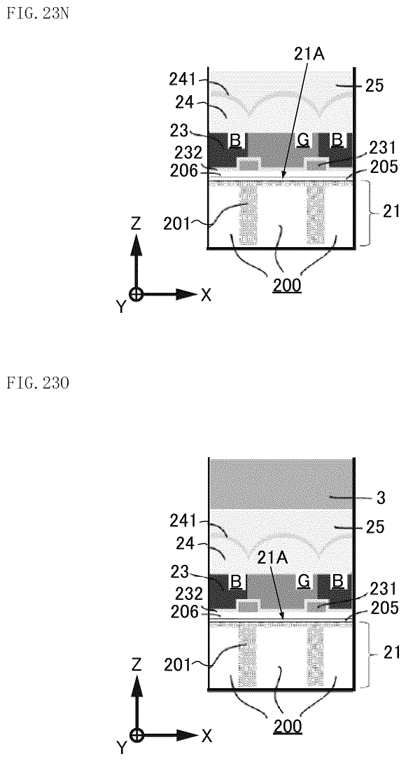

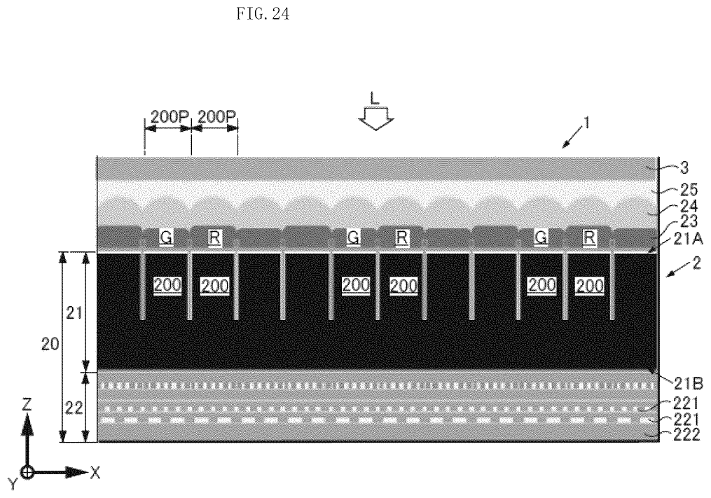

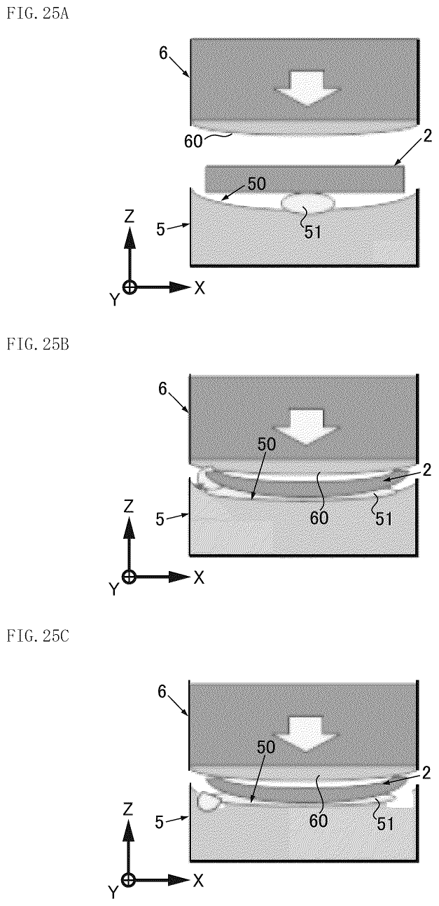

FIG. 24 illustrates an example of a cross-sectional configuration of the solid-state imaging element 2 and the infrared-absorbing filter 3 that are to be used for a press type curved mounting method. FIG. 25A illustrates an example of a cross-section in a first step describing the press type curved mounting method. FIGS. 25B and 25C each illustrate an example of a cross-section in a second step. FIG. 26A illustrates an example of a schematic cross-section including the pressing jig 6 in a step in the press type curved mounting method. FIG. 26B illustrates an example of the seating 5, the solid-state imaging element 2, and the infrared-absorbing filter 3 as viewed from an oblique direction.

The press type curved mounting method is as follows.

First, as illustrated in FIG. 24, the solid-state imaging element 2 including the infrared-absorbing filter 3 is formed. Detailed configurations of the infrared-absorbing filter 3 and the solid-state imaging element 2 and the method of manufacturing the infrared-absorbing filter 3 and the solid-state imaging element 2 are as described above.

Next, the seating 5 is prepared, and the solid-state imaging element 2 including the infrared-absorbing filter 3 is disposed at a position corresponding to the curved housing section 50 of the seating 5 (see FIG. 25A). The curved surface of the curved housing section 50 of the seating 5 has a configuration in which the CRA is incident vertically at any image height in a manner corresponding to an optical design of an unillustrated module lens.

In addition, the adhesive 51 is formed in the curved housing section 50. The adhesive 51 may be applied to the solid-state imaging element 2 on the side of the second surface 21B.

Here, the pocket 55 may be formed in the curved housing section 50 of the seating 5 (see FIG. 12). The pocket 55 effectively suppresses or prevents spillover of the adhesive 51. In addition, the stepped part 56 may be formed in the curved housing section 50 (see FIG. 13). The stepped part 56 allows for accurate positioning of the curved housing section 50 and the solid-state imaging element 2. Furthermore, the mark 57 may be formed in the seating 5 (see FIG. 14). The mark 57 allows for accurate positioning of the curved housing section 50 and the solid-state imaging element 2.

As illustrated in FIG. 25A, the pressing jig 6 is placed on the curved housing section 50 of the seating 5 with the solid-state imaging element 2 and the infrared-absorbing filter 3 interposed therebetween, and press-mounting by the pressing jig 6 starts. As illustrated in FIGS. 25A and 26A, the pressing jig 6 is provided with the end part 60 with a curved shape that protrudes on the side opposite to the arrow-Z direction (in the incident direction of the incident light L).

Here, a protective film may be interposed between the infrared-absorbing filter 3 and the end part 60 of the pressing jig 6. In this case, the protective film makes it possible to effectively suppress or prevent occurrence of a scar on the surface of the infrared-absorbing filter 3 or the solid-state imaging element 2.

Alternatively, a curved sensor 65 may be adopted instead of the protective film, as illustrated in FIGS. 26A and 26B. In a case where the curved sensor 65 is adopted, it is possible to perform monitoring of an appropriate stress when the solid-state imaging element 2 and the infrared-absorbing filter 3 are each formed in a curved shape.

As illustrated in FIG. 25B or FIG. 25C, the adhesive 51 is cured while the end part 60 of the pressing jig 6 is pressed against the infrared-absorbing filter 3 and the solid-state imaging element 2. Thus, the solid-state imaging element 2 and the infrared-absorbing filter 3 in a state of being formed in the curved shape are fixed to the curved housing section 50 of the seating 5.

A step illustrated in FIG. 25C illustrates an example in which the pocket 55 is formed in the curved housing section 50 of the seating 5. The packet 55 takes in the excess of the adhesive 51. Meanwhile, a step illustrated in FIG. 25B illustrates an example in which no pocket 55 is formed in the curved housing section 50 of the seating 5.

For example, one or more resin adhesives selected from an epoxy-based resin, an acrylic-based resin, and a cyan-based resin are used for the adhesive 51. It is possible to use a resin adhesive of a cured type such as an ultraviolet (UV)-cured type, a thermally-cured type, or a time-cured type for the adhesive 51, and the cured type is not particularly limited.

In a case of adopting the resin adhesive of the UV-cured type for the adhesive 51, the seating 5 is formed by a material that allows UV light to pass therethrough. In addition, the adhesive 51 is irradiated with UV light when the end part 60 of the pressing jig 6 is pressed against the infrared-absorbing filter 3 and the solid-state imaging element 2.

It is to be noted that the cured type of the adhesive 51 is not limited to the UV-cured type.

In addition, the adhesive 51 may be replaced with a die attach film (DAF: Die Attach Film).

Thereafter, pressing by the pressing jig 6 is finished, and the pressing jig 6 is moved in the arrow-Z direction. In a case where the protective film is used, the protective film is removed.

Here, when the pocket 55 is formed in the curved housing section 50 of the seating 5, an end part of the pocket 55 is formed in a rounding shape as described above to effectively suppress or prevent occurrence of stress concentration.

In addition, although not illustrated, an underfill material may be formed on a side surface of the solid-state imaging element 2. The underfill material is able to reduce a possibility of breakage of the solid-state imaging element 2 even if an impact or the like occurs on the solid-state imaging element 2.

Although the press type curved mounting method has been described above, the step illustrated in (C) of FIG. 10 described above may be combined. That is, the gas leakproof film 601 may be adopted, and a gas may be released from the inside of the cavity through the ventilation section 53 to mount the solid-state imaging element 2 in the curved housing section 50 by a pressure difference. The cavity is closed by the gas leakproof film 601, the solid-state imaging element 2, and the curved housing section 50.

In addition, the step illustrated in (D) of FIG. 10 may be combined. That is, the gas leakproof film 601 may be adopted, and the gas leakproof film 601 and the solid-state imaging element 2 may be pressurized by a gas blown from the nozzle 610 to mount the solid-state imaging element 2 in the curved housing section 50 by a pressure difference.

According to the imaging device 1 adopting the press type curved mounting method, the configuration of the unillustrated module lens becomes simple. Specifically, it is possible to reduce the number of lenses of the module lens. In addition, it is possible to achieve a decrease in height of the module lens. Furthermore, it is possible to achieve higher resolution of the module lens.

In addition, according to the imaging device 1, dependence on the image height for the optical path difference in the infrared-absorbing filter 3 is eliminated, which makes it possible to effectively suppress or prevent degradation in image quality at the field angle end.

In addition, according to the imaging device 1, it is possible to omit the infrared cut filter on a side of the unillustrated module lens, which makes it possible to reduce reflection surfaces of the infrared cut filter and reduce fabrication cost. The reflection surfaces of the infrared cut filter may cause flare or ghost.

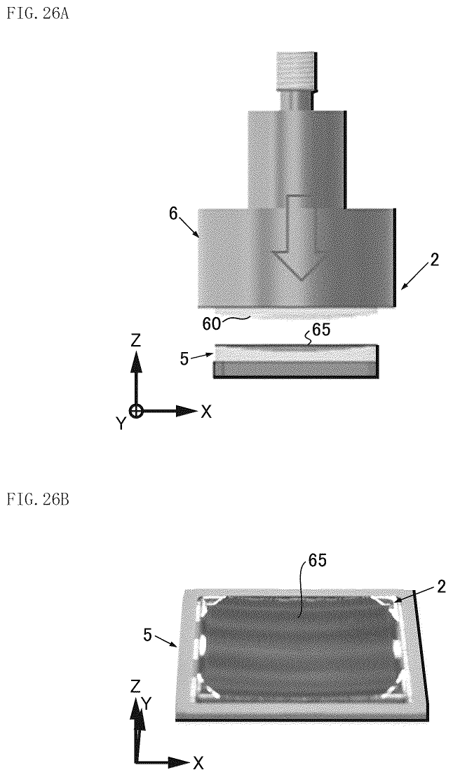

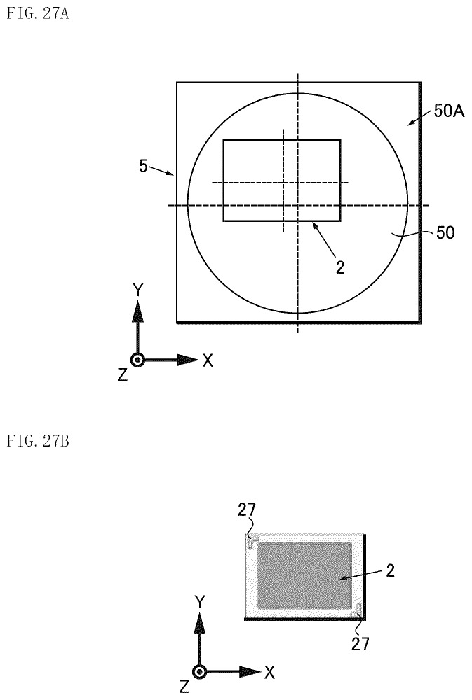

FIG. 27A illustrates an example of a planar configuration of the curved housing section 50 of the seating 5 in which the solid-state imaging element 2 is mounted. FIG. 27B illustrates an example of a planar configuration of the solid-state imaging element 2.

As with the second curved mounting method illustrated in FIG. 9 described above, as illustrated in FIG. 27A, the solid-state imaging element 2 is formed in a shape and a size that each allow the solid-state imaging element 2 to be housed in the curved housing section 50 of the seating 5 in a plan view.

In addition, as illustrated in FIG. 27B, the solid-state imaging element 2 may be formed in a rectangular shape in a plan view. A mark (an alignment mark) 27 to be used for positioning is disposed in a peripheral part of the solid-state imaging element 2. The mark 27 is positioned with respect to, for example, the mark 57 of the seating 5 illustrated in FIG. 14 described above.

### [Pressure Difference Type Curved Mounting Method]

### (1) Depressurization Type Curved Mounting Method

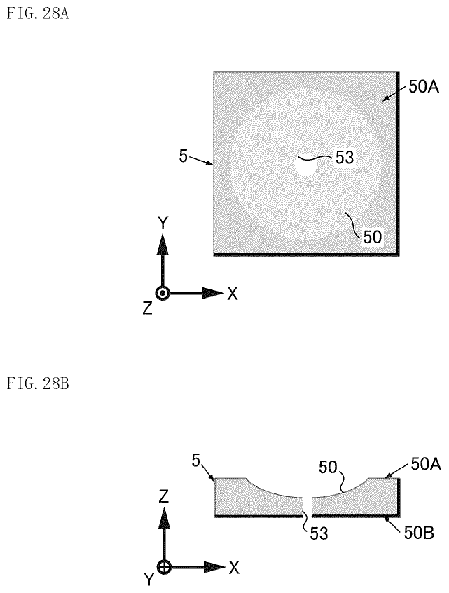

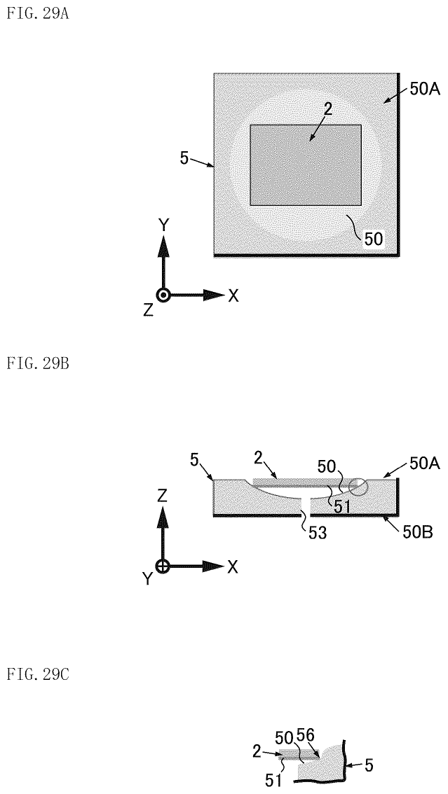

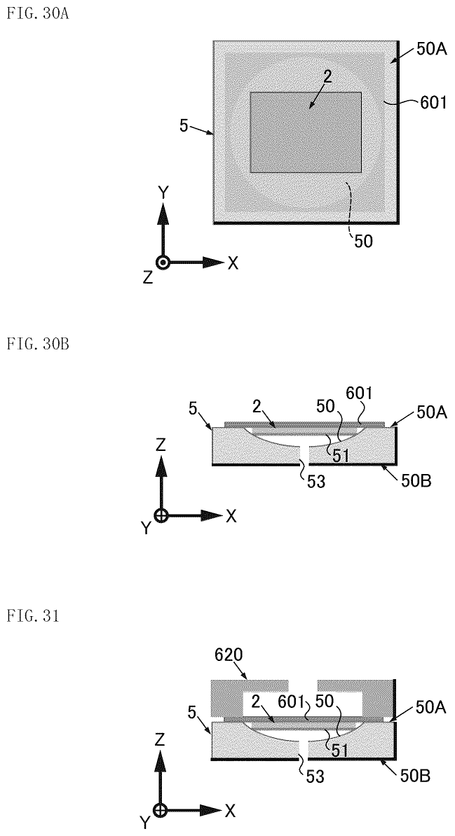

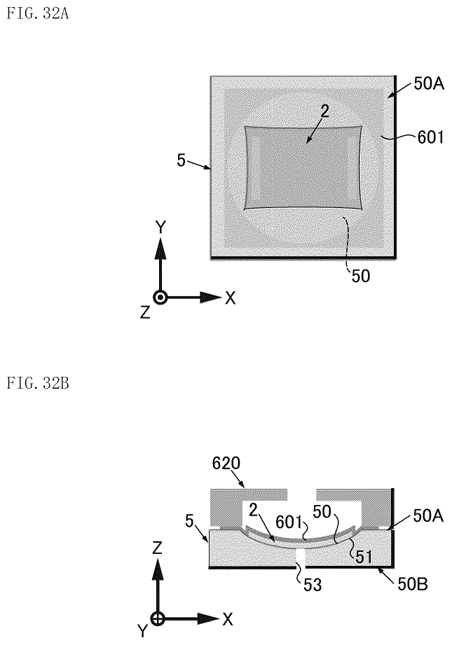

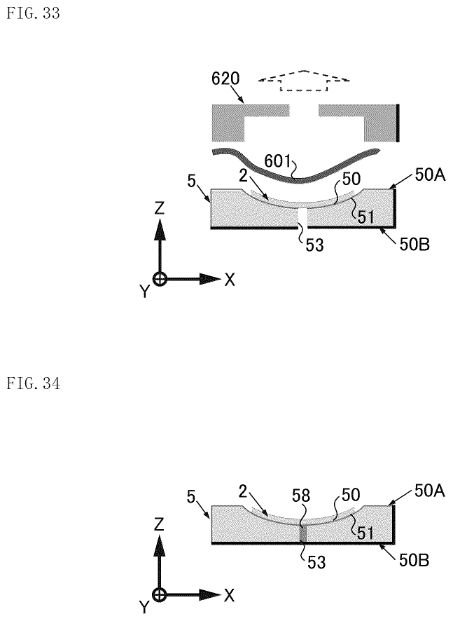

FIGS. 28 to 34 each illustrate an example of each step describing a depressurization type curved mounting method of a pressure difference type curved mounting method.
FIG. 28A illustrates an example of a planar configuration of the seating 5, and FIG. 28B illustrates an example of a cross-sectional configuration of the seating 5. FIG. 29A illustrates an example of a planar configuration of the seating 5 on which the solid-state imaging element 2 is placed. FIG. 29B illustrates an example of a cross-sectional configuration of the seating 5 on which the solid-state imaging element 2 is placed. Furthermore, FIG. 29C illustrates, in an enlarged manner, an example of a cross-sectional configuration of a main part of the seating 5. FIG. 30A illustrates an example of a planar configuration of the seating 5 on which the gas leakproof film 601 is mounted. FIG. 30B illustrates an example of a cross-sectional configuration of the seating 5 on which the gas leakproof film 601 is mounted. FIG. 31 illustrates an example of a cross-sectional configuration of the seating 5 on which a collet 620 is mounted. FIG. 32A illustrates an example of a planar configuration of the seating 5 in a depressurization state. FIG. 32B illustrates an example of a cross-sectional configuration of the seating 5 in the depressurization state. FIG. 33 illustrates an example of a cross-sectional configuration of the seating 5 after finishing of curved mounting. FIG. 34 illustrates an example of a cross-sectional configuration of the imaging device 1 after the finishing of the curved mounting.

The depressurization type curved mounting method is as follows.

First, as illustrated in FIGS. 28A and 28B, the seating 5 is prepared. As described above, the seating 5 includes the curved housing section 50, and the ventilation section 53 is formed in the curved housing section 50. The curved surface of the curved housing section 50 of the seating 5 has a configuration in which the CRA is incident vertically at any image height in a manner corresponding to the optical design of the unillustrated module lens. The ventilation section 53 has a configuration similar to that of the ventilation section 53 illustrated in (A) of FIG. 10 and (B) of FIG. 10 described above.

As illustrated in FIGS. 29A and 29B, the solid-state imaging element 2 including the infrared-absorbing filter 3 is disposed at a position corresponding to the curved housing section 50 of the seating 5. Detailed configurations of the infrared-absorbing filter 3 and the solid-state imaging element 2 and the method of manufacturing the infrared-absorbing filter 3 and the solid-state imaging element 2 are as described above.

Here, as illustrated in FIG. 29C, the stepped part 56 is formed in the curved housing section 50 (see FIG. 13), and the solid-state imaging element 2 is positioned with respect to an inside of the curved housing section 50 by the stepped part 56.

In addition, although not illustrated, as with the step illustrated in FIG. 25A described above, the adhesive 51 is formed in the curved housing section 50. The adhesive 51 may be applied to the solid-state imaging element 2 on the side of the second surface 21B. In addition, the adhesive 51 may be replaced with a DAF.

As illustrated in FIGS. 30A and 30B, the gas leakproof film 601 that covers the entirety of the curved housing section 50 is disposed on the front surface 50A of the seating 5 with the solid-state imaging element 2 and the infrared-absorbing filter 3 interposed therebetween.

As illustrated in FIG. 31, the collet 620 is mounted on the seating 5 with the gas leakproof film 601 interposed therebetween, and the gas leakproof film 601 is pressed against the seating 5. Thus, the solid-state imaging element 2 and the infrared-absorbing filter 3 are housed in a sealed state in the curved housing section 50 covered with the gas leakproof film 601.

As illustrated in FIGS. 32A and 32B, a pressure in the curved housing section 50 is reduced through the ventilation section 53 connected to the vacuum device 600 (see (C) of FIG. 10). This generates a pressure difference, which causes the solid-state imaging element 2 and the infrared-absorbing filter 3 to be curved along the curved shape of the curved housing section 50, and thus the solid-state imaging element 2 is mounted in the curved housing section 50. It is to be noted that the curved shape of the solid-state imaging element 2 is maintained by curing of the unillustrated adhesive 51. The specific material and curing type of the adhesive 51 are as described above.

As illustrated in FIG. 33, the collet 620 is pulled up, and the gas leakproof film 601 is removed.

As illustrated in FIG. 34, an inside of the ventilation section 53 of the seating 5 is filled with an embedded member 58. The embedded member 58 makes it possible to effectively suppress or prevent a phenomenon of reflection of a shape of the ventilation section 53, for example, when the incident light L in a long wavelength region passes through the solid-state imaging element 2 and is reflected by the curved housing section 50 of the seating 5.

In addition, the embedded member 58 makes it possible to effectively suppress or prevent loss of a stress balance in the solid-state imaging element 2 caused by the ventilation section 53. This makes it possible to effectively suppress or prevent deterioration in a dark current and a white spot in the solid-state imaging element 2.

Furthermore, the embedded member 58 may be formed by a material having a thermal conductivity higher than a thermal conductivity of the seating 5. This makes it possible to improve a heat dissipation characteristic in the imaging device 1.

To achieve such advantages, the embedded member 58 includes one or more materials selected from a material having a high reflectance, a material that is able to be embedded accurately in the ventilation section 53 with no void, a material having a high thermal conductivity.

Although the depressurization type curved mounting method has been described above, the mark 27 may be formed in the solid-state imaging element 2 as described above (see FIG. 27B). In addition, the porous material 54 may be formed in the ventilation section 53 of the seating 5 (see (A) of FIG. 11 and (B) of FIG. 11).

### (2) Pressurization Type Curved Mounting Method

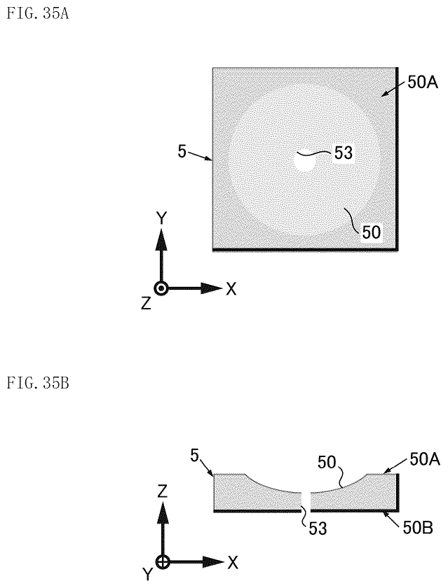

FIGS. 35 to 41 each illustrate an example of each step describing a pressurization type curved mounting method of the pressure difference type curved mounting method.

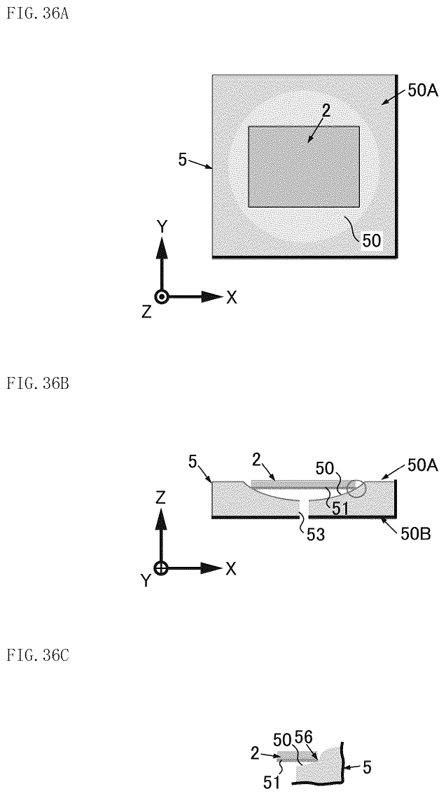

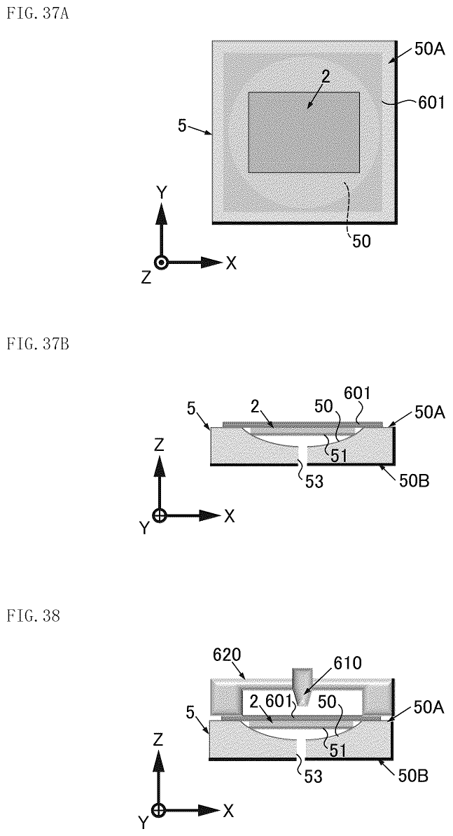

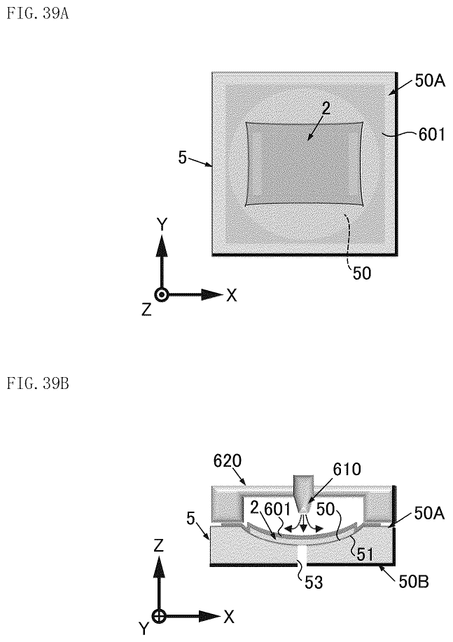

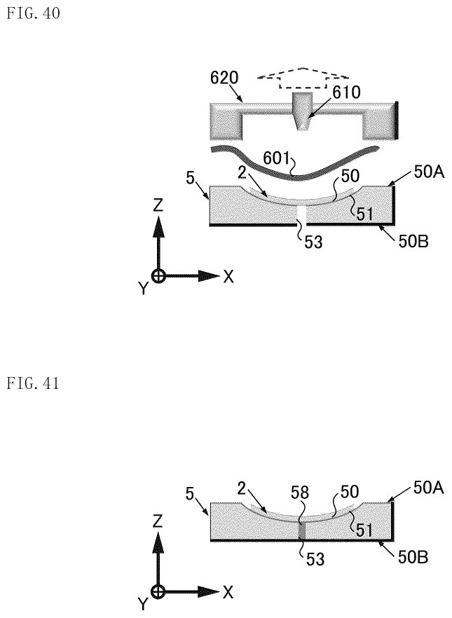

FIG. 35A illustrates an example of a planar configuration of the seating 5, and FIG. 35B illustrates an example of a cross-sectional configuration of the seating 5. FIG. 36A illustrates an example of a planar configuration of the seating 5 on which the solid-state imaging element 2 is placed. FIG. 36B illustrates an example of a cross-sectional configuration of the seating 5 on which the solid-state imaging element 2 is placed. FIG. 36C illustrates, in an enlarged manner, an example of a cross-sectional configuration of a main part of the seating 5. FIG. 37A illustrates an example of a planar configuration of the seating 5 on which the gas leakproof film 601 is mounted. FIG. 37B illustrates an example of a cross-sectional configuration of the seating 5 on which the gas leakproof film 601 is mounted. FIG. 38 illustrates an example of a cross-sectional configuration of the seating 5 on which the nozzle 610 is mounted. FIG. 39A illustrates an example of a planar configuration of the seating 5 in a pressurization state. FIG. 39B illustrates an example of a cross-sectional configuration of the seating 5 in the pressurization state. FIG. 40 illustrates an example of a cross-sectional configuration of the seating 5 after finishing of curved mounting. FIG. 41 illustrates an example of a cross-sectional configuration of the imaging device 1 after the finishing of the curved mounting.

The pressurization type curved mounting method is as follows.

First, as illustrated in FIGS. 35A and 35B, the seating 5 is prepared. As described above, the seating 5 includes the curved housing section 50, and the ventilation section 53 is formed in the curved housing section 50. The ventilation section 53 has a configuration similar to that of the ventilation section 53 illustrated in (A) of FIG. 10 and (B) of FIG. 10 described above.

As illustrated in FIGS. 36A and 36B, the solid-state imaging element 2 including the infrared-absorbing filter 3 is disposed at a position corresponding to the curved housing section 50 of the seating 5. Detailed configurations of the infrared-absorbing filter 3 and the solid-state imaging element 2 and the method of manufacturing the infrared-absorbing filter 3 and the solid-state imaging element 2 are as described above.

Here, as illustrated in FIG. 36C, the stepped part 56 is formed in the curved housing section 50 (see FIG. 13), and the solid-state imaging element 2 is positioned with respect to the inside of the curved housing section 50 by the stepped part 56.

In addition, although not illustrated, as with the step illustrated in FIG. 25A described above, the adhesive 51 is formed in the curved housing section 50. The adhesive 51 may be applied to the solid-state imaging element 2 on the side of the second surface 21B. In addition, the adhesive 51 may be replaced with a DAF.

As illustrated in FIGS. 37A and 37B, the gas leakproof film 601 that covers the entirety of the curved housing section 50 is disposed on the front surface 50A of the seating 5 with the solid-state imaging element 2 and the infrared-absorbing filter 3 interposed therebetween.

As illustrated in FIG. 38, the collet 620 is mounted on the seating 5 with the gas leakproof film 601 interposed therebetween, and the gas leakproof film 601 is pressed against the seating 5. The nozzle 610 is attached to the collet 620. An unillustrated gas generation device is connected to the nozzle 610.

The mounting of the collet 620 causes the solid-state imaging element 2 and the infrared-absorbing filter 3 to be housed in the sealed state in the curved housing section 50 covered with the gas leakproof film 601.

As illustrated in FIGS. 39A and 39B, a gas is blown from the nozzle 610 to the infrared-absorbing filter 3 and the solid-state imaging element 2 through the gas leakproof film 601. In other words, the infrared-absorbing filter 3 and the solid-state imaging element 2 are pressurized by the gas.

A gas in the curved housing section 50 is released through the ventilation section 53 of the seating 5 at the same timing. In addition, the pressure in the curved housing section 50 is reduced through the ventilation section 53 of the seating 5. This generates a pressure difference, which causes the solid-state imaging element 2 and the infrared-absorbing filter 3 to be curved along the curved shape of the curved housing section 50, and thus the solid-state imaging element 2 is mounted in the curved housing section 50. It is to be noted that the curved shape of the solid-state imaging element 2 is maintained by curing of the unillustrated adhesive 51. The specific material and curing type of the adhesive are as described above.

As illustrated in FIG. 40, the collet 620 is pulled up, and the gas leakproof film 601 is removed.

As with the step illustrated in FIG. 34 described above, as illustrated in FIG. 41, the inside of the ventilation section 53 of the seating 5 is filled with the embedded member 58. The material of the embedded member 58 is as described above.

Although the pressurization type curved mounting method has been described above, the mark 27 may be formed in the solid-state imaging element 2 as described above (see FIG. 27B). In addition, the porous material 54 may be formed in the ventilation section 53 of the seating 5 (see (A) of FIG. 11 and (B) of FIG. 11).

### [Configuration Example of Solid-State Imaging Element 2]

### (1) First Configuration of Solid-State Imaging Element 2

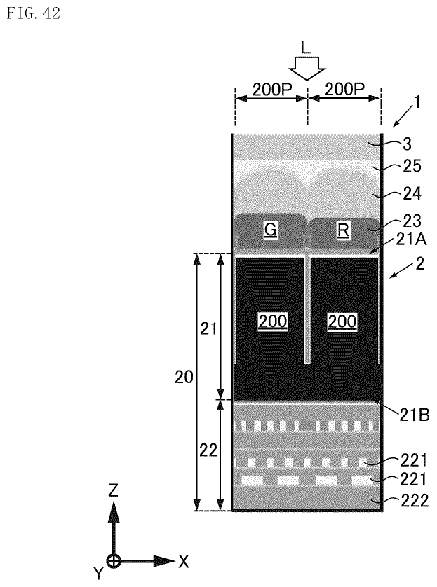

FIG. 42 illustrates an example of a specific cross-sectional configuration of the solid-state imaging element 2 according to the first configuration and the infrared-absorbing filter 3.

As illustrated in FIG. 42, the solid-state imaging element 2 basically has a configuration similar to that of the solid-state imaging element 2 illustrated in FIGS. 1 and 21 described above. The solid-state imaging element 2 is a back-illuminated solid-state imaging element.

Here, in the solid-state imaging element 2, the optical filter 23 and the optical lens 24 are sequentially stacked on the side of the first surface 21A of the semiconductor substrate 21, and the planarization film 25 is disposed as a final layer. A high refractive index material is used for the optical lens 24. In contrast, a low refractive index material having a refractive index lower than the refractive index of the optical lens 24 is used for the planarization film 25. The refractive index of the planarization film 25 is set to be higher than or equal to 1.2 and lower than or equal to 1.5. Furthermore, the infrared-absorbing filter 3 is disposed on the planarization film 25.

In the solid-state imaging element 2 configured as described above, it is possible to form the thick infrared-absorbing filter 3, which makes it possible to sufficiently absorb infrared rays. In addition, in the solid-state imaging element 2, the infrared-absorbing filter 3 is disposed on the optical lens 24, which makes it possible to bring the optical lens 24 closer to the photoelectric conversion region 200. This enables an oblique incidence characteristic of the solid-state imaging element 2 to be robust.

### (2) Second Configuration of Solid-State Imaging Element 2

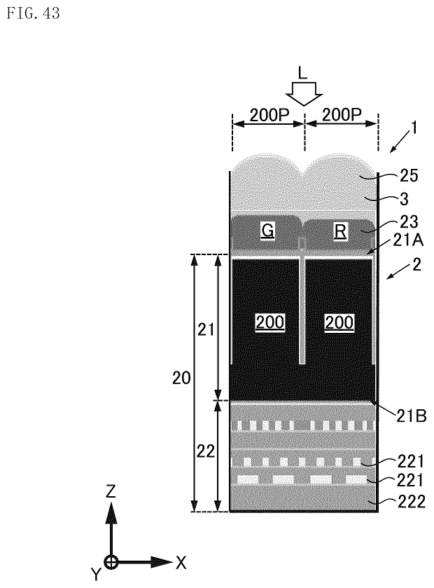

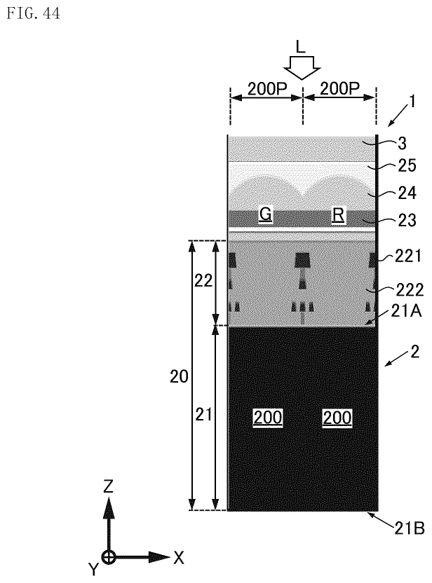

FIG. 43 illustrates an example of a specific cross-sectional configuration of the solid-state imaging element 2 according to a second configuration and the infrared-absorbing filter 3.

As illustrated in FIG. 43, the solid-state imaging element 2 is a back-illuminated solid-state imaging element, as with the solid-state imaging element 2 illustrated in FIG. 42 described above.

In the solid-state imaging element 2, the infrared-absorbing filter 3 is disposed between the optical filter 23 and the optical lens 24. The planarization film 25 is omitted. The optical lens 24 is formed by a normal refractive index material.

In the solid-state imaging element 2 illustrated in FIG. 42 described above, a frontmost surface thereof is planarized by the infrared-absorbing filter 3, which causes strong specular reflection to the incident light L. For example, this is a factor that causes the specular reflection from the solid-state imaging element 2 to be reflected again at a member on a side of the module lens, thus causing a ghost phenomenon, for a high-luminance light source such as sunlight.

However, as illustrated in FIG. 43, in the solid-state imaging element 2, the optical lens 24 (and the antireflection film 241) having an uneven frontmost surface is disposed, which causes the incident light L to be scattered. This makes it possible to effectively suppress or prevent the ghost phenomenon.

### (3) Third Configuration of Solid-State Imaging Element 2

FIG. 44 illustrates an example of a specific cross-sectional configuration of the solid-state imaging element 2 according to a third configuration and the infrared-absorbing filter 3.

As illustrated in FIG. 44, the solid-state imaging element 2 is a front-illuminated solid-state imaging element, which is different from the solid-state imaging element 2 illustrated in FIG. 42 described above.

In the solid-state imaging element 2, the semiconductor substrate 21 and the wiring layer 22 in the base 20 are replaced with each other, and the wiring layer 22 is disposed between the semiconductor substrate 21 and the optical filter 23. A stacked structure of the optical filter 23, the optical lens 24, the planarization film 25, and the infrared-absorbing filter 3 is similar to that in the solid-state imaging element 2 according to the first configuration.

Here, a high refractive index material is used for the optical lens 24. In contrast, a low refractive index material having a refractive index lower than the refractive index of the optical lens is used for the planarization film 25.

According to the solid-state imaging element 2 configured as described above, it is possible to obtain workings and effects similar to the workings and effects obtained by the solid-state imaging element 2 according to the first configuration.

### (4) Fourth Configuration of Solid-State Imaging Element 2

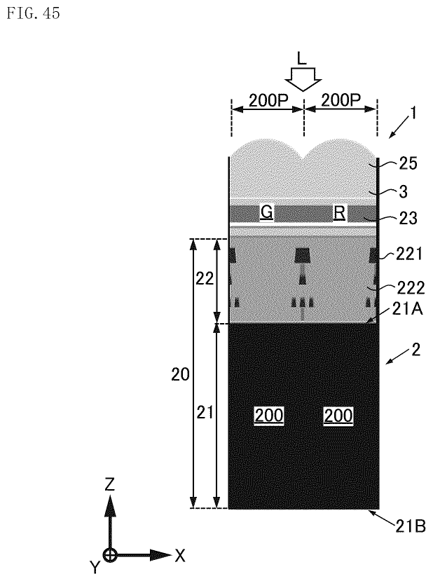

FIG. 45 illustrates an example of a specific cross-sectional configuration of the solid-state imaging element according to a fourth configuration and the infrared-absorbing filter 3.

As illustrated in FIG. 45, the solid-state imaging element 2 is a front-illuminated solid-state imaging element, as with the solid-state imaging element 2 illustrated in FIG. 44 described above.

In addition, in the solid-state imaging element 2, as with the solid-state imaging element 2 illustrated in FIG. 43 described above, the infrared-absorbing filter 3 is disposed between the optical filter 23 and the optical lens 24. The planarization film 25 is omitted. The optical lens 24 is formed by a normal refractive index material.

According to the solid-state imaging element 2 configured as described above, it is possible to obtain workings and effects similar to the workings and effects obtained by the solid-state imaging element 2 according to the second configuration.

### (5) Fifth Configuration of Solid-State Imaging Element 2

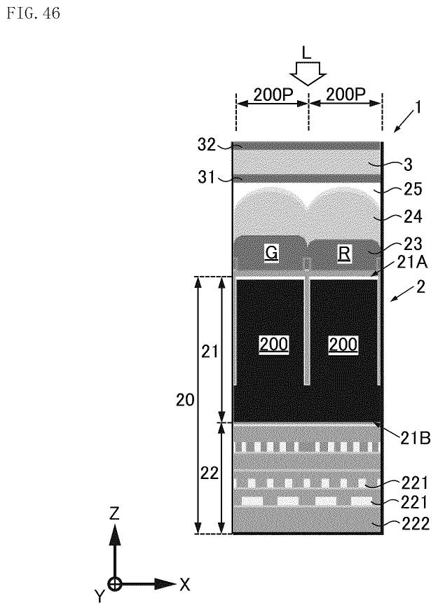

FIG. 46 illustrates an example of a specific cross-sectional configuration of the solid-state imaging element 2 according to a fifth configuration and the infrared-absorbing filter 3.

As illustrated in FIG. 46, the solid-state imaging element 2 is a back-illuminated solid-state imaging element, as with the solid-state imaging element 2 illustrated in FIG. 42 described above.

The solid-state imaging element 2 further includes, on the infrared-absorbing filter 3, one or more selected from an inorganic protective film 31 and the antireflection film 32.

The inorganic protective film 31 is disposed between the planarization film 25 and the infrared-absorbing filter 3. The inorganic protective film 31 is formed by a material having a smallest possible extinction coefficient for a wavelength to be detected by the solid-state imaging element 2. An extinction coefficient of the inorganic protective film 31 is set to 0.01 or less, for example. For example, the inorganic protective film 31 is formed, for example, by one or more materials selected from SiO₂, SiN, SiON, SiC, Al₂O₃, HfO₂, and TiO₂.

In addition, the inorganic protective film 31 is formed to have a thickness that allows for less reflection for the wavelength to be detected. Here, the thickness of the inorganic protective film 31 is set to about 4/(nλ) or an integral multiple thereof, where 2 is a wavelength of the incident light L and n is a refractive index of the inorganic protective film 31. Strictly speaking, in consideration of interference and an influence of oblique incidence in a multilayer structure, the thickness of the inorganic protective film 31 is set on the basis of a theoretical calculation by a Fresnel coefficient method or a wave optics simulation, or by a measured reflectance of a prepared actual sample.

The antireflection film 32 is disposed on the infrared-absorbing filter 3 on a side opposite to the inorganic protective film 31. In other words, the infrared-absorbing filter 3 is interposed between the inorganic protective film 31 and the antireflection film 32.

The antireflection film 32 is formed by an inorganic material basically similar to that of the inorganic protective film 31 to have a thickness basically similar to that of the inorganic protective film 31.

In addition, the antireflection film 32 may be formed by a material different from the material of the inorganic protective film 31. In addition, the antireflection film 32 may be formed by stacking different materials to effectively improve an antireflection effect. In addition, the antireflection film 32 may be formed thicker than the inorganic protective film 31 to improve a passivation function.

According to the solid-state imaging element 2 including the infrared-absorbing filter 3 configured as described above, at least one of the inorganic protective film 31 or the antireflection film 32 is disposed, which makes it possible to effectively suppress or prevent entry of moisture and the like.

In addition, it is possible to set of the thickness of at least one of the inorganic protective film 31 or the antireflection film 32 in consideration of the refractive index, which makes it possible to effectively suppress or prevent reflection.

In addition, in the method of manufacturing the solid-state imaging element 2, forming the antireflection film 32 on the infrared-absorbing filter 3 makes it possible to effectively suppress or prevent mixing of an organic material formed on the antireflection film 32, and the infrared-absorbing filter 3. The organic material corresponds to, for example, a resist to be used to form a bonding opening in the infrared-absorbing filter 3 or the like.

### (6) Sixth Configuration of Solid-State Imaging Element 2

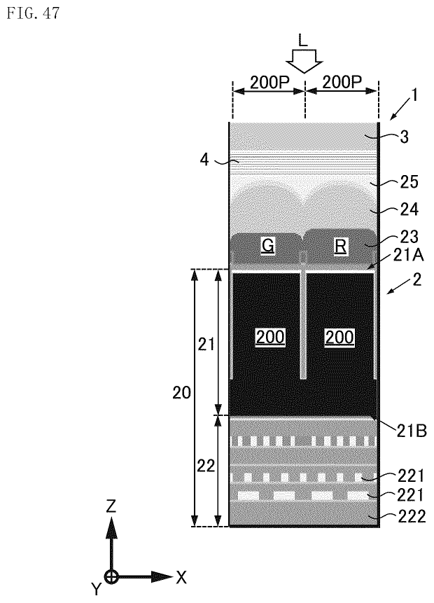

FIG. 47 illustrates an example of a specific cross-sectional configuration of the solid-state imaging element 2 according to a sixth configuration, the infrared-absorbing filter 3, and the multilayer film filter 4.

As illustrated in FIG. 47, the solid-state imaging element 2 basically has a configuration similar to that of the solid-state imaging element 2 illustrated in FIG. 5 described above. The solid-state imaging element 2 is a back-illuminated solid-state imaging element.

The solid-state imaging element 2 includes the multilayer film filter 4 between the planarization film 25 and the infrared-absorbing filter 3. In other words, the solid-state imaging element 2 includes the infrared-absorbing filter as an absorption type infrared cut filter (IRCF) and the multilayer film filter 4 as a reflection type infrared cut filter (IRCF) or a band-pass filter (BPF).

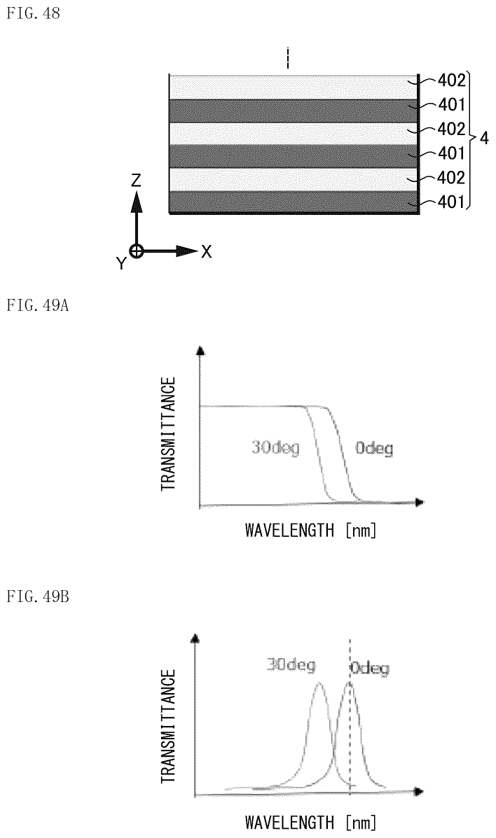

FIG. 48 illustrates an example of a specific cross-sectional configuration of the multilayer film filter 4 in an enlarged manner.

As illustrated in FIG. 48, the multilayer film filter 4 is formed by alternately stacking a plurality of high refractive index layers 401 and a plurality of low refractive index layers 402.

For example, one or more high refractive index materials selected from Al₂O₃ having a refractive index of 1.77, SiN having a refractive index of 1.91, HfO₂ having a refractive index of 1.93, ZnO₂ having a refractive index of 2.00, Ta2O₅ having a refractive index of 2.15, TiO₂ having a refractive index of 2.28, and Nb₂O₅ having a refractive index of 2.33 are used for the high refractive index layers 401, for example.

In addition, for example, one or more low refractive index materials selected from SiO₂ having a refractive index of 1.45, SiOC having a refractive index of 1.40, MgF₂ having a refractive index of 1.38, and AlF₃ having a refractive index of 1.38 are used for the low refractive index layers 402.

Here, FIG. 49A illustrates an example of a relationship between a wavelength and a transmittance of the infrared-absorbing filter 3. In addition, FIG. 49B illustrates an example of a relationship between a wavelength and a transmittance of the multilayer film filter 4. In each of FIGS. 49A and 49B, a horizontal axis indicates the wavelength and the vertical axis indicates the transmittance.

As illustrated in FIG. 49A, the transmittance of the infrared-absorbing filter 3 is uniform even if the incident angle of the incident light L is changed.

Likewise, as illustrated in FIG. 49B, the transmittance of the multilayer film filter 4 is uniform even if the incident angle of the incident light L is changed.

According to the solid-state imaging element 2 configured as described above, combination of the infrared-absorbing filter 3 and the multilayer film filter 4 counterbalances each other's disadvantages, thus making it possible to improve characteristics as the infrared cut filter.

In addition, according to the solid-state imaging element 2, the combination of the multilayer film filter 4 and the infrared-absorbing filter 3 makes it possible to reduce the number of layers of the multilayer film filter 4, as compared with a case where the multilayer film filter 4 is provided solely. This makes it possible to reduce fabrication cost of the solid-state imaging element 2.

### (7) Seventh Configuration of Solid-State Imaging Element 2

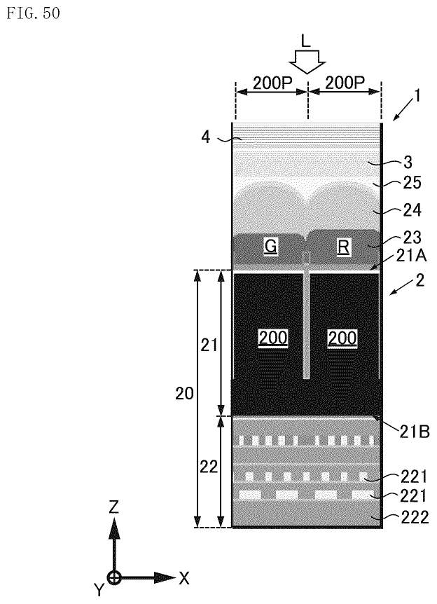

FIG. 50 illustrates an example of a specific cross-sectional configuration of the solid-state imaging element 2 according to a seventh configuration, the infrared-absorbing filter 3, and the multilayer film filter 4.

As illustrated in FIG. 50, the solid-state imaging element 2 is basically a back-illuminated solid-state imaging element, as with the solid-state imaging element 2 illustrated in FIG. 47 described above.

In the solid-state imaging element 2, the infrared-absorbing filter 3 is disposed on the planarization film 25, and the multilayer film filter 4 is disposed on the infrared-absorbing filter 3. In other words, the positions of the infrared-absorbing filter 3 and the multilayer film filter 4 are replaced with each other.

According to the solid-state imaging element 2 configured as described above, it is possible to obtain workings and effects similar to the workings and effects obtained by the solid-state imaging element 2 illustrated in FIG. 47.

### (8) Eighth Configuration of Solid-State Imaging Element 2

FIG. 51 illustrates an example of a specific cross-sectional configuration of the solid-state imaging element 2 according to an eighth configuration, the infrared-absorbing filter 3, and the multilayer film filter 4.

As illustrated in FIG. 51, the solid-state imaging element 2 is basically a back-illuminated solid-state imaging element, as with the solid-state imaging element 2 illustrated in FIG. 43 described above.

In the solid-state imaging element 2, the infrared-absorbing filter 3 is disposed between the optical filter 23 and the optical lens 24. Furthermore, the multilayer film filter 4 is disposed on the optical lens 24 with the planarization film 25 interposed therebetween.

According to the solid-state imaging element 2 configured as described above, it is possible to obtain workings and effects similar to the workings and effects obtained by the solid-state imaging element 2 illustrated in FIG. 47.

### (9) Ninth Configuration of Solid-State Imaging Element 2

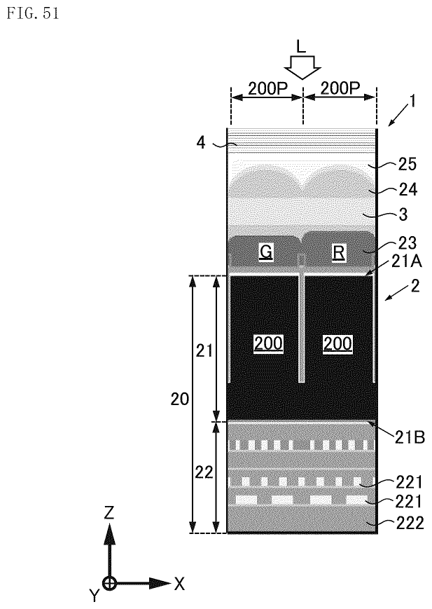

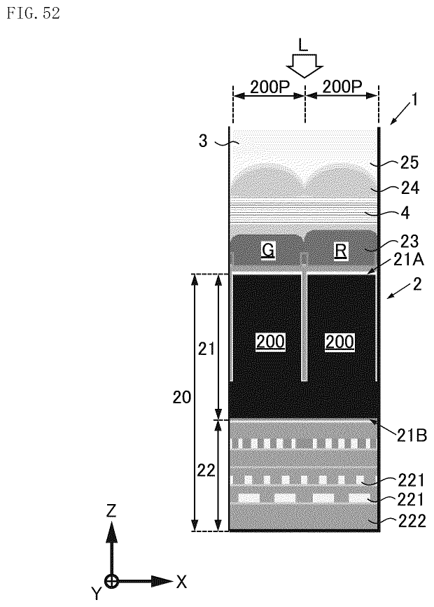

FIG. 52 illustrates an example of a specific cross-sectional configuration of the solid-state imaging element 2 according to a ninth configuration, the infrared-absorbing filter 3, and the

### Multilayer Film Filter 4.

As illustrated in FIG. 52, the solid-state imaging element 2 is basically a back-illuminated solid-state imaging element, as with the solid-state imaging element 2 illustrated in FIG. 47 described above.

In the solid-state imaging element 2, the multilayer film filter 4 is disposed between the optical filter 23 and the optical lens 24. Furthermore, the infrared-absorbing filter 3 is disposed on the optical lens 24 with the planarization film 25 interposed therebetween.

According to the solid-state imaging element 2 configured as described above, it is possible to obtain workings and effects similar to the workings and effects obtained by the solid-state imaging element 2 illustrated in FIG. 47.

### [Configuration Example of Infrared-Absorbing Filter 3]

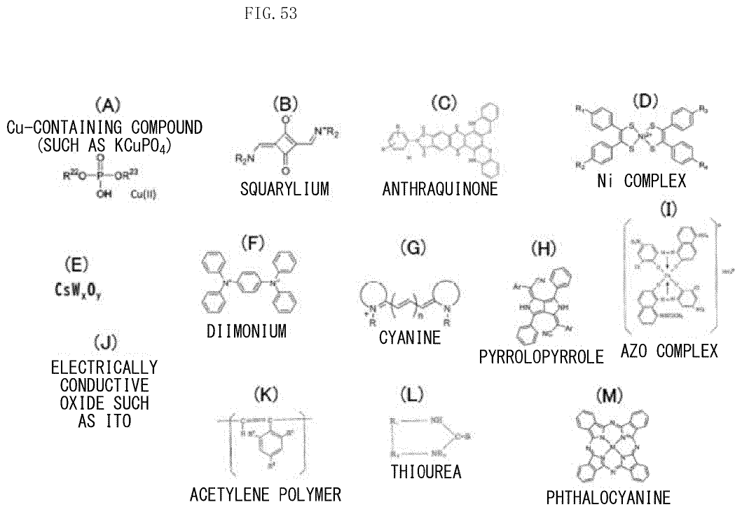

(A) to (M) of FIG. 53 each illustrate an example of an infrared-absorbing material of the infrared-absorbing filter 3.

The infrared-absorbing materials forming the infrared-absorbing filter 3 include a Cu-containing compound illustrated in (A) of FIG. 53, squarylium illustrated in (B) of FIG. 53, anthraquinone illustrated in (C) of FIG. 53, a Ni complex illustrated in (D) of FIG. 53, and CsWxOy illustrated in (E) of FIG. 53. In addition, the infrared-absorbing materials include diimonium illustrated in (F) of FIG. 53, the above-described cyanine dye illustrated in (G) of FIG. 53, pyrrolopyrrole illustrated in (H) of FIG. 53, an azo complex illustrated in (I) of FIG. 53, and an electrically conductive oxide such as ITO illustrated in (J) of FIG. 53. Furthermore, the infrared-absorbing materials include an acetylene polymer illustrated in (K) of FIG. 53, a thiouric acid illustrated in (L) of FIG. 53, and phthalocyanine illustrated in (M) of FIG. 53.

As described above, it is possible to use various infrared-absorbing materials other than the above-described cyanine dye. In addition, the infrared-absorbing filter 3 may be formed by combination of two or more selected from the infrared-absorbing materials illustrated in (A) to (M) of FIG. 53 in consideration of an infrared absorbance and a visible light transmittance.

### 2. Second Embodiment

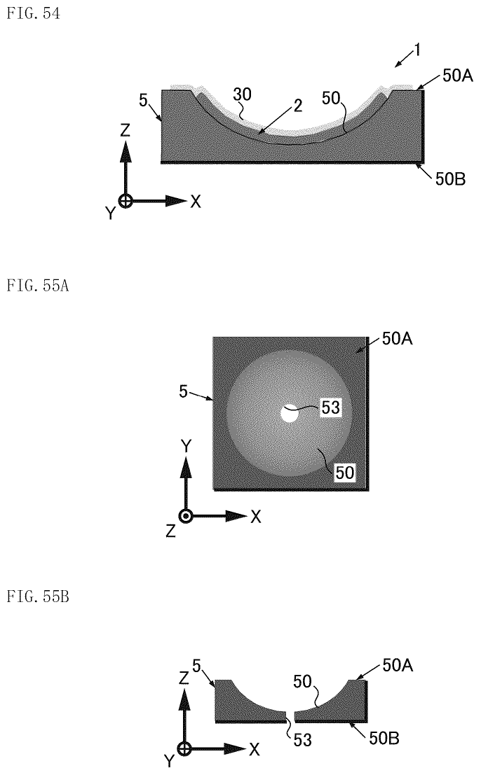

Description is given, with reference to FIGS. 54 to 76, of the imaging device 1 and a method of manufacturing the imaging device 1 according to the second embodiment of the present disclosure.

### [Schematic Configuration of Imaging Device 1]

FIG. 54 illustrates an example of a cross-sectional configuration of the imaging device 1 according to the second embodiment.

The imaging device 1 according to the second embodiment includes the seating 5 and the solid-state imaging element 2 curvedly mounted in the curved housing section 50 of the seating 5, as with the imaging device 1 according to the first embodiment, and further includes an infrared-absorbing filter 30.

The infrared-absorbing filter 30 extends from the light-receiving surface of the solid-state imaging element 2 to the peripheral part of the front surface 50A of the seating 5 via the side surface of the solid-state imaging element 2, and is in close contact with each of the light-receiving surface, the side surface, and the front surface 50A. The infrared-absorbing filter 30 has a function similar to that of the infrared-absorbing filter 3 according to the first embodiment, and also has a function of the gas leakproof film 601. The infrared-absorbing filter 30 is formed in a film shape.

### [Overview of Method of Manufacturing Imaging Device 1]

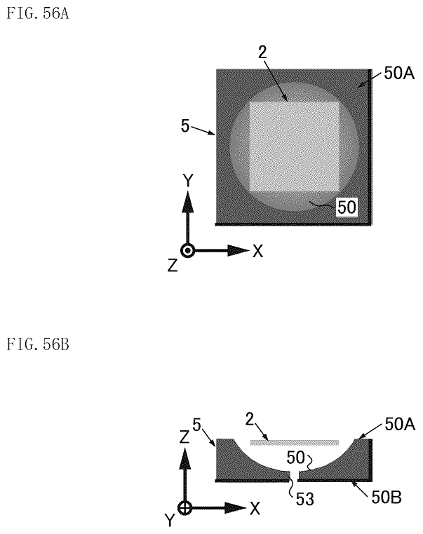

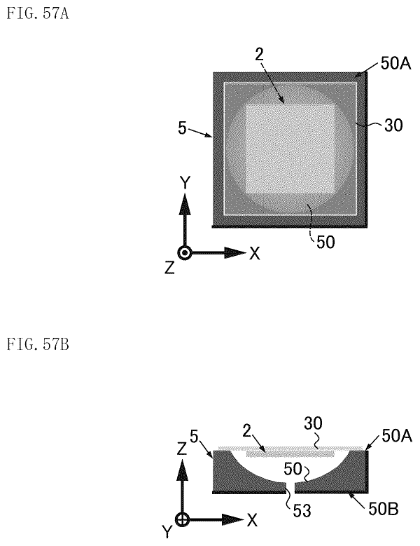

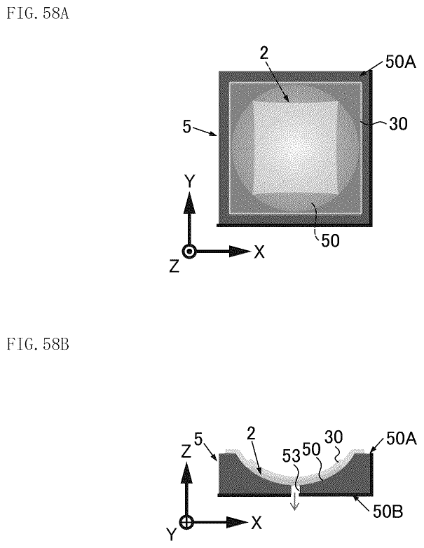

FIGS. 55 to 58 are each a step diagram describing an overview of the method of manufacturing the imaging device 1. FIG. 55A illustrates an example of a planar configuration of the seating 5 before mounting. FIG. 55B illustrates an example of a cross-sectional configuration of the seating 5 before the mounting. FIG. 56A illustrates an example of a planar configuration of the seating 5 on which the solid-state imaging element 2 is placed. FIG. 56B illustrates an example of a cross-sectional configuration of the seating 5 on which the solid-state imaging element 2 is placed. FIG. 57A illustrates an example of a planar configuration of the seating 5 on which the infrared-absorbing filter 30 is mounted. FIG. 57B illustrates an example of a cross-sectional configuration of the seating 5 on which the infrared-absorbing filter 30 is mounted. FIG. 58A illustrates an example of a planar configuration of the seating 5, the solid-state imaging element 2, and the infrared-absorbing filter 30 after finishing of curved mounting. FIG. 58B illustrates an example of a cross-sectional configuration of the seating 5, the solid-state imaging element 2, and the infrared-absorbing filter 30 after the finishing of the curved mounting.

First, as illustrated in FIGS. 55A and 55B, the seating 5 is formed. The seating 5 includes the curved housing section 50. The ventilation section 53 is formed at the middle part of the curved housing section 50 of the seating 5.

Meanwhile, the solid-state imaging element 2 similar to the solid-state imaging element according to the first embodiment described above is formed (see FIGS. 1 and 21).

As illustrated in FIGS. 56A and 56B, the solid-state imaging element 2 is placed on the curved housing section 50 of the seating 5. Although not illustrated here, the adhesive 51 is formed in the curved housing section 50 or on the solid-state imaging element 2 (see (C) of FIG. 12).

Subsequently, as illustrated in FIGS. 57A and 57B, the infrared-absorbing filter 30 is disposed on the surface of the solid-state imaging element 2. As described above, the infrared-absorbing filter 30 also has the function of the gas leakproof film 601. The infrared-absorbing filter 30 is formed to have a size larger than each of sizes of the solid-state imaging element 2 and the curved housing section 50 in a plan view, and an edge of the infrared-absorbing filter 30 reaches the peripheral part of the front surface 50A of the seating 5.

As illustrated in FIGS. 58A and 58B, the solid-state imaging element 2 is curved along the curved shape of the curved housing section 50 by a pressure difference, and thus the solid-state imaging element 2 is mounted in the curved housing section 50. The pressure difference is caused by depressurization or pressurization, as with the pressure difference according to the first embodiment.

Here, when the solid-state imaging element 2 is formed in the curved shape, the infrared-absorbing filter 30 is formed in a curved shape along the light-receiving surface of the solid-state imaging element 2, and is formed in close contact with the light-receiving surface, the side surface, and the like. The infrared-absorbing filter 3 is incorporated as a component of the imaging device 1.

In addition, when the adhesive 51 is cured, the solid-state imaging element 2 and the infrared-absorbing filter 30 that are in the curved shape are fixed in the curved housing section 50 of the seating 5.

When the solid-state imaging element 2 and the infrared-absorbing filter 30 are mounted on the seating 5, the manufacturing method is finished, and the imaging device 1 is completed.

According to the imaging device 1 configured as described above, the solid-state imaging element 2 is mounted on the seating 5 in a state in which the infrared-absorbing filter 30 is disposed throughout the side surface of the solid-state imaging element 2 from the light-receiving surface of the solid-state imaging element 2. This makes it possible to effectively reduce the possibility of breakage of the solid-state imaging element 2 even if an impact or the like occurs on the solid-state imaging element 2.

In addition, it is possible to enhance an effect of attenuating stray light in an absorption wavelength region of the infrared-absorbing filter 30, for flare or ghost that is to occur when the side surface of the solid-state imaging element 2 is irradiated with the incident light L from a high-luminance light source such as sunlight.

In addition, according to the method of manufacturing (mounting) the imaging device 1, the infrared-absorbing filter 30 also having the function of the gas leakproof film 601 is formed. Accordingly, in the method of manufacturing the imaging device 1, a step of forming the gas leakproof film 601, a step of removing the gas leakproof film 601, and the like are eliminated, which makes it possible to reduce the number of steps.

### [Pressure Difference Type Curved Mounting Method]

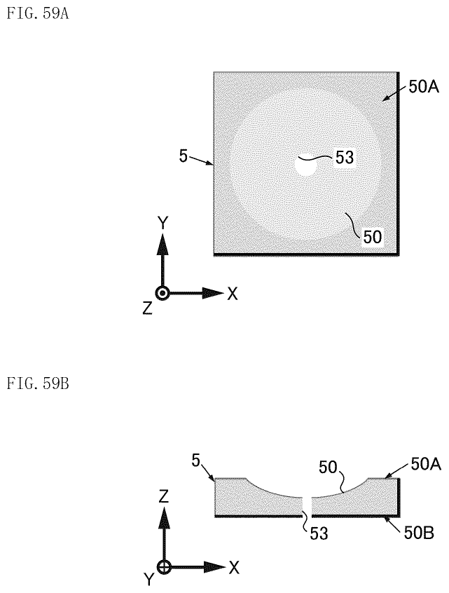

FIGS. 59 to 67 each illustrate an example of each step describing a depressurization type curved mounting method of the pressure difference type curved mounting method.

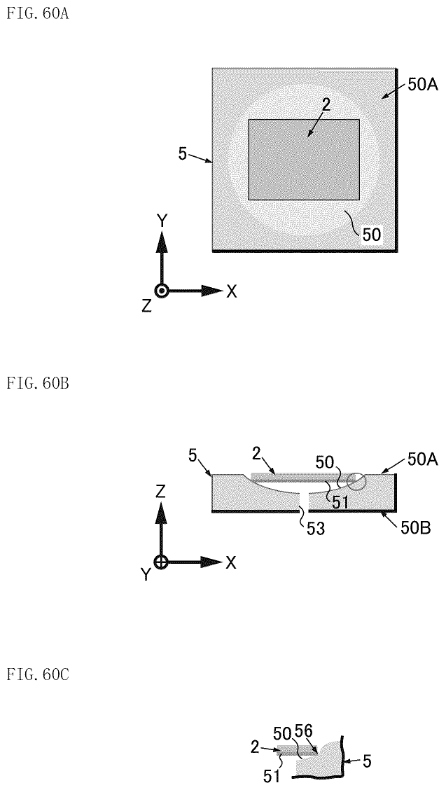

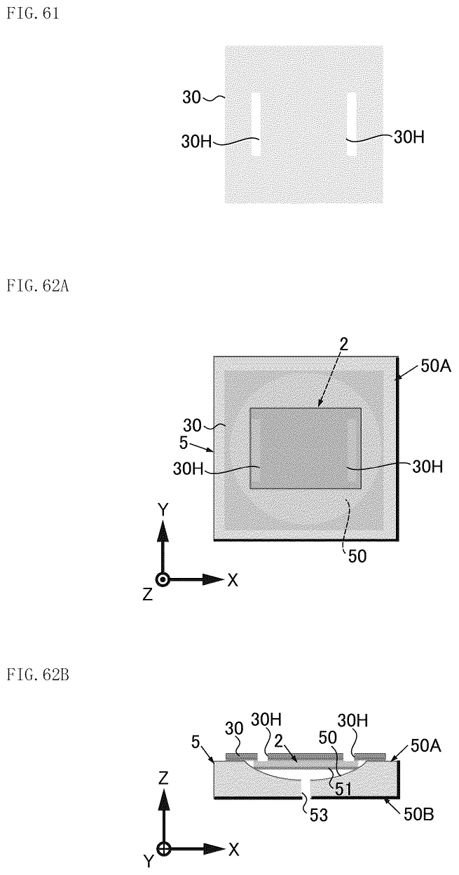

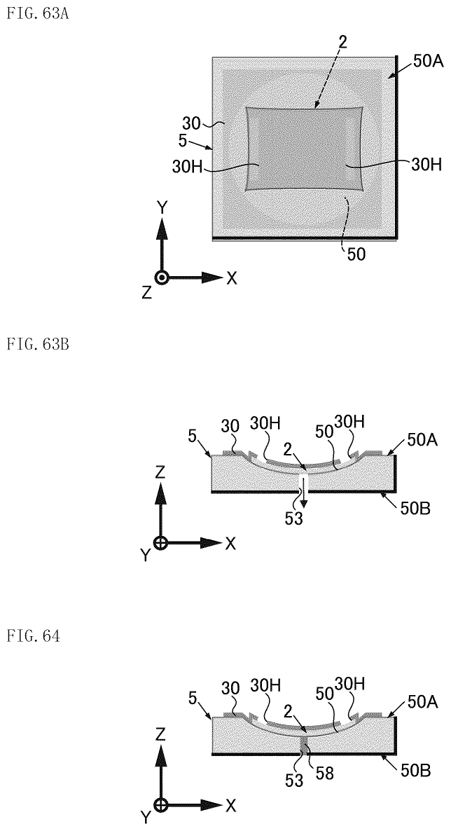

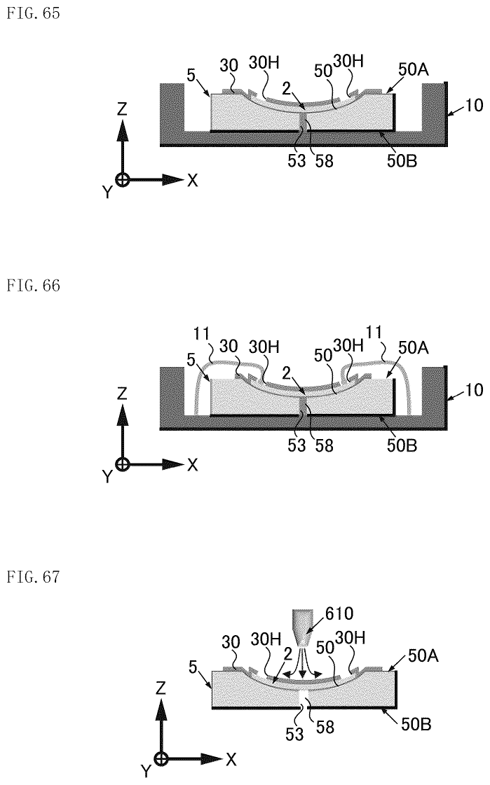

FIG. 59A illustrates an example of a planar configuration of the seating 5. FIG. 59B illustrates an example of a cross-sectional configuration of the seating 5. FIG. 60A illustrates an example of a planar configuration of the seating 5 on which the solid-state imaging element 2 is placed. FIG. 60B illustrates an example of a cross-sectional configuration of the seating 5 on which the solid-state imaging element 2 is placed. Furthermore, FIG. 60C illustrates an example of a cross-sectional configuration of a main part of the seating 5 in an enlarged manner. FIG. 61 illustrates an example of a planar configuration of the infrared-absorbing filter 30. FIG. 62A illustrates an example of a planar configuration of the seating on which the infrared-absorbing filter 30 is mounted. FIG. 62B illustrates an example of a cross-sectional configuration of the seating 5 on which the infrared-absorbing filter 30 is mounted. FIG. 63A illustrates an example of a planar configuration of the seating 5 in the depressurization state. FIG. 63B illustrates an example of a cross-sectional configuration of the seating 5 in the depressurization state. FIG. 64 illustrates an example of a cross-sectional configuration of the seating 5 in a state in which the ventilation section 53 is filled with the embedded member 58. FIG. 65 illustrates an example of a cross-sectional configuration of a package 10 on which the seating 5 is mounted. FIG. 66 illustrates an example of a cross-sectional configuration of the package 10 in a state in which a wire 11 is bonded. FIG. 67 illustrates an example of a cross-sectional configuration of the seating 5 in a pressurization state according to a modification example.

The depressurization type curved mounting method is as follows.

First, as illustrated in FIGS. 59A and 59B, the seating 5 is prepared. As described above, the seating 5 includes the curved housing section 50, and the ventilation section 53 is formed in the curved housing section 50. The curved surface of the curved housing section 50 of the seating 5 has a configuration in which the CRA is incident vertically at any image height in a manner corresponding to the optical design of the unillustrated module lens. The ventilation section 53 has a configuration similar to that of the ventilation section 53 illustrated in (A) of FIG. 10 and (B) of FIG. 10 described above.

As illustrated in FIGS. 60A and 60B, the solid-state imaging element 2 is disposed at a position corresponding to the curved housing section 50 of the seating 5. A detailed configuration of the solid-state imaging element 2 and the method of manufacturing the solid-state imaging element 2 are as described above.

Here, as illustrated in FIG. 60C, the stepped part 56 is formed in the curved housing section 50 (see FIG. 13), and the solid-state imaging element 2 is positioned with respect to the inside of the curved housing section 50 by the stepped part 56.

In addition, here, the adhesive 51 is formed on the solid-state imaging element 2 on the side of the second surface 21B.

As illustrated in FIG. 61, the infrared-absorbing filter 30 is prepared. The infrared-absorbing filter 30 also has the function of the gas leakproof film 601 as described above. In addition, a bonding opening 30H is formed in the infrared-absorbing filter 30 at a position corresponding to an unillustrated bonding pad of the solid-state imaging element 2.

As illustrated in FIGS. 62A and 62B, the infrared-absorbing filter 30 that entirely covers the curved housing section 50 is disposed on the front surface 50A of the seating 5 with the solid-state imaging element 2 interposed therebetween.

As illustrated in FIGS. 63A and 63B, a pressure in the curved housing section 50 is reduced through the ventilation section 53 connected to the vacuum device 600 (see (C) of FIG. 10). This generates a pressure difference, which causes the solid-state imaging element 2 and the infrared-absorbing filter 30 to be curved along the curved shape of the curved housing section 50, and thus the solid-state imaging element 2 is mounted in the curved housing section 50.

At this time, the infrared-absorbing filter 30 is in close contact with the light-receiving surface and the side surface of the solid-state imaging element 2 and the peripheral part of the front surface 50A of the seating 5. The curved shape of the solid-state imaging element 2 is maintained by curing of the adhesive 51. The specific material and curing type of the adhesive 51 are as described above.

As illustrated in FIG. 64, the inside of the ventilation section 53 of the seating 5 is filled with the embedded member 58. As with the embedded member 58 according to the first embodiment, the embedded member 58 makes it possible to effectively suppress or prevent the phenomenon of reflection of the shape of the ventilation section 53, for example, when the incident light L in the long wavelength region passes through the solid-state imaging element 2 and is reflected by the curved housing section 50 of the seating 5.

In addition, the embedded member 58 makes it possible to effectively suppress or prevent loss of a stress balance in the solid-state imaging element 2 caused by the ventilation section 53. This makes it possible to effectively suppress or prevent deterioration in a dark current and a white spot in the solid-state imaging element 2.

Furthermore, the embedded member 58 may be formed by a material having a thermal conductivity higher than the thermal conductivity of the seating 5. This makes it possible to improve the heat dissipation characteristic in the imaging device 1.

To achieve such advantages, the embedded member 58 includes one or more materials selected from a material having a high reflectance, a material that is able to be embedded accurately in the ventilation section 53 with no void, a material having a high thermal conductivity.

As illustrated in FIG. 65, the seating 5 having been subjected to curved mounting is mounted in the package 10. Although a detailed configuration and description of the configuration are omitted, here, a wiring is formed in the package 10.

As illustrated in FIG. 66, the wire 11 is bonded. An end of the wire 11 is electrically coupled to the wiring of the package 10. Another end of the wire 11 is electrically coupled to the unillustrated bonding pad of the solid-state imaging element 2 through the bonding opening 30H of the infrared-absorbing filter 30.

When a series of the manufacturing methods is finished, the imaging device 1 is completed that includes the solid-state imaging element 2 and the infrared-absorbing filter 30. The solid-state imaging element 2 is curvedly mounted in the curved housing section 50 of the seating 5. The infrared-absorbing filter 30 is in close contact with the light-receiving surface and the like of the solid-state imaging element 2. The infrared-absorbing filter 30 is a component of the imaging device 1.

It is to be noted that in the method of manufacturing the imaging device 1, the mark 27 may be formed in the solid-state imaging element 2 as described above (see FIG. 27B). In addition, the porous material 54 may be formed in the ventilation section 53 of the seating 5 (see (A) of FIG. 11 and (B) of FIG. 11).

In addition, in the method of manufacturing the imaging device 1 here, as illustrated in FIG. 67, it is possible to adopt the pressurization type curved mounting method in which a pressure difference is generated by pressurization (see FIGS. 35 to 41). In other words, a pressurized gas is blown from the nozzle 610 to curve the solid-state imaging element 2 and the infrared-absorbing filter 30 along the curved shape of the curved housing section 50, and thus the solid-state imaging element 2 is mounted in the curved housing section 50. The infrared-absorbing filter 30 is brought into close contact with the light-receiving surface and the side surface of the solid-state imaging element 2 and the peripheral part of the front surface 50A of the seating 5 by the pressure difference.

According to the imaging device 1 configured as described above, the solid-state imaging element 2 is mounted on the seating 5 in a state in which the infrared-absorbing filter 30 is disposed throughout the side surface of the solid-state imaging element 2 from the light-receiving surface of the solid-state imaging element 2. This makes it possible to effectively reduce the possibility of breakage of the solid-state imaging element 2 even if an impact or the like occurs on the solid-state imaging element 2.

In addition, it is possible to enhance the effect of attenuating stray light in the absorption wavelength region of the infrared-absorbing filter 30, for flare or ghost that is to occur when the side surface of the solid-state imaging element 2 is irradiated with the incident light L from a high-luminance light source such as sunlight.

In addition, according to the method of manufacturing (mounting) the imaging device 1, the infrared-absorbing filter 30 also having the function of the gas leakproof film 601 is formed. Accordingly, in the method of manufacturing the imaging device 1, the step of forming the gas leakproof film 601, the step of removing the gas leakproof film 601, and the like are eliminated, which makes it possible to reduce the number of steps.

### [First Press Type Curved Mounting Method]

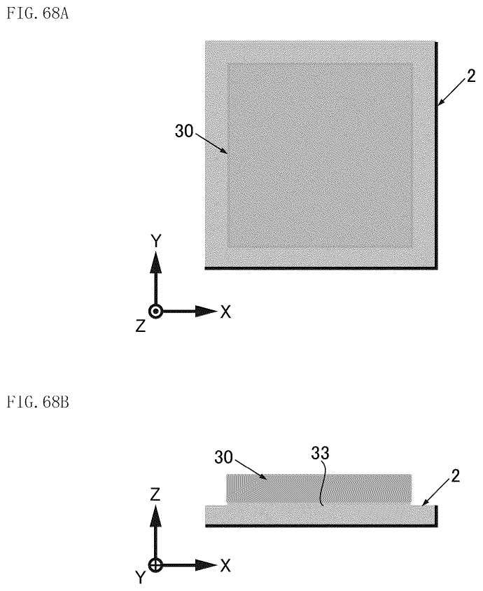

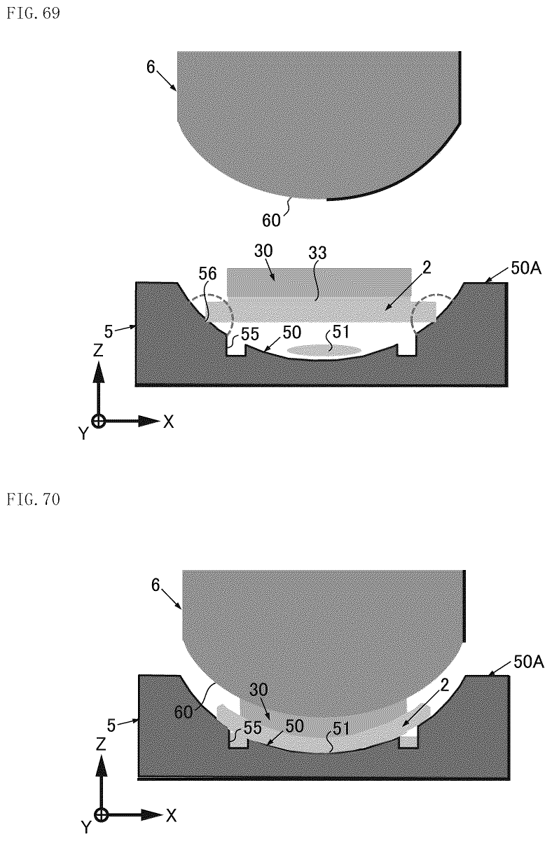

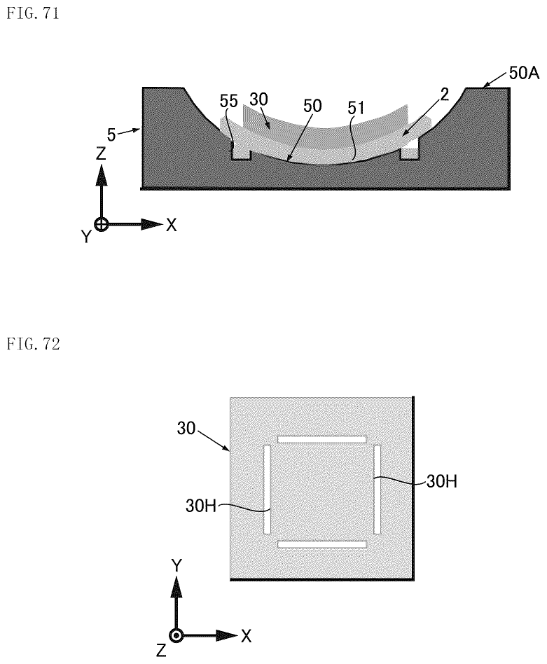

FIGS. 68 to 71 each illustrate an example of each step describing a press type curved mounting method. FIG. 68A illustrates an example of a planar configuration of the solid-state imaging element 2 and the infrared-absorbing filter 30 for describing the press type curved mounting method, and FIG. 68B illustrates an example of a cross-sectional configuration of the solid-state imaging element 2 and the infrared-absorbing filter 30. FIG. 69 illustrates an example of a cross-sectional configuration of the seating 5, the solid-state imaging element 2, the infrared-absorbing filter 30, and the pressing jig 6 before press type curved mounting. FIG. 70 illustrates an example of a cross-sectional configuration of the seating 5, the solid-state imaging element 2, the infrared-absorbing filter 30, and the pressing jig 6 during the press type curved mounting. FIG. 71 illustrates an example of a cross-sectional configuration of the seating 5, the solid-state imaging element 2, the infrared-absorbing filter 30, and the pressing jig 6 after the press type curved mounting.

The press type curved mounting method is as described below.

First, as illustrated in FIGS. 68A and 68B, the infrared-absorbing filter 30 in a film shape is formed on the light-receiving surface of the solid-state imaging element 2 with an adhesive 33 interposed therebetween. A detailed configuration of the solid-state imaging element 2 and the method of manufacturing the solid-state imaging element 2 are as described above. For example, a resin adhesive is used for the adhesive 33, and the adhesive 33 is applied to the solid-state imaging element 2 or the infrared-absorbing filter 30. Alternatively, a DAF may be used for the adhesive 33.

Here, the infrared-absorbing filter 30 is formed in a plane size smaller than a plane size of the solid-state imaging element 2.

Next, the seating 5 is prepared, and the solid-state imaging element 2 including the infrared-absorbing filter 30 is disposed at a position corresponding to the curved housing section 50 of the seating 5 (see FIG. 69). The curved surface of the curved housing section 50 of the seating 5 has a configuration in which the CRA is incident vertically at any image height in a manner corresponding to the optical design of the unillustrated module lens.

In addition, the adhesive 51 is formed in the curved housing section 50. The adhesive 51 may be applied to the solid-state imaging element 2 on the side of the second surface 21B. The adhesive 51 is formed by a material similar to that of the adhesive 51 according to the first embodiment or by a material of a curing type similar to the curing type of the adhesive 51 according to the first embodiment.

Here, the pocket 55 is formed in the curved housing section 50 of the seating 5 (see FIG. 12). The pocket 55 effectively suppresses or prevents spillover of the adhesive 51. In addition, the stepped part 56 is formed in the curved housing section 50 (see FIG. 13). The stepped part 56 allows for accurate positioning of the curved housing section 50 and the solid-state imaging element 2. Furthermore, the mark 57 may be formed in the seating 5 (see FIG. 14). The mark 57 allows for accurate positioning of the curved housing section 50 and the solid-state imaging element 2.

As illustrated in FIG. 69, the pressing jig 6 is placed on the curved housing section 50 of the seating 5 with the solid-state imaging element 2 and the infrared-absorbing filter 30 interposed therebetween, and press-mounting by the pressing jig 6 starts. The pressing jig 6 is provided with the end part 60 with a curved shape that protrudes on the side opposite to the arrow-Z direction (in the incident direction of the incident light L).

Here, a protective film may be interposed between the infrared-absorbing filter 30 and the end part 60 of the pressing jig 6. In this case, the protective film makes it possible to effectively suppress or prevent occurrence of a scar on the surface of the infrared-absorbing filter 30 or the solid-state imaging element 2.

As illustrated in FIG. 70, the adhesive 51 is cured while the end part 60 of the pressing jig 6 is pressed against the infrared-absorbing filter 30 and the solid-state imaging element 2. The pocket 55 takes in the excess of the adhesive 51. Thus, the solid-state imaging element 2 and the infrared-absorbing filter 30 in a state of being formed in the curved shape are fixed to the curved housing section 50 of the seating 5.

Thereafter, pressing by the pressing jig 6 is finished, and the pressing jig 6 is moved in the arrow −Z direction. In a case where the protective film is used, the protective film is removed.

Here, when the pocket 55 is formed in the curved housing section 50 of the seating 5, the end part of the pocket 55 is formed in a rounding shape as described above to effectively suppress or prevent occurrence of stress concentration.

According to the imaging device 1 configured as described above and the method of manufacturing the imaging device 1, it is possible to obtain workings and effects similar to the workings and effects obtained by the imaging device 1 and the method of manufacturing the imaging device 1 (the pressure difference type curved mounting method) described in FIGS. 59 to 67.

### [Second Press Type Curved Mounting Method]

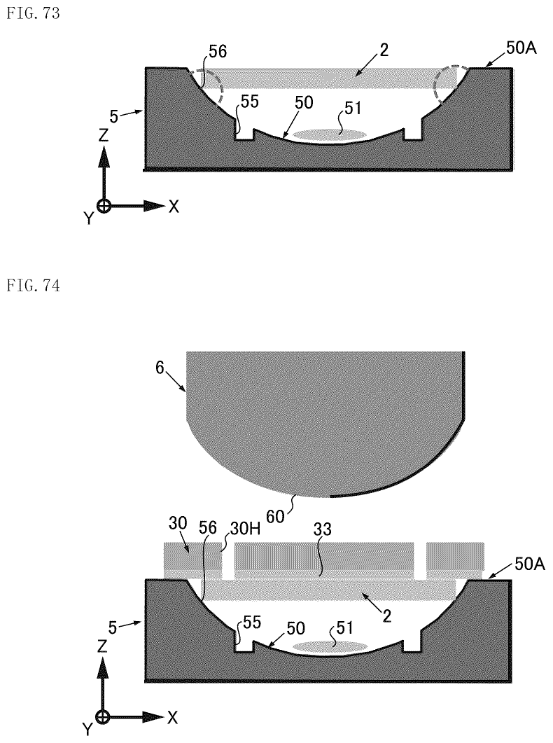

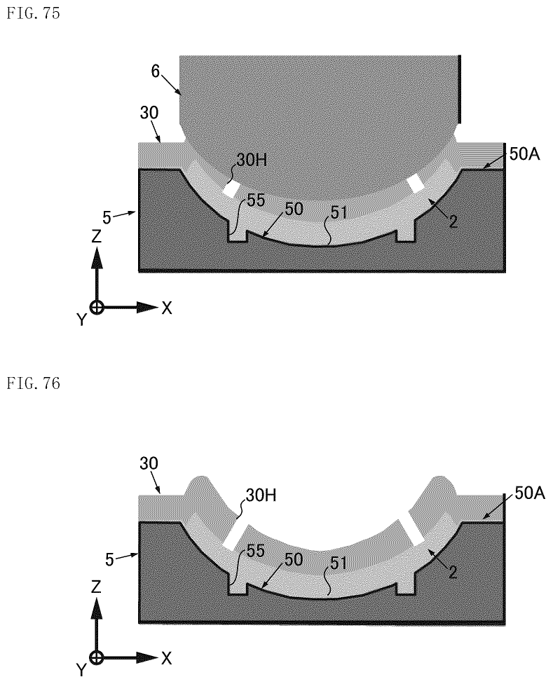

FIGS. 72 to 76 each illustrate an example of each step describing a press type curved mounting method. FIG. 72 illustrates an example of a planar configuration of the infrared-absorbing filter 30 for describing the press type curved mounting method. FIG. 73 illustrates an example of a cross-sectional configuration of the seating 5 on which the solid-state imaging element 2 and the infrared-absorbing filter 30 are placed. FIG. 74 illustrates an example of a cross-sectional configuration of the seating 5, the solid-state imaging element 2, the infrared-absorbing filter 30, and the pressing jig 6 before press type curved mounting. FIG. 75 illustrates an example of a cross-sectional configuration of the seating 5, the solid-state imaging element 2, the infrared-absorbing filter 30, and the pressing jig 6 during the press type curved mounting. FIG. 76 illustrates an example of a cross-sectional configuration of the seating 5, the solid-state imaging element 2, the infrared-absorbing filter 30, and the pressing jig 6 after the press type curved mounting.

The press type curved mounting method is as below.

First, as illustrated in FIG. 72, the infrared-absorbing filter 30 in a film shape is formed. The bonding opening 30H is formed in the infrared-absorbing filter 30.

Next, the seating 5 is prepared (see FIG. 73). The curved surface of the curved housing section 50 of the seating 5 has a configuration in which the CRA is incident vertically at any image height in a manner corresponding to the optical design of the unillustrated module lens.

As illustrated in FIG. 73, the solid-state imaging element 2 is disposed at a position corresponding to the curved housing section 50 of the seating 5. A detailed configuration of the solid-state imaging element 2 and the method of manufacturing the solid-state imaging element 2 are as described above. The curved surface of the curved housing section 50 of the seating 5 has a configuration in which the CRA is incident vertically at any image height in a manner corresponding to the optical design of the unillustrated module lens.

In addition, the adhesive 51 is formed in the curved housing section 50. The adhesive 51 may be applied to the solid-state imaging element 2 on the side of the second surface 21B. The adhesive 51 is formed by a material similar to that of the adhesive 51 according to the first embodiment or by a material of a curing type similar to the curing type of the adhesive 51 according to the first embodiment.

Here, the pocket 55 is formed in the curved housing section 50 of the seating 5 (see FIG. 12). The pocket 55 effectively suppresses or prevents spillover of the adhesive 51. In addition, the stepped part 56 is formed in the curved housing section 50 (see FIG. 13). The stepped part 56 allows for accurate positioning of the curved housing section 50 and the solid-state imaging element 2. Furthermore, the mark 57 may be formed in the seating 5 (see FIG. 14). The mark 57 allows for accurate positioning of the curved housing section 50 and the solid-state imaging element 2.

The infrared-absorbing filter 30 is formed on the light-receiving surface of the solid-state imaging element 2 with the adhesive 33 interposed therebetween (see FIG. 74). For example, a resin adhesive is used for the adhesive 33, and the adhesive 33 is applied to the solid-state imaging element 2 or the infrared-absorbing filter 30. Alternatively, a DAF may be used for the adhesive 33.

As illustrated in FIG. 74, the pressing jig 6 is placed on the curved housing section 50 of the seating 5 with the solid-state imaging element 2 and the infrared-absorbing filter 30 interposed therebetween, press-mounting by the pressing jig 6 starts. The pressing jig 6 is provided with the end part 60.

Here, a protective film may be interposed between the infrared-absorbing filter 30 and the end part 60 of the pressing jig 6. In this case, the protective film makes it possible to effectively suppress or prevent occurrence of a scar on the surface of the infrared-absorbing filter 30 or the solid-state imaging element 2.

As illustrated in FIG. 75, the adhesive 51 is cured while the end part 60 of the pressing jig 6 is pressed against the infrared-absorbing filter 30 and the solid-state imaging element 2. The pocket 55 takes in the excess of the adhesive 51. Thus, the solid-state imaging element 2 and the infrared-absorbing filter 30 in a state of being formed in the curved shape are fixed to the curved housing section 50 of the seating 5.

Thereafter, pressing by the pressing jig 6 is finished, and the pressing jig 6 is moved in the arrow −Z direction. In a case where the protective film is used, the protective film is removed.

Here, when the pocket 55 is formed in the curved housing section 50 of the seating 5, the end part of the pocket 55 is formed in a rounding shape as described above to effectively suppress or prevent occurrence of stress concentration.

According to the imaging device 1 configured as described above and the method of manufacturing the imaging device 1, it is possible to obtain workings and effects similar to the workings and effects obtained by the imaging device 1 and the method of manufacturing the imaging device 1 (the pressure difference type curved mounting method) described in FIGS. 59 to 67.

In addition, the imaging device 1 does not include an infrared cut filter on the side of the unillustrated module lens. This makes it possible to reduce reflection surfaces of the infrared cut filter and to effectively reduce fabrication cost. The reflection surfaces of the infrared cut filter may cause flare or ghost.

### 3. Other Embodiments

The present disclosure is not limited to the foregoing embodiments. For example, in the present disclosure, two or more of the respective examples described for the imaging device 1 and the method of manufacturing the imaging device 1 according to the first embodiment may be combined. Likewise, in the present disclosure, two or more of the respective examples described for the imaging device 1 and the method of manufacturing the imaging device 1 according to the second embodiment may be combined. Furthermore, in the present disclosure, any of the respective examples described for the imaging device 1 and the method of manufacturing the imaging device 1 according to the first embodiment and any of the respective examples described for the imaging device 1 and the method of manufacturing the imaging device 1 according to the second embodiment may be combined.

An imaging device according to a first aspect of the present disclosure includes an infrared-absorbing filter and a solid-state imaging element. The infrared-absorbing filter absorbs infrared light. The solid-state imaging element includes a base in which a plurality of pixels is arranged in a two-dimensional array. The pixels each include a photoelectric conversion region that converts incident light having passed through the infrared-absorbing filter into an electric signal. The infrared-absorbing filter and the base are recessed in an incident direction of the incident light, and are curved as a whole.

According to the imaging device configured as described above, it is possible to reduce reflection surfaces on a set side, which makes it possible to effectively suppress or prevent flare or ghost. As a result, it is possible to effectively suppress or prevent deterioration in color reproducibility.

In an imaging device according to a second aspect of the present disclosure, the infrared-absorbing filter includes an infrared-absorbing film, in the imaging device according to the first aspect. The infrared-absorbing film is formed by an on-chip in the pixel of the solid-state imaging element. In addition, the imaging device according to the second aspect further includes a multilayer film filter layer formed by an on-chip, in addition to the infrared-absorbing film. The multilayer film filter layer is. The multilayer film filter layer includes a high refractive index layer and a low refractive index layer that are alternately stacked, and has a specific transmission spectrum. The low refractive index layer has a refractive index lower than that of the high refractive index layer.

According to the imaging device configured as described above, the multilayer film filter enhances a transmittance of visible light with a thin film. As a result, it is possible to reduce the number of layers stacked in the multilayer film filter.

An imaging device according to a third aspect of the present disclosure further includes a seating including a curved housing section at a middle part of a surface of the seating on a side of the solid-state imaging element, in the imaging device according to the first aspect. The curved housing section corresponds to a curved shape of the solid-state imaging element, and is recessed in the incident direction of the incident light to house the solid-state imaging element.

According to the imaging device configured as described above, the seating includes the curved housing section, and the solid-state imaging element is housed in the curved housing section, which makes it possible to easily achieve the curved shapes of the solid-state imaging element and the infrared-absorbing filter.

A method of manufacturing an imaging device according to a fourth aspect of the present disclosure includes: forming a solid-state imaging element including a base in which a plurality of pixels is arranged in a two-dimensional array, the pixels each including a photoelectric conversion region that converts incident light into an electric signal; forming a seating including a curved housing section at a middle part of a front surface of the seating, and a ventilation section, the curved housing section being recessed in an incident direction of the incident light to house the solid-state imaging element, the ventilation section being formed in the curved housing section from the middle part of the front surface to a side of a back surface opposed to the middle part of the front surface; placing the solid-state imaging element on the curved housing section and forming an infrared-absorbing filter that covers the curved housing section with the solid-state imaging element interposed between the infrared-absorbing filter and the curved housing section and absorbs infrared light; and generating a pressure difference in which a pressure on an inner side of the curved housing section is smaller than a pressure on a side of the infrared-absorbing filter to curve the solid-state imaging element and the infrared-absorbing filter along the curved housing section and bring the infrared-absorbing filter into close contact with a light-receiving surface, on which the plurality of pixels is arranged, of the solid-state imaging element.

According to such a method of manufacturing the imaging device, the seating including the curved housing section and the ventilation section is formed, and the pressure difference is generated through the ventilation section on the solid-state imaging element placed in the curved housing section, which makes it possible to form the infrared-absorbing filter and the solid-state imaging element in a curved shape along the shape of the curved housing section.

A method of manufacturing an imaging device according to a fifth aspect of the present disclosure includes: forming a solid-state imaging element including a base in which a plurality of pixels is arranged in a two-dimensional array, the pixels each including a photoelectric conversion region that converts incident light into an electric signal; forming a seating including a curved housing section at a middle part of a front surface of the seating, the curved housing section being recessed in an incident direction of the incident light to house the solid-state imaging element; placing the solid-state imaging element in the curved housing section and bringing an infrared-absorbing filter into close contact with a light-receiving surface, on which the plurality of pixels is arranged, of the solid-state imaging element, the infrared-absorbing filter that absorbs infrared light; and curving the solid-state imaging element and the infrared-absorbing filter along the curved housing section after bringing the infrared-absorbing filter into close contact with the light-receiving surface of the solid-state imaging element.

According to such a method of manufacturing the imaging device, the seating including the curved housing section is formed, and the infrared-absorbing filter is brought into close contact with the solid-state imaging element placed in the curved housing section, which makes it possible to form the infrared-absorbing filter and the solid-state imaging element along the shape of the curved housing section.

### <Configuration of Present Disclosure>

The present disclosure includes the following configurations. Providing the following configurations makes it possible to provide an imaging device that makes it possible to effectively suppress or prevent deterioration in color reproducibility, and a method of manufacturing the imaging device.

(1)

An imaging device including:
an infrared-absorbing filter that absorbs infrared light; and
a solid-state imaging element including a base in which a plurality of pixels is arranged in a two-dimensional array, the pixels each including a photoelectric conversion region that converts incident light having passed through the infrared-absorbing filter into an electric signal, in which
the infrared-absorbing filter and the base are recessed in an incident direction of the incident light, and are curved as a whole.
   (2)

The imaging device according to (1), in which the infrared-absorbing filter includes an infrared-absorbing film formed by an on-chip in the pixel of the solid-state imaging element.

(3)

The imaging device according to (2), further including multilayer film filter formed by an on-chip, in addition to the infrared-absorbing film, the multilayer film filter including a high refractive index layer and a low refractive index layer that are alternately stacked, and having a specific transmission spectrum, the low refractive index layer having a refractive index lower than a refractive index of the high refractive index layer.

(4)

The imaging device according to any one of (1) to (3), in which
the infrared-absorbing filter includes an infrared-absorbing film, and
the infrared-absorbing film is in close contact with a light-receiving surface, on which the plurality of pixels is arranged, of the solid-state imaging element on which incident light is incident.
   (5)

The imaging device according to (4), in which the infrared-absorbing film extends along a side surface of the solid-state imaging element from the light-receiving surface, and is in close contact with the side surface.

(6)

The imaging device according to any one of (1) to (5), further including a seating including a curved housing section at a middle part of a front surface on a side of the solid-state imaging element, the curved housing section corresponding to a curved shape of the solid-state imaging element, and being recessed in the incident direction of the incident light to house the solid-state imaging element.

(7)

The imaging device according to (4), further including a seating including a curved housing section at a middle part of a front surface on a side of the solid-state imaging element, the curved housing section corresponding to a curved shape of the solid-state imaging element, and being recessed in the incident direction of the incident light to house the solid-state imaging element, in which
the infrared-absorbing film extends along a peripheral part of a front surface of the seating from the light-receiving surface of the solid-state imaging element via a side surface of the solid-state imaging element, and is in close contact with the side surface of the solid-state imaging element and the peripheral part of the front surface of the seating.
   (8)

The imaging device according to any one of (4) to (7), in which
the solid-state imaging element includes a bonding pad on a side of the light-receiving surface of the base, and
the infrared-absorbing film has an opening at a position corresponding to the bonding pad.
   (9)

The imaging device according to (6) or (7), in which the solid-state imaging element is housed along a curved shape of the curved housing section, and is fixed to the curved housing section.

(10)

The imaging device according to (9), in which the solid-state imaging element is housed in the curved housing section without protruding outside the curved housing section.

(11)

The imaging device according to any one of (6), (7), (9), and (10), in which the seating includes a ventilation section in the curved housing section from the middle part of the front surface to a side of a back surface opposed to the middle part of the front surface.

(12)

The imaging device according to (11), in which a porous material is formed in the ventilation section.

(13)

The imaging device according to (11), in which the ventilation section includes an opening penetrating from the middle part of front surface to the side of the back surface.

(14) p The imaging device according to (13), in which the ventilation section is filled with an embedded member embedded in the opening.
(15)

The imaging device according to any one of (1) to (14), in which the infrared-absorbing filter absorbs light in a specific wavelength region including visible light or ultraviolet light other than infrared light.

(16)

A method of manufacturing an imaging device, the method including:
forming a solid-state imaging element including a base in which a plurality of pixels is arranged in a two-dimensional array, the pixels each including a photoelectric conversion region that converts incident light into an electric signal;
forming a seating including a curved housing section at a middle part of a front surface of the seating, and a ventilation section, the curved housing section being recessed in an incident direction of the incident light to house the solid-state imaging element, the ventilation section being formed in the curved housing section from the middle part of the front surface to a side of a back surface opposed to the middle part of the front surface;
placing the solid-state imaging element in the curved housing section and forming an infrared-absorbing filter that covers the curved housing section with the solid-state imaging element interposed between the infrared-absorbing filter and the curved housing section and absorbs infrared light; and
generating a pressure difference in which a pressure on an inner side of the curved housing section is smaller than a pressure on a side of the infrared-absorbing filter to curve the solid-state imaging element and the infrared-absorbing filter along the curved housing section and bring the infrared-absorbing filter into close contact with a light-receiving surface, on which the plurality of pixels is arranged, of the solid-state imaging element.
   (17)

The method of manufacturing the imaging device according to (16), in which the pressure difference is generated by reducing a pressure in the curved housing section through the ventilation section.

(18)

The method of manufacturing the imaging device according to (16), in which the pressure difference is generated by applying a pressure on a side of the infrared-absorbing filter.

(19)

The method of manufacturing the imaging device according to (16), in which the pressure difference is generated by blowing of a pressurized gas or pressing of a pressing jig.

(20)

A method of manufacturing an imaging device, the method including:
forming a solid-state imaging element including a base in which a plurality of pixels is arranged in a two-dimensional array, the pixels each including a photoelectric conversion region that converts incident light into an electric signal;
forming a seating including a curved housing section at a middle part of a front surface of the seating, the curved housing section being recessed in an incident direction of the incident light to house the solid-state imaging element;
placing the solid-state imaging element in the curved housing section and bringing an infrared-absorbing filter into close contact with a light-receiving surface, on which the plurality of pixels is arranged, of the solid-state imaging element, the infrared-absorbing filter that absorbs infrared light; and
curving the solid-state imaging element and the infrared-absorbing filter along the curved housing section after bringing the infrared-absorbing filter into close contact with the light-receiving surface of the solid-state imaging element.

The present application claims the benefit of U.S. Provisional Patent Application No. 63/456135 filed with the United States Patent and Trademark Office on Mar. 31, 2023, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An imaging device, comprising:
an infrared-absorbing filter that absorbs infrared light; and
a solid-state imaging element including a base in which a plurality of pixels is arranged in a two-dimensional array, the pixels each including a photoelectric conversion region that converts incident light having passed through the infrared-absorbing filter into an electric signal, wherein
the infrared-absorbing filter and the base are recessed in an incident direction of the incident light, and are curved as a whole.

2. The imaging device according to claim 1, wherein the infrared-absorbing filter comprises an infrared-absorbing film formed by an on-chip in the pixel of the solid-state imaging element.

3. The imaging device according to claim 2, further comprising a multilayer film filter formed by an on-chip, in addition to the infrared-absorbing film, the multilayer film filter including a high refractive index layer and a low refractive index layer that are alternately stacked, and having a specific transmission spectrum, the low refractive index layer having a refractive index lower than a refractive index of the high refractive index layer.

4. The imaging device according to claim 1, wherein
the infrared-absorbing filter comprises an infrared-absorbing film, and
the infrared-absorbing film is in close contact with a light-receiving surface, on which the plurality of pixels is arranged, of the solid-state imaging element on which incident light is incident.

5. The imaging device according to claim 4, wherein the infrared-absorbing film extends along a side surface of the solid-state imaging element from the light-receiving surface, and is in close contact with the side surface.

6. The imaging device according to claim 1, further comprising a seating including a curved housing section at a middle part of a front surface on a side of the solid-state imaging element, the curved housing section corresponding to a curved shape of the solid-state imaging element, and being recessed in the incident direction of the incident light to house the solid-state imaging element.

7. The imaging device according to claim 4, further comprising a seating including a curved housing section at a middle part of a front surface on a side of the solid-state imaging element, the curved housing section corresponding to a curved shape of the solid-state imaging element, and being recessed in the incident direction of the incident light to house the solid-state imaging element, wherein
the infrared-absorbing film extends along a peripheral part of a front surface of the seating from the light-receiving surface of the solid-state imaging element via a side surface of the solid-state imaging element, and is in close contact with the side surface of the solid-state imaging element and the peripheral part of the front surface of the seating.

8. The imaging device according to claim 4, wherein
the solid-state imaging element includes a bonding pad on a side of the light-receiving surface of the base, and
the infrared-absorbing film has an opening at a position corresponding to the bonding pad.

9. The imaging device according to claim 6, wherein the solid-state imaging element is housed along a curved shape of the curved housing section, and is fixed to the curved housing section.

10. The imaging device according to claim 9, wherein the solid-state imaging element is housed in the curved housing section without protruding outside the curved housing section.

11. The imaging device according to claim 6, wherein the seating includes a ventilation section in the curved housing section from the middle part of the front surface to a side of a back surface opposed to the middle part of the front surface.

12. The imaging device according to claim 11, wherein a porous material is formed in the ventilation section.

13. The imaging device according to claim 11, wherein the ventilation section comprises an opening penetrating from the middle part of front surface to the side of the back surface.

14. The imaging device according to claim 13, wherein the ventilation section is filled with an embedded member embedded in the opening.

15. The imaging device according to claim 1, wherein the infrared-absorbing filter absorbs light in a specific wavelength region including visible light or ultraviolet light other than infrared light.

16. A method of manufacturing an imaging device, the method comprising:
forming a solid-state imaging element including a base in which a plurality of pixels is arranged in a two-dimensional array, the pixels each including a photoelectric conversion region that converts incident light into an electric signal;
forming a seating including a curved housing section at a middle part of a front surface of the seating, and a ventilation section, the curved housing section being recessed in an incident direction of the incident light to house the solid-state imaging element, the ventilation section being formed in the curved housing section from the middle part of the front surface to a side of a back surface opposed to the middle part of the front surface;
placing the solid-state imaging element in the curved housing section and forming an infrared-absorbing filter that covers the curved housing section with the solid-state imaging element interposed between the infrared-absorbing filter and the curved housing section and absorbs infrared light; and
generating a pressure difference in which a pressure on an inner side of the curved housing section is smaller than a pressure on a side of the infrared-absorbing filter to curve the solid-state imaging element and the infrared-absorbing filter along the curved housing section and bring the infrared-absorbing filter into close contact with a light-receiving surface, on which the plurality of pixels is arranged, of the solid-state imaging element.

17. The method of manufacturing the imaging device according to claim 16, wherein the pressure difference is generated by reducing a pressure in the curved housing section through the ventilation section.

18. The method of manufacturing the imaging device according to claim 16, wherein the pressure difference is generated by applying a pressure on a side of the infrared-absorbing filter.

19. The method of manufacturing the imaging device according to claim 18, wherein the pressure difference is generated by blowing of a pressurized gas or pressing of a pressing jig.

20. A method of manufacturing an imaging device, the method comprising:
forming a solid-state imaging element including a base in which a plurality of pixels is arranged in a two-dimensional array, the pixels each including a photoelectric conversion region that converts incident light into an electric signal;
forming a seating including a curved housing section at a middle part of a front surface of the seating, the curved housing section being recessed in an incident direction of the incident light to house the solid-state imaging element;
placing the solid-state imaging element in the curved housing section and bringing an infrared-absorbing filter into close contact with a light-receiving surface, on which the plurality of pixels is arranged, of the solid-state imaging element, the infrared-absorbing filter that absorbs infrared light; and
curving the solid-state imaging element and the infrared-absorbing filter along the curved housing section after bringing the infrared-absorbing filter into close contact with the light-receiving surface of the solid-state imaging element.
